(19) United States
(12) Patent Application Publication
(10) Pub. No.: US 2025/0181949 A1
(43) Pub. Date: Jun. 5, 2025

(54) METAMORPHOSING MEMORY

(71) Applicant: William Robert Reohr, Severna Park, MD (US)

(72) Inventors: William Robert Reohr, Severna Park, MD (US); Barry Watson Krumm, Ocean Grove, NJ (US); Oliver Timothy Oberg, Elkridge, MD (US); Benjamin Bogan Reohr, Severna Park, MD (US)

(21) Appl. No.: 18/840,672

(22) PCT Filed: Mar. 23, 2023
(86) PCT No.: PCT/US2023/016090

§ 371 Date: Aug. 22, 2024

Related U.S. Application Data
(60) Provisional application No. 63/425,160, filed on Nov. 14, 2022.
(60) Provisional application No. 63/394,130, filed on Aug. 1, 2022.
(60) Provisional application No. 63/322,694, filed on Mar. 23, 2022.

(51) Int. Cl. G06N 10/20; G06N 10/40; H10N 60/12

(52) U.S. Cl. CPC G06N 10/20; G06N 10/40; H10N 60/12

(57) ABSTRACT

A cache circuit for use in a computing system includes at least one random-access memory (RAM) and at least one directory coupled to the RAM. The RAM includes multiple memory cells configured to store data, comprising operands, operators and instructions. The directory is configured to index locations of operands, operators and/or instructions stored in the RAM. An operator stored in the RAM is configured to perform one or more computations based at least in part on operands retrieved from the RAM, and to compute results as a function of the retrieved operands and inherent states of the memory cells in the RAM. The directory is further configured to confirm that at least one of a requested operand, operator and instruction is stored in the RAM.

### CROSS-REFERENCE TO RELATED APPLICATIONS

This application claims the benefit of and priority to U.S. Provisional Patent Application No. 63/425,160, filed Nov. 14, 2022, entitled “Superconducting Memory, Programmable Logic Arrays, and Fungible Arrays,” U.S. Provisional Patent Application No. 63/394,130, filed on Aug. 1, 2022, entitled “Control and Data Flow Logic for Reading and Writing Large Capacity Memories, Logic Arrays, and Interchangeable Memory and Logic Arrays Within Superconducting Systems,” and U.S. Provisional Patent Application No. 63/322,694, filed Mar. 23, 2022, entitled “Control Logic, Buses, Memory and Support Circuitry for Reading and Writing Large Capacity Memories Within Superconducting Systems,” the disclosures of which are incorporated by reference herein in their entirety for all purposes.

### BACKGROUND

The present invention relates generally to quantum and classical digital superconducting, and more specifically to superconducting array circuits.

Superconducting digital technology has provided computing and/or communications resources that benefit from high speed and low power dissipation. For decades, superconducting digital technology has lacked random-access memory (RAM) with adequate capacity and speed relative to logic circuits. This has been a major obstacle to industrialization for current applications of superconducting technology in telecommunications and signal intelligence, and can be especially forbidding for high-end and quantum computing.

In the field of digital logic, extensive use is made of well-known and highly developed complementary metal-oxide semiconductor (CMOS) technology. CMOS has been implemented in a number of computer systems to provide digital logic capability. As CMOS has begun to approach maturity as a technology, there is an interest in alternatives that may lead to higher performance in terms of speed, power dissipation computational density, interconnect bandwidth, and the like. An alternative to CMOS technology comprises superconducting circuitry, utilizing superconducting Josephson junctions. Superconducting digital technology is required, as support circuitry in the refrigerated areas (4.2 degrees Kelvin and below), to achieve power and performance goals of quantum computers, among other applications.

Unlike CMOS circuits which exploit simple wires, the interconnect technologies for connecting superconducting logic circuits are highly constrained, and thus complex to implement. There are essentially two separate circuit solutions for interconnects available to superconducting logic and memory circuits. They are (1) Josephson transmission lines (JTLs) that serve as local interconnects, and (2) passive transmission lines (PTLs) that serve as long-haul (distance) interconnects. A JTL is a superconducting circuit that contains two Josephson junctions, inductors, and a transformer (to couple in its AC operating energy). In modern superconducting processes, the JTL can link logic gates or memory circuits less than approximately 55 μm apart; the JTL link can only be distributed across about four logic gates. Individual JTL delays are about 12 picoseconds (ps). PTLs, on the other hand, include a PTL driver circuit, a passive transmission line (which includes ground shielding), and a PTL receiver. The signal reach of these circuits is about 0.1 mm/ps on the passive transmission line, plus frontend driver and backend receiver delays. Thus, optimal circuit designs for a superconducting system would feature PTL connections over JTL connections, like those found in memories currently under development, that have radio frequency (RF)-transmission-line-based read paths (like Josephson magnetic random-access memory (JMRAM)), although such circuit designs have not been developed to date.

There is an interest in developing superconducting field-programmable logic arrays (FPLAs) and superconducting field-programmable gate arrays (FPGAs) to serve as programmable controllers and to perform more general-purpose functions for quantum computers. To this end, compelling designs for FPLAs and FPGAs are disclosed in U.S. Pat. No. 9,595,970, by W. Reohr and R. Voigt, and in a paper entitled, “Superconducting Magnetic Field Programmable Gate Array,” by N. Katam et. al., IEEE Transactions On Applied Superconductivity, Vol. 28, No. 2, March 2018, respectively, the disclosures of which are incorporated by reference herein in their entirety. Unfortunately, using current state-of-the-art approaches, magnetic Josephson junction (MJJ) technology and other superconducting circuitry will not mature by the time entangled quantum bits (“qubits”) cross the necessary integration threshold to provide measurable performance advantages over CMOS technology.

### SUMMARY

The present invention, as manifested in one or more embodiments, addresses the above-identified problems with conventional superconducting systems by providing both general and tailored solutions for a variety of quantum computing memory architectures. In this regard, embodiments of the present invention provide a superconducting system that can be configured to function as logic and/or memory. More particularly, one or more embodiments of the invention may be configured to perform operations across multiple subarrays, and regions of a subarray can be used in a “logic” mode of operation while other regions of the subarray may be used in a “memory” mode of operation.

In accordance with one embodiment of the invention, a cache circuit for use in a computing system includes at least one random-access memory (RAM) and at least one directory coupled to the RAM. The RAM includes multiple memory cells configured to store data, comprising operands, operators and instructions. The directory is configured to index locations of operands, operators and/or instructions stored in the RAM. An operator stored in the RAM is configured to perform one or more computations based at least in part on operands retrieved from the RAM, and to compute results as a function of the retrieved operands and inherent states of the memory cells in the RAM. The directory is further configured to confirm that at least one of a requested operand, operator and instruction is stored in the RAM.

The cache circuit may further comprise an address translator, the address translator being controlled by an operating system and configured to translate logical memory to physical memory, and at least one translation lookaside buffer (TLB) operatively coupled to the RAM and the directory, the TLB being configured to store translated addresses generated by the address translator. The operating system controls movement of page data between the cache circuit and a file system operatively coupled to the cache circuit.

As the term may be used herein, “facilitating” an action includes performing the action, making the action easier, helping to carry the action out, or causing the action to be performed. Thus, by way of example only and without limitation, in the context of a processor-implemented method, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

One or more embodiments of the invention or elements thereof may be implemented in the form of a computer program product including a computer readable storage medium with computer usable program code for performing the method steps indicated. Furthermore, one or more embodiments of the invention or elements thereof can be implemented in the form of a system (or apparatus) including a memory, and at least one processor that is coupled to the memory and configured to perform the exemplary method steps.

Yet further, in another aspect, one or more embodiments of the invention or elements thereof can be implemented in the form of means for carrying out one or more of the method steps described herein; the means can include (i) hardware module(s), (ii) software module(s) stored in a computer readable storage medium (or multiple such media) and implemented on a hardware processor, or (iii) a combination of (i) and (ii); any of (i)-(iii) implement the specific techniques, or elements thereof, set forth herein.

Techniques of the present invention can provide substantial beneficial technical effects. By way of example only and without limitation, techniques according to embodiments of the invention may provide one or more of the following advantages, among other benefits:
reduces the amount of energy required in a computing system;
can be used to perform lower-energy computations in the system;
reduces inter-component latency within the system.

These and other features and advantages of the present invention will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1A through 1C are schematic diagrams depicting at least a portion of an exemplary MM that includes arrays of cells that can serve either as memory cells, for memory operations, programmable switches, for logic operations, or both, for mixed mode operations, according to one or more embodiments of the present invention;

FIG. 2 is a timing diagram depicting at least a subset of word line inputs, data inputs and/or partial address inputs that enable exemplary memory read operations, logic operations, and mixed mode operations associated with the illustrative MM shown in FIGS. 1A through 1C, according to one or more embodiments of the present invention;

FIG. 3A is a schematic diagram depicting at least a portion of an exemplary quantum computing system that includes elements configurable for implementing control and data plane/path logic to process mixed quantum and classical/Boolean algorithms, according to one or more embodiments of the present invention;

FIG. 3B is a schematic diagram depicting at least a portion of an exemplary quantum computing system that includes elements configurable for implementing control and data path/plane logic, elements partially enabled by compound MMs consistent with FIGS. 1A through 1C to process mixed quantum and classical/Boolean algorithms, according to one or more other embodiments of the present invention;

FIG. 4 is a block diagram depicting at least a portion of an exemplary logic implementation (e.g., a reciprocal quantum logic (RQL) implementation) of an electable inverter included in the illustrative MM of FIGS. 1A through 1C, according to one or more embodiments of the present invention;

FIG. 5 depicts at least a portion of an exemplary first logic block diagram that is used to conceptually explain how two passes through the illustrative MM of FIGS. 1A through 1C enables the generation of a universal Boolean expression, according to one or more embodiments of the present invention;

FIG. 6 is a schematic diagram depicting at least a portion of an exemplary array output circuit, known in the art;

FIG. 7 is a schematic diagram depicting at least a portion of a programmable-neighbor-to-neighbor-data-flow circuit, according to one or more embodiments of the present invention;

FIG. 8A is a schematic diagram depicting at least a portion of an exemplary programmable copy delay circuit, according to one or more embodiments of the invention, where enable signals selectively choose possible delay values;

FIG. 8B is a schematic diagram depicting at least a portion of an exemplary copy delay circuit, according to one or more embodiments of the invention, where the delays are fixed and compelled;

FIG. 9 is a schematic diagram depicting at least a portion of an exemplary sequential memory read comparison, according to one or more embodiments of the invention, where the comparison output can be selected by an enable signal;

FIG. 10 is a diagram conceptually depicting at least a portion, which may be referred to herein as a bit slice, of an exemplary array output data flow, according to one or more embodiments of the present invention;

FIG. 11 is a block diagram depicting at least a portion of an exemplary north-south-east-west network element, which may be utilized in a superconducting system for performing logic, memory, and/or mixed logic and memory operations according to one or more embodiments of the present invention;

FIG. 12 is a schematic depicting at least a portion (i.e., bit slice) of an exemplary array output data flow, which can include array output circuits, OR gates, cycle sequenced logic, and elective inverters, according to one or more embodiments of the present invention;

FIG. 13 is a schematic depicting at least a portion of an exemplary wide logic gate, having specific bit slices as inputs, according to one or more embodiments of the present invention;

FIG. 14 is a schematic diagram depicting at least a portion of an exemplary multi-channel passive transmission line circuit that is used to match the bandwidth of between driver/receiver pairs to that of the incoming Josephson transmission line, according to one or more embodiments of the present invention;

FIG. 15 is a schematic diagram depicting at least a portion of an exemplary multi-channel passive transmission line circuit that is used to manage the availability of transmission line channels when the total bandwidth of channels is less than that of the incoming Josephson transmission line, according to one or more embodiments of the present invention;

FIG. 16 is a block diagram that conceptually illustrates at least a portion of an exemplary branch resolution system configured to perform early and late branch resolutions, according to one or more embodiments of the present invention;

FIG. 17 is a block diagram depicting at least a portion of an exemplary file and memory circuit, according to one or more embodiments of the present invention;

FIG. 18 is a schematic diagram depicting at least a portion of conventional request lookup circuitry;

FIG. 19 is a schematic diagram depicting at least a portion of exemplary enhanced request lookup circuitry, according to one or more embodiments of the present invention; and

FIGS. 20 and 21 are block diagrams conceptually illustrating at least a portion of exemplary embodiments of a lookup path, according to embodiments of the present invention.

It is to be appreciated that elements in the figures are illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Thus, principles of the present invention, as manifested in one or more embodiments, will be described herein in the context of quantum and classical digital superconducting circuits, and more specifically to various embodiments of array systems configured to support, with programmability, data plane/path and control plane/path for entangled quantum bits (i.e., “qubits”) of a quantum computer. It is to be appreciated, however, that the invention is not limited to the specific devices, circuits, systems and/or methods illustratively shown and described herein. Rather, it will become apparent to those skilled in the art given the teachings herein that numerous modifications to the embodiments shown are contemplated and are within the scope of embodiments of the claimed invention. That is, no limitations with respect to the embodiments shown and described herein are intended or should be inferred.

Hot semiconductor embodiments work for many of the logical elements described herein so long as the logic requirements met for a memory cell, programmable switch, and fixed switch, also described herein and associated with a metamorphosing memory (MM) architecture according to aspects of the present disclosure, are implemented in an underlying array circuit. At present, such a semiconductor circuit with an “OR” (“AND”) read column line may not be area-efficient, so it might not see widespread use.

Including principally both arrays (short for cell arrays) and buses, a MM according to one or more embodiments of the inventive concepts can be implemented to perform logic operations, memory operations, or both logic and memory operations in a superconducting environment, such as in a reciprocal quantum logic (RQL) quantum computing environment. A given array may include a plurality of superconducting array cells, arranged in at least one row and at least one column, which may be configured to selectively (e.g., after programming) perform logic operations and/or memory operations. Outputs of multiple arrays can be logically ORed together, outside each “array,” in accordance with one or more embodiments of the present disclosure. It is to be appreciated that logical “OR” functionality may be implemented using either OR or AND gates, in accordance with known principles, such as De Morgan's theorem. Thus, “AND”-style data flows in array columns and at their outputs for alternative superconducting circuits are also contemplated, rather than “OR”-style data flows principally used throughout the Detailed Description. Such signals will preferably be conveyed through Josephson transmission lines (JTLs) or through passive transmission lines (PTLs), PTL drivers, and/or PTL receivers, given the extended distances that may be covered. A standard JTL may propagate a signal across less than about 120 μm, thus providing only relatively short-range communications.

In general, microwave signals, such as, for example, single flux quantum (SFQ) pulses, may be used to control the state of a memory cell in a memory array. During read/write operations, word lines (i.e., row lines) and bit lines (i.e., column lines) may be selectively activated by SFQ pulses, or RQL pulses arriving via an address bus and via independent read and write control signals. These pulses may, in turn, control row-line and column-line driver circuits adapted to selectively provide respective word-line and bit-line currents to the relevant memory cells in the memory array.

Many forms of memory are suitable for use in this invention including, but not limited to, RQL-based random-access memory (RAM) and Josephson magnetic random-access memory (JMRAM), among other memory topologies.

For logic operations, at least one input that is associated with a corresponding row may receive respective logic input signal(s), and at least one output that is associated with a respective column may correspond to a logical output based on a predetermined logic operation associated with the superconducting cell array logic circuit system. As described herein, the term “logic signal” (including “logic input signal” and “logic output signal”), with respect to a superconducting cell array logic circuit, is intended to refer broadly to the presence of a signal (e.g., indicative of a logic-1 signal) or the absence of a signal (e.g., indicative of a logic-0 signal). Therefore, in the context of RQL, for example, the term “signal” may describe the presence of at least one SFQ pulse to indicate a first logic state (e.g., logic-1), or the absence of an SFQ pulse to indicate a second logic state (e.g., logic-0). Similarly, in the context of RQL, for example, the at least one pulse may correspond to a positive pulse (e.g., SFQ pulse or fluxon) followed by a negative pulse (e.g., negative SFQ pulse or anti-fluxon).

For memory operations, the memory element (e.g., a magnetic Josephson junction (MJJ)), or collective memory elements, in each of the superconducting array cells in the superconducting cell array logic circuit can store a digital state corresponding to one of a first binary state (e.g., logic-1) or a second binary state (e.g., logic-0) in response to a write-word current and a write-bit current associated with the MJJ. For example, the first binary state may correspond to a positive x-state, in which a superconducting phase is exhibited. As an example, the write-word and write-bit currents can each be provided on an associated (e.g., coupled, such as by a magnetic field, to the MJJ) write-word line (WWL) and an associated write-bit line (WBL), which, in conjunction with one another, can set the logic state of a selected MJJ. As the term is used herein, a “selected” MJJ may be defined as an MJJ designated for writing among a plurality of MJJs by activating current flow in its associated write-bit line. The digital state of a selected MJJ is preferably written by application of a positive or negative current flow within its associated write-bit line (for all known or postulated MJJs except a “toggle” MJJ). Moreover, to prevent the MJJ from being set to an undesired negative x-state, the MJJ may include a directional write element that is configured to generate a directional bias current through the MJJ during a data-write operation. Thus, the MJJ can be forced into a positive x-state to provide a superconducting phase in a predetermined direction.

In addition, the MJJ in each of the JMRAM memory cells in an array can provide an indication of the stored digital state in response to application of a read-word current and a read-bit current. The superconducting phase can thus lower a critical current associated with at least one Josephson junction of each of the JMRAM memory cells of a row in the array. Therefore, the read-bit current and a derivative of the read-word current (e.g., induced by the read-word current flowing through a transformer) can be provided, in combination, (i) to trigger the Josephson junction(s) to change a voltage on an associated read-bit line if the MJJ stores a digital state corresponding to the first binary state, and (ii) not to trigger the Josephson junction(s) to change the voltage on the associated read-bit line if the MJJ stores a digital state corresponding to the second binary state. Thus, the read-bit line may have a voltage present, the magnitude of which varies based on whether the digital state of the MJJ corresponds to the binary logic-1 state or the binary logic-0 state (e.g., between a non-zero and a zero amplitude). As used herein, the term “trigger” with respect to Josephson junctions is intended to refer broadly to a phenomenon of the Josephson junction generating a discrete voltage pulse in response to current flow through the Josephson junction exceeding a prescribed critical current level.

Returning to the discussion of logic operations enabled by the MM according to embodiments of the present inventive concept, a predetermined logic operation may be based on a selective coupling of at least one input to at least one corresponding output via the superconducting array cells. Stated another way, the predetermined logic operation can be based on a selective coupling of the at least one input to the superconducting array cells, which are coupled to at least one corresponding output in each respective column.

As described herein, the term “selective coupling” with respect to a given one of the superconducting array cells is intended to refer broadly to a condition of a respective input of a given one of the superconducting array cells being either coupled or decoupled from a respective output of the given one of the superconducting array cells (e.g., via a programmable switch (PS)), or either coupled or decoupled from a respective one of the superconducting array cells. Therefore, for a given array of superconducting array cells, the array of superconducting array cells can have inputs that are selectively coupled to one or more outputs, such that all, some (e.g., a proper subset), or none of the input(s) to the respective superconducting array cells may be coupled to the output(s) via the respective superconducting array cells in a predetermined manner. Accordingly, input(s) that are coupled to the respective output(s) via the respective superconducting cell(s) based on the selective coupling are described herein as “coupled,” and thus the respective coupled superconducting cell(s) provide a corresponding output logic signal in response to a logic input signal. Conversely, input(s) that are not coupled to the respective output(s) via the respective superconducting cell(s) based on the selective coupling are described herein as “uncoupled” or “non-coupled,” and thus the respective uncoupled superconducting cell(s) do not provide a corresponding output logic signal in response to a logic input signal.

The selective coupling of the input(s) to the output(s) via the superconducting array cells (configured as programmable switches) can be beneficially field-programmable in a manner similar to a field-programmable gate array (FPGA). For example, the selective coupling may be based on the presence or absence of an inductive coupling of the input(s) to a superconducting quantum interference device (SQUID) associated with the respective superconducting cell, with the SQUID being coupled to a respective one of the output(s), or on the direct injection of an SFQ pulse or pulse pair (for RQL) to read the state of a non-destructive readout (NDRO) memory cell (see, e.g., U.S. Pat. No. 10,554,207 to Herr, et al., the disclosure of which is incorporated by reference herein in its entirety), etc. Therefore, one or more Josephson junctions associated with the SQUID may trigger in response to a respective logic input signal to provide a respective output signal in a first logic state based on inductive coupling or direct injection, or will not trigger in response to the respective logic input signal(s) to provide the respective output signal in a second logic state based on no inductive coupling or no direct injection.

As another example, each of at least a subset of the superconducting array cells may include a hysteretic magnetic Josephson junction device (HMJJD) configured to store a first magnetic state or a second magnetic state in response to at least one programming signal. Thus, the HMJJD may provide coupling between the respective input(s) and output(s) in the first magnetic state, and may provide non-coupling between the respective input(s) and output(s) in the second magnetic state. Accordingly, providing the programming signal(s) to set the magnetic state of the HMJJD may facilitate field-programmability of the superconducting cell array logic circuit system to set the logic operation.

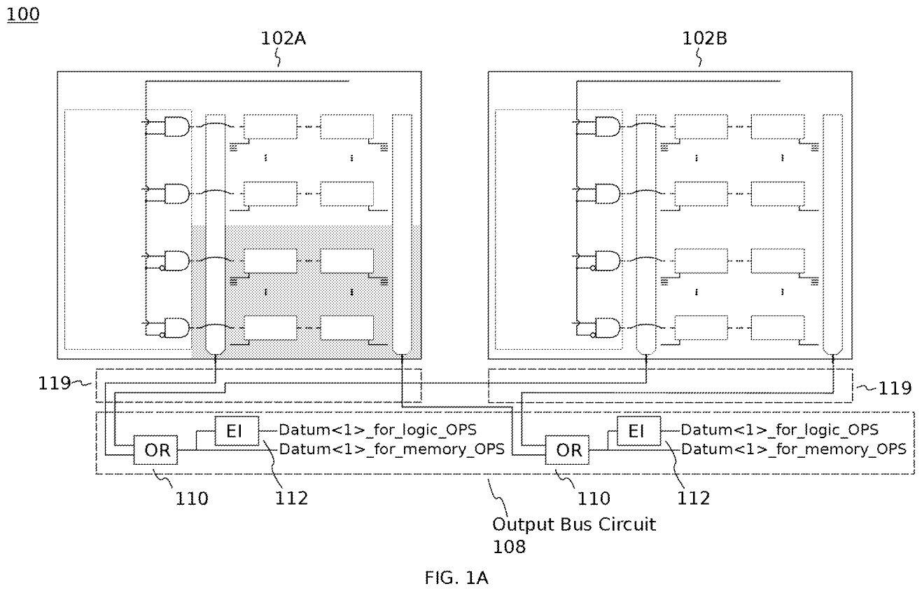

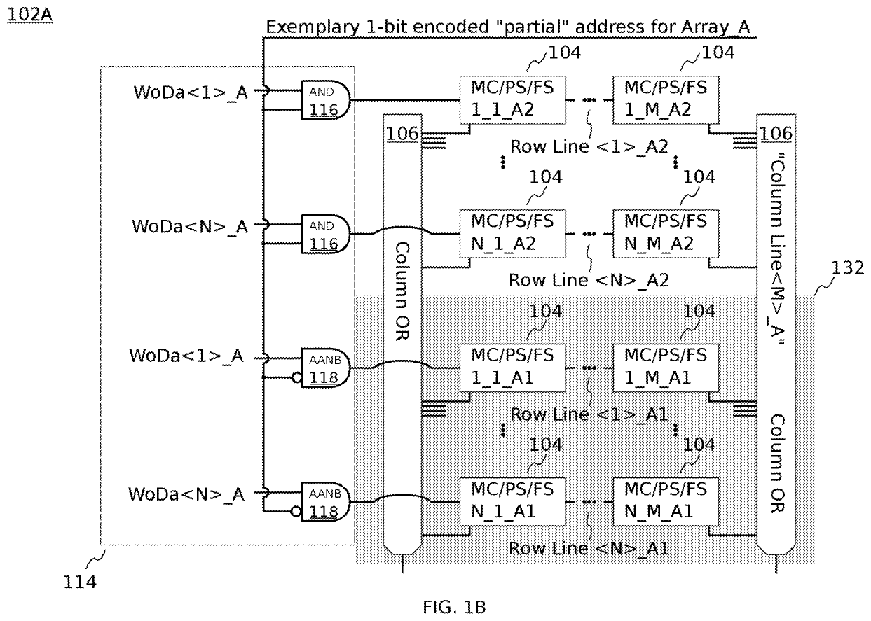

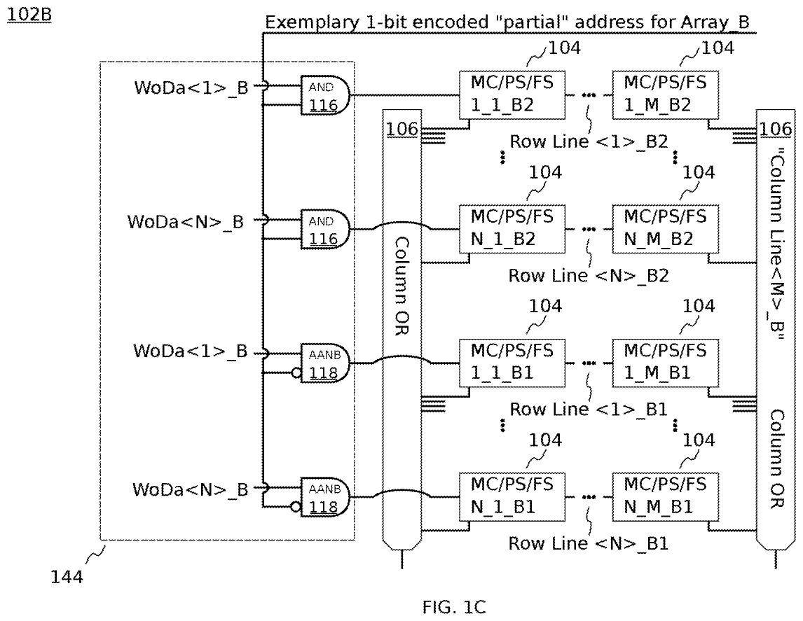

FIG. 1A is a schematic diagram depicting at least a portion of an exemplary MM 100, according to one or more embodiments of the inventive concept; FIGS. 1B and 1C are schematic diagrams depicting at least a portion of exemplary superconducting arrays, 102A and 102B, respectively (which can be collectively referred to herein as 102), each of which may include arrays of cells configured to serve either as memory cells for memory operations, or as programmable switches for logic operations, or both for mixed-mode operations, which may be used in the illustrative MM 100 of FIG. 1A, according to one or more embodiments of the inventive concept. The arrays of cells can advantageously exploit fixed closed or open switches, for example, as defined by masks during fabrication. The MM 100 may be implemented in any of a variety of quantum and/or classical computer systems, in accordance with aspects of the inventive concept. In the illustrative embodiments shown in FIGS. 1A-1C, the MM 100, comprising superconducting arrays 102A, 102B, can be used to implement a memory system, a programmable logic system, or both (e.g., a programmable processor pipeline or execution unit).

With reference to FIGS. 1A-1C, the exemplary MM 100 includes a plurality of superconducting arrays, 102A and 102B, each of the superconducting arrays comprising a plurality of superconducting cells 104. Each of the superconducting cells 104 may be configurable as a memory cell (MC), or as a programmable switch (PS), or as a fixed switch (FS) (where its state is fixed by design). The superconducting cells 104 are preferably organized into one or more arrays 102A, 102B, wherein the superconducting cells in each of the arrays may be arranged in at least one row (word line) and at least one column (bit line). Although in this illustrative embodiment, the superconducting cells 104 are organized into two arrays 102A, 102B, Array_A and Array_B, respectively, it is to be appreciated that the invention is not limited to any specific number of arrays. Defined as such, the MM 100 can serve broadly as at least one of a memory system, a logic system, and a co-mingled memory and logic system.

Each superconducting cell (MC/PS/FS) 104 may be connected to a corresponding input of a column OR gate 106 that serves as a bit line or data line. Each of at least a subset of the superconducting cells 104 (MC/PS/FS) may be configured to implement the functionality of the OR gate 106, in whole or in part; that is, although shown as a separate block, it is to be understood that at least a portion of the function(s) of the column OR gate 106 may be integrated into the superconducting cells 104. In the illustrative embodiment depicted in FIGS. 1A-1C, a location of each superconducting cell 104 within the arrays 102A, 102B may be represented by its name: “MC/PS/FS <row>_<column>_<region>.” Various other ways of indicating the location of a given superconducting cell 104 are similarly contemplated. Further description regarding the engagement of an actual row within an array 102 will be provided herein below, once other aspects of the MM 100 have been described, such as its output bus circuit 108.

When using a memory cell as described in U.S. Pat. No. 10,554,207 to Anna Herr, et al. (which defines an RQL-read-path NDRO memory cell) in the superconducting array 102A, 102B, a two-input RQL OR gate would be included as part of the memory cell to form, when connected in series with the respective two-input RQL OR gates of other cells in the array, the multiple-input OR gate 106 (for bit line and/or data line) shown in FIGS. 1B-1C, as will become apparent to those skilled in the art. That is, the OR gate 106 preferably represents the collective OR functionality implemented by the plurality of superconducting cells 104, each of which implements a two-input OR gate; a first input of the OR gate being sourced by the upstream superconducting cell 104, a second input of the OR gate being sourced by the superconducting cell 104 itself (which represents its state), and an output of the superconducting cell 104, which is forwarded to the downstream superconducting cell 104 in a corresponding column.

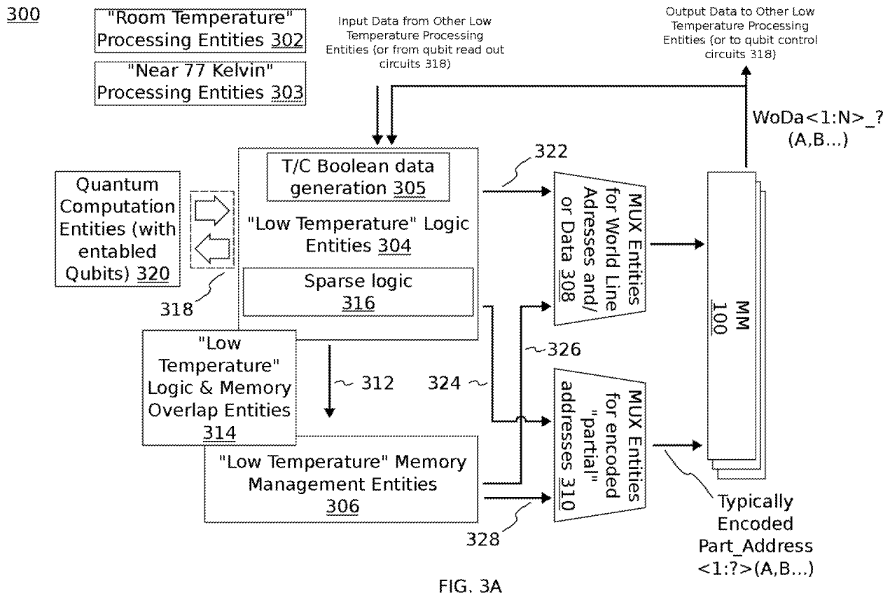

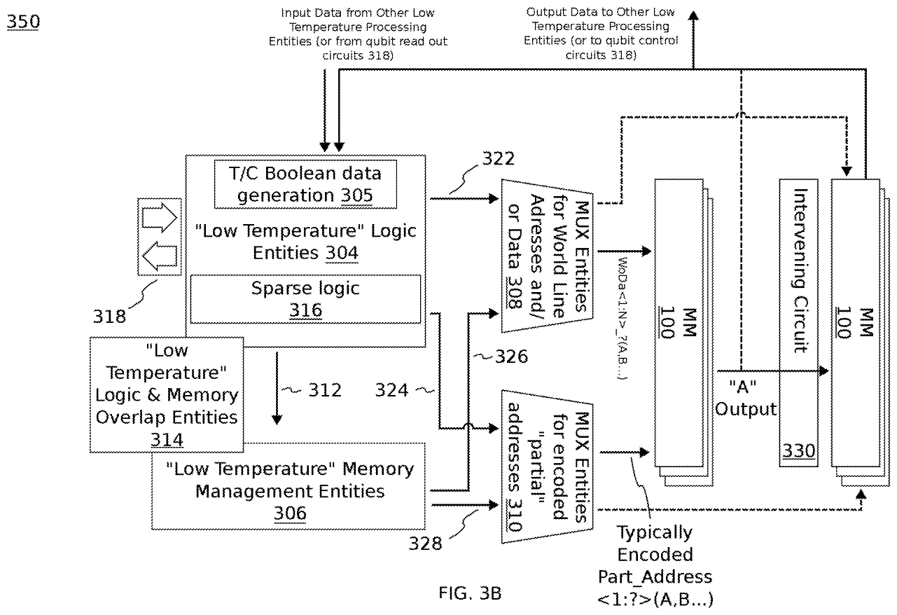

With continued reference to FIGS. 1A-1C, the illustrative MM 100 further includes one or more output bus circuits 108. In a memory operation, the output bus circuit 108 is preferably configured to receive read data of one array from a set of arrays 102A, 102B and return the read data (labeled “Datum<1:M>_for_memory_OPS,” where M is an integer greater than 1) to an entity not specified in the MM 100, as will be explained in further detail in conjunction with FIG. 3A. The output bus circuit 108, in a first logic operation, is preferably configured to receive logic data from at least one array 102A, 102B and return the logic data (labeled “Datum<1:M>_for_logic_OPS”) to an entity not specified in the MM 100 (to be specified and explained in conjunction with FIG. 3A). In a second logic operation, the output bus circuit 108 is configured to receive logic data from at least one array 102A, 102B, to perform logic operations on such data (e.g., OR gates 110 in the output bus circuit 108 may perform OR operations on outputs from a plurality of activated/enabled arrays), and to return in-transit-modified logic data (labeled “Datum<1:M>_for_logic_OPS”) to an entity not specified in the MM 100 (to be specified and explained in conjunction with FIG. 3A).

In a mixed memory and logic operation or in a multiple-read memory operation, the output bus circuit 108 is preferably configured to perform bit-wise (i.e., bit-by-bit), or whole data field, combinations of a memory operation, first logic operation and/or second logic operation using OR logic (e.g., OR gate 110). One skilled in the relevant art, given the teachings herein, will appreciate the various possibilities of memory, logic and mixed-mode (memory and logic) operations that can be achieved using the MM 100, in accordance with embodiments of the inventive concept. In fact, ORing the results of one or more superconducting cells 104 among the superconducting array 102A, 102B configured as a programmable switch (PS), configured as a memory cell (MC), and/or configured as a fixed switch (FS), can be done within each array 102A, 102B, or, in yet another embodiment, among multiple arrays, such as through array enable signals, which can preferably be propagated, in the exemplary MM 100, by “WoDa” signals (FIGS. 1B-1C).

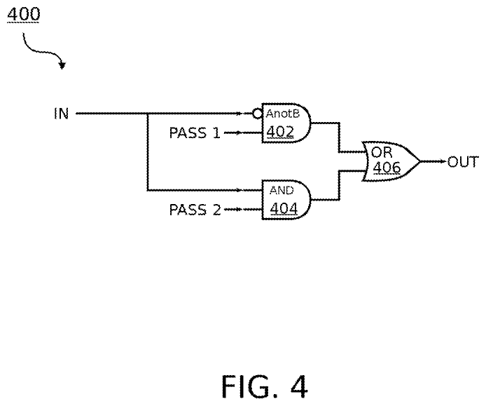

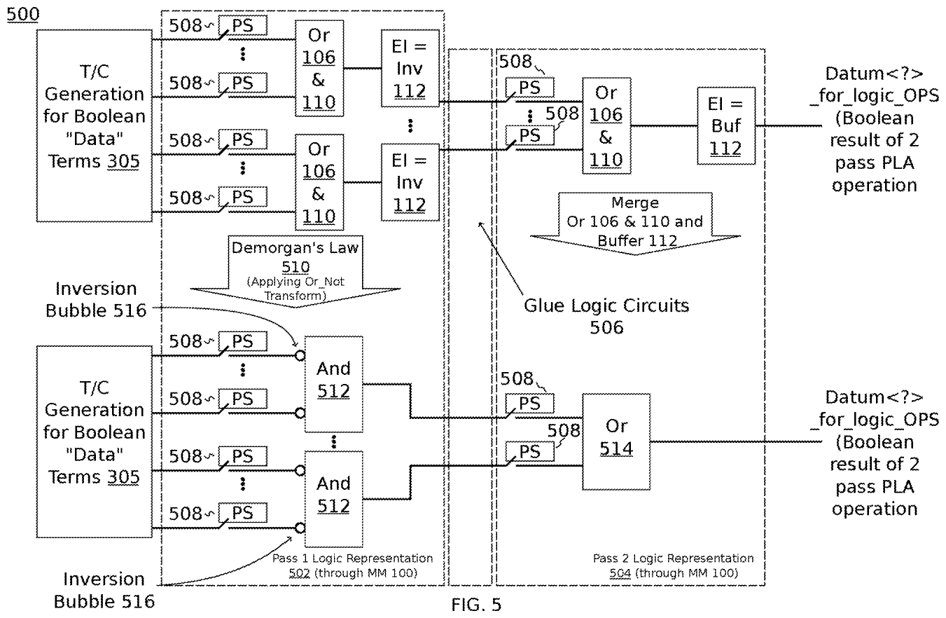

The output bus circuit 108 may, in one or more embodiments, includes a plurality of OR gates 110 for combining data outputs of the arrays 102A, 102B, and a plurality of electable inverters 112 for enabling a realization of a comprehensive Boolean logic function in two passes through the MM 100, as will be discussed in further detail with respect to FIG. 5. A detailed schematic of an exemplary electable inverter 112 is shown in FIG. 4, according to one or more embodiments of the invention.

Many of the FIGS. depict illustrative embodiments of the present invention that are directed to memory read operations, which may be enabled by selection of a single row of memory cells, and to logic operations, which may be enabled by rows of programmed switches that are invoked in a “none,” “some,” or “all” multi-row select read operation. Given this purpose, and for enhanced clarity of the description, all of the FIGS. (as interpreted by the inventors) notably exclude independent write address ports, write word lines (WWLs), and write bit lines (WBLs) of the arrays 102A, 102B, as will become apparent to those skilled in the art. It is important to note that superconducting read and write ports are typically separate even at the level of a memory cell circuit. Unlike 6-transistor (6-T) static random-access memory (SRAM), dynamic random-access memory (DRAM), and flash memories, among other CMOS-based memories, most, if not all, superconducting memory cells feature independent read and write ports.

For superconducting memories or programmable logic arrays (PLAs), a write operation configured to program a row of programmable switches (i.e., superconducting array cells (MC/PS/FS) 104 configured as programmable switches) can be performed in a manner similar to a write operation to set the state of a row of memory cells (i.e., superconducting array cells (MC/PS/FS) 104 configured as memory cells). Likewise, a column line (e.g., bit line, data line) oriented write operation can be performed to enable a match array of a content addressable memory (CAM), as known in the art. (See, e.g., U.S. Pat. No. 9,613,699, Apr. 4, 2017, to W. Reohr et al.).

One or more embodiments of the invention contemplate that certain artificial intelligence (AI) operations may gain an advantage if this architecture permits updates of/to at least a subset of programmable switches during a program or an algorithm runtime. Thus, considering such updates can be desirable, there is essentially no formal difference between the timing of write operations directed to memory cells and programmable switches during the runtime of a program or an algorithm. On the other hand, a different style of writing, which exploits shift registers, can be used to program programmable switches (PSs) if these switches are programmed in advance of program runtime.

The MM 100 can further include proximate (i.e., local) decode logic 114 configured to direct data input or memory word line selection signals to a particular (i.e., selected) subset of rows within an array 102A, 102B, which is defined herein as a “region” (one of which is highlighted by underlying rectangle/region 132). Such row-oriented functionality is emphasized by input signals labeled with the prefix “WoDa,” where the “Wo” portion of the prefix represents a word line of a memory, and where the “Da” portion of the prefix represents data input to a logic array. In the exemplary MM 100 shown in FIGS. 1A and 1B, the decode logic 114 used to decode the “exemplary 1-bit encoded ‘partial’ address for Array_A” may include only AND gates 116 and AnotB gates 118. The memory cells 104 in the array 102A may be associated with row lines in a first subarray, A1, and row lines in a second subarray, A2, with outputs of the AnotB gates 118 driving corresponding row lines in the first subarray A1, and outputs of the AND gates 116 driving corresponding row lines in the second subarray A2.

More particularly, in the array 102A shown in FIG. 1B, the decode logic 114 may include a first plurality (1 through N, where Nis an integer) of AND gates 116, and a second plurality (1 through N) of AnotB gates 118. Each of the first plurality of AND gates 116 includes a first input adapted to receive the “exemplary 1-bit encoded ‘partial’ address for Array_A” signal, a second input adapted to receive a corresponding one of the WoDa signals, WoDa<1>_A through WoDa<N>_A, and an output connected to a corresponding one of row lines <1>_A2 through <N>A2 and their associated memory cells 104 in the second subarray A2. Likewise, each of the second plurality of AnotB gates 118 includes a first input adapted to receive an inversion of the “exemplary 1-bit encoded ‘partial’ address for Array_A” signal, a second input adapted to receive a corresponding one of the WoDa signals WoDa<1>_A through WoDa<N>A, and an output connected to a corresponding one of the row lines <1>_A1 through <N>_A1 and their associated memory cells 104 in the first subarray A1.

Similarly, the second array 102B shown in FIG. 1C may include decode logic 144 configured in a manner consistent with the decode logic 114 shown in FIG. 1B. Specifically, in the exemplary MM 100 shown in FIGS. 1A and 1C, the decode logic 144 used to decode an “exemplary 1-bit encoded ‘partial’ address for Array_B” signal may include only AND gates 116 and AnotB gates 118. The memory cells 104 in the array 102B may be associated with row lines in a first subarray, B1, and row lines in a second subarray, B2, with outputs of the AnotB gates 118 driving corresponding row lines in the first subarray B1, and outputs of the AND gates 116 driving corresponding row lines in the second subarray B2.

More particularly, in the array 102B shown in FIG. 1C, the decode logic 144 may include a first plurality (1 through N) of AND gates 116, and a second plurality (1 through N) of AnotB gates 118. Each of the first plurality of AND gates 116 includes a first input adapted to receive the “exemplary 1-bit encoded ‘partial’ address for Array_B” signal, a second input adapted to receive a corresponding one of the WoDa signals, WoDa<1>_B through WoDa<N>_B, and an output connected to a corresponding one of row lines <1>_B2 through <N>_B2 and their associated memory cells 104 in the second subarray B2. Likewise, each of the second plurality of AnotB gates 118 includes a first input adapted to receive an inversion of the “exemplary 1-bit encoded ‘partial’ address for Array_B” signal, a second input adapted to receive a corresponding one of the WoDa signals WoDa<1>B through WoDa<N>_B, and an output connected to a corresponding one of the row lines <1>_B1 through <N>_B1 and their associated memory cells 104 in the first subarray B1.

Although a specific arrangement of logic gates is shown in FIGS. 1A-1C, it is to be appreciated that other organizations of logic gates and corresponding interconnections are similarly contemplated for the decode logic 114, 144 according to embodiments of the invention, some exemplary alternatives of which will be described in further detail herein below. The value of alternative decode logic will become apparent to those skilled in the art given the teachings herein.

In the decode logic 114, 144 of the exemplary MM 100, the true signal feeds the AND gates 116 directly. For generation of the complement signals, the true signal is fed into an inverting input of the AnotB gates 118. A logic function made available within the family of RQL circuits, the AnotB gates 118 can be implemented, in one or more embodiments, as AND gates with their second (B) input inverted. As noted in FIGS. 1A-1C (and already discussed in part), other input signals in the illustrative MM 100, which feed the decode logic 114, 144 and which complete the decode/selection of a row(s), are the WoDa signals.

Row activation signals for a memory read operation and/or for logic operations (i.e., row activation signals directly propagating on row line <1:N>_A1, row line <1:N>_A2, row line <1:N>_B1, and row line <1:N>_B2) emerge from the AND gates 116 and AnotB gates 118 of the decode logic 114, 144. When activated by such row activation signal(s), selected superconducting memory cells 104 in a given row deliver their respective data states (either “1-state” and/or “0-state”) to corresponding OR gates 106, which serve, at least conceptually speaking, as bit lines (as the term is often used for conventional memory operations and architectures) and output data lines (as the term is used for conventional logic operations in the art of PLA design) of the arrays 102A, 102B. These bit lines and data lines preferably feed into the output bus circuit 108, which can operatively merge results from a plurality of operations applied to the arrays 102A, 102B and deliver these results to an intended location, as will be described in further detail in conjunction with FIG. 3A.

More formally within embodiments of the present disclosure, a “region” may be defined as a set of rows partially enabled by the “partial” address feeding decode logic 114, 144. Row activation requires simultaneous “region” and “WordData” (WoDa<#>) activation. A region in a given array 102A, 102B includes at least one row line.

While the decode logic 114, 144 is shown as directly driving the row lines (i.e., row line <1:N>_A1, row line <1:N>_A2, row line <1:N>_B1, and row line <1:N>_B2) in FIGS. 1A-1C, it is important to recognize that the array 102A, 102B is merely representational of logic, and is not circuit specific. Therefore, depending on the superconducting memory cell 104 chosen, and desired “regional” selection patterns chosen, various alternative decode circuits and row drivers may be required for operation, or for logical function, as will be understood by those skilled in the art.

By way of example only and without limitation, for a 16-deep memory array addressed with what would be a maximum of 4 encoded address bits, possible combinations of encoded partial address bits (which may define a region) and WordData (WoDa) bits are indicated in the following table:

TABLE 1

| Number of Encoded | Number of WordData |
|---|---|
| Partial Address Bits | (WoDa) Bits |
| 0 | 16 |
| 1 | 8 |
| 2 | 4 |
| 3 | 2 |
| 4 | 1 |

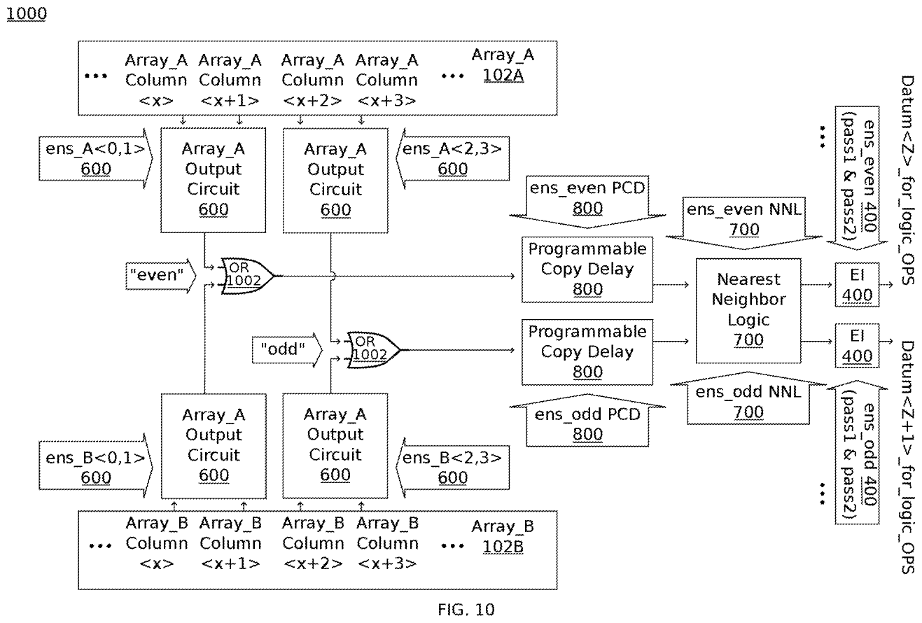

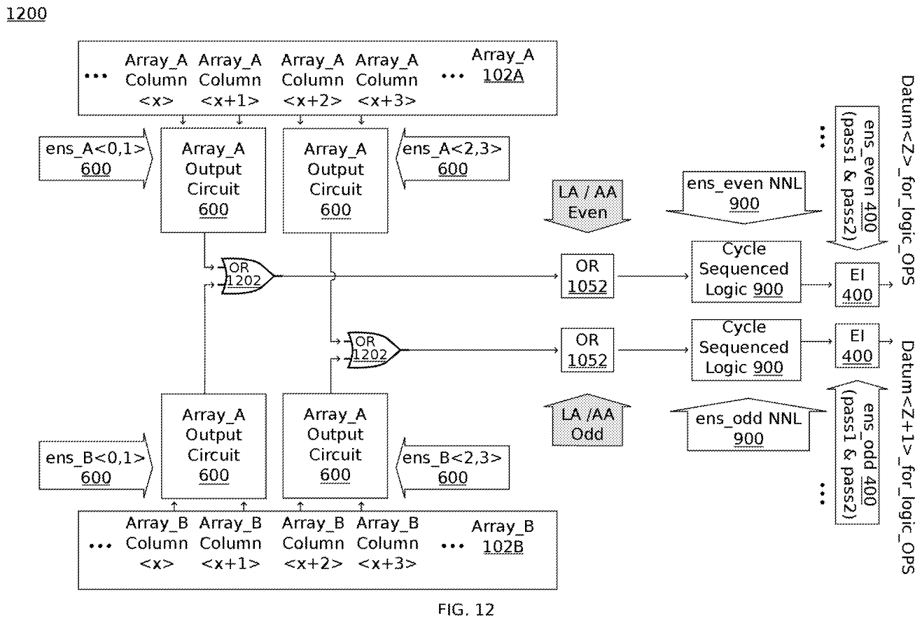

It is also important to recognize that column-oriented address logic (e.g., multiplexors)-serving to enable a second form of address decoding in arrays—can be implemented by array output circuit(s) 119, which may be integrated in each array 102A, 102B, in some embodiments, or may reside external to the arrays in other embodiments. These array output circuits 119 may be configured to select a set of columns of data from one or more arrays 102A, 102B for output, as will be discussed in further detail herein below with respect to illustrative bit slice output dataflows of FIGS. 10 and 12.

### 2) Dynamic Decoding

Table 2 describes dynamic decoding to select more than one region. Two regions having four rows each would double the width of the maximum PLA column based OR to an eight input OR. It has 3 columns. For example, that same exemplary 16-deep memory array, the possible combinations of encoded address bits (notably not fully defining a region), region enables (in the example of Table 2, there are two), and WordData bits are indicated in the following table:

TABLE 2

| | Number of Region | Number of |
|---|---|---|
| | Enable Bits | WordData Bits |
| | Their Bit Pattern | (WoDa bits) |
| | Being: | Reported Here |
| Number of | 01 | With Two Regions |
| Encoded | 10 | Simultaneously |
| Address Bits | 11 | Activated |
| 1 | 2 | 8 |
| 2 | 2 | 4 |

Region enable bits in combination with encoded address bits define a region. The choice to exploit one or more regions for a logic operation (an operator function) depends on the size of the OR logic needed to perform a particular function. Moving forward to discuss the principal/predominant data flow logic in system containing both control and data flow, it is important to note that while the illustrative MM 100 exploits OR-based logic for which non-controlling inputs are “0s,” it is similarly contemplated by embodiments of the invention that AND-based logic could be used in its place, in whole or in part, as will be understood by those skilled in the art. From a practical standpoint for RQL, it is advantageous to use an OR-based approach, which results in significant power savings given that a logic “0,” the non-controlling signal, consumes extremely little energy. In the case of AND-based logic, a non-controlling logic “1” propagates flux quantum pairs 180 degrees out of phase with each other with respect to the AC clocks of RQL (a flux quantum first and an anti-flux quantum second). These two flux quanta consume substantial energy.

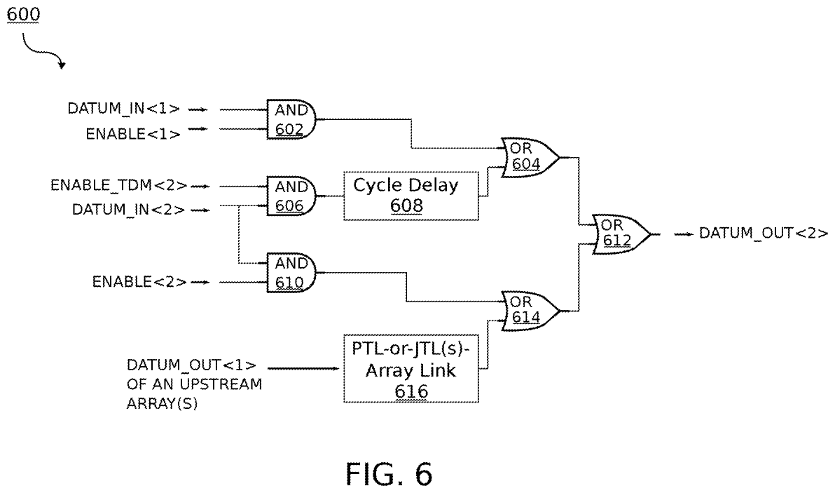

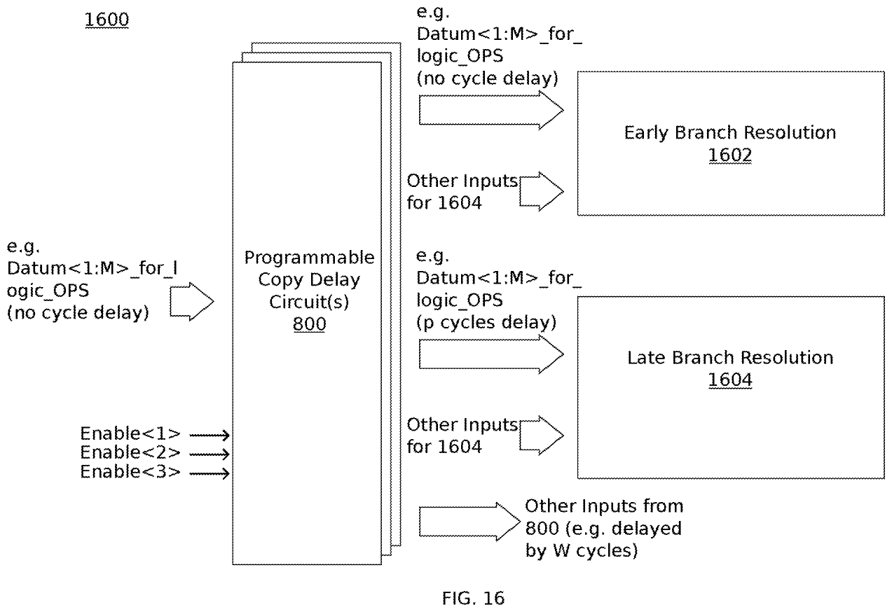

The MM 100 can further include one or more array-output circuits 119 operatively coupled between OR gate(s) 106 of array(s) 102 and OR gate(s) 110 of output bus circuit 108. The array-output circuits 119 are preferably proximate to their corresponding array(s) 102. These array-output circuits 119, in one or more embodiments, can be adapted in the following manner (which will be discussed with reference to the schematic of FIG. 6):
Possible adaption (1) can be to down-select the data—Data<1:M> for_logic_OPS and Data<1:M> for_memory_OPS-returned to a requesting entity(ies). In this example, the array-output circuits 119 can serve as a multiplexors (or AND-ORs) that propagate only the selected set of data;
Possible adaption (2) can be to propagate the output data on fewer bus lines by, for example, converting a substantially concurrent output into a partial serial output in time (through time division multiplexing as known in the art, which can be propagated on fewer bus lines using time division multiplexing preferably across neighboring outputs;
Possible adaption (3) can be to deselect the output data of a selected array (literally zeroing its results, generating non-controlling “0s”) so that the output of redundancy arrays can be used instead;
Possible adaption (4) can be to deselect at least some of the output data of a selected array (again literally zeroing its results, generating non-controlling “0s”) so that the sequential instructions and data requests being processed within it, obviated by detection of a branch taken, for example, can be nullified/disabled (i) to clear a pipeline and (ii) reduce its (the pipelines/the entities) power consumption (review the discussion associated with FIG. 16); and
Possible adaption (5) can be to enable mixed bit-field operations among arrays 102 (e.g., Arrays A and B) by disabling specific fields of output data (such as by setting them to non-controlling “0s”) emerging from a first array 102 (e.g., Array A) while enabling others from a second array 102 (e.g., Array B) in the same bit position to combine and concatenate the returned data (i.e., Datum<1:M>_for_logic_OPS and Datum<1:M>_for memory_OPS) in unique ways permitting a variety of logic, memory, and mixed logic and memory operations.

For possible adaption (5), a rich set of instructions (e.g., programmable instructions) could be devised so that logic (memory or mixed logic and memory) operations preferably among neighboring outputs (physically adjacent outputs) of the input terms WoDa<1:N>A and WoDa<1:N>_B could be executed. Note, that WoDa<1:N>A and WoDa<1:N>_B feed Array_B and Array_B, respectively. It is to be understood that the outputs of either array contain within-array-programmed ORing of WoDa<1:N>_A or of WoDa<1:N>_B. In a first combined output data field, only odd integers of the data output of Array_A are enabled, and even integers of the data output of Array_B are enabled, or, in a second alternative combined output data field, vice versa.

As will be understood, these embodiments recognize the criticality (crucial nature) of (i) proximate signals and (ii) regular data flows in realizing logic operations in superconducting circuits, especially given the limited reach or bandwidth capabilities (i.e., JTLs or PTLs, respectively) of superconducting interconnect in comparison to CMOS interconnect. Increasing the temporal and spatial confluence of various sets of signals along the output bus circuit 108, and into various processing units, assures a greater variety of nearest neighbor computations. In the example offered, the output can have twice as many input terms. For this example, the twice-as-many input terms are WoDa<1:N>A and WoDa<1:N>_B.

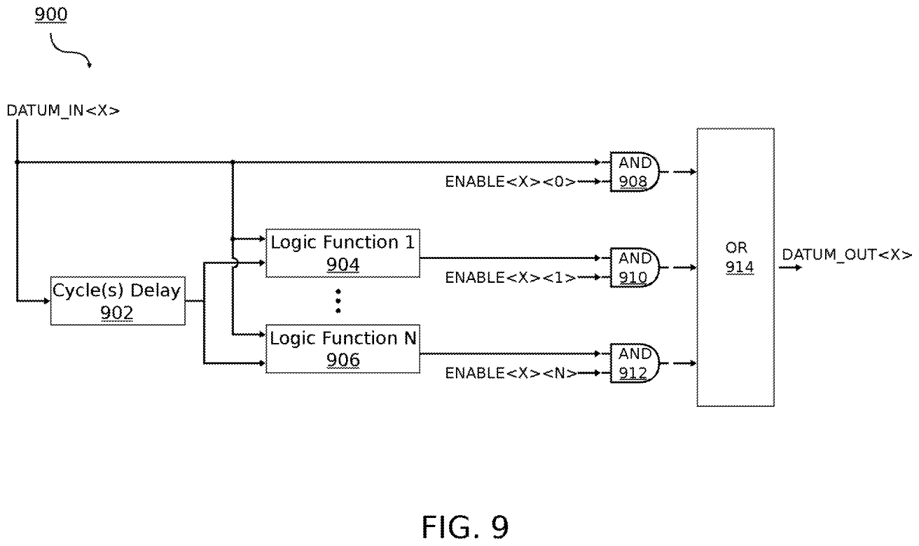

As will be discussed with respect to FIG. 9, neighbor to neighbor data flow processing of returned data (i.e., Datum<1:M>_for_logic_OPS and Datum<1:M> for memory_OPS) could be performed either in output bus circuit 108 of FIG. 1, or “low temperature” logic entities 304 of FIG. 3A, or other processing entities, that, for example, would combine array_derived_data_output<X>_A with array_derived_data_output/<X+1>_B in the data flows, where X is an integer ranging from 1 to M (M had also been defined as an integer).

It should be understood that branches, a redirection of present and future computation passing through the data flow, can be based on a number/text stored in memory, data just processed, and/or data stored in a register as understood by those skilled in the art.

When mixed logic and memory operations are conducted among arrays 102, certain portions of the field can be disabled. In one or more embodiments, AND gates can be inserted along with associated enables to elect a fraction of the data from an array 102 or set of arrays to be propagated in the output bus circuit 108 before OR gates 110. To support an understanding of these aforementioned capabilities of the array-output circuit(s) 119, the function and exemplary implementation of such array-output circuit(s) 119 will be described in greater detail in conjunction with FIG. 6.

After understanding the detailed principles of an array 102 with a decode structure designed to support fungible circuits for memory, logic or mixed mode operations, it is now beneficial to speak broadly about array alternatives. Fungible arrays require memory cells, which can serve as either memory cells (MC) or programmable switches (PS). While this capability represents some embodiments of the present invention, it is important to recognize that the capabilities described in the present invention can be applied more generally to superconducting arrays, such as Josephson fixed logic arrays (JFLA). For example, other superconducting array cells 102 of these JFLAs form fixed switches (FS), which are advantageously more compact than programmable switches (PS).

RQL-read-path-NDRO array cells (represented by array cell 104) can be, for example, NDRO memory cells described in Burnett, R. et. al., “Demonstration of Superconducting Memory for an RQL CPU,” Proceedings of the Fourth International Symposium on Memory Systems (2018), the disclosure of which is incorporated by reference herein in its entirety. Generally, these array cells 104 are meant to be representative of almost all other memory cells, for example, formed form ERSFQ or RQL circuit families. The name “RQL-read-path NDRO array cells” is thus intended herein to denote representative capabilities of these other memory cells, in terms of their potential bandwidths and latencies (which are abstracted in this detailed description), but it is not construed to be limiting.

RF-read-path array cells (represented by array cell 104) can be, for example, NDRO memory cells for JMRAM, PRAM (passive random-access memory as known in the art), or JLA. It is important to recognize that not all array cells 104 are memory cells; some array cells, when selected, couple a specified Boolean state—that being a “0-state or 1-state”—to the OR gate 106; a particular variety of them cannot be written; they are what is known as mask programmable array cells (a.k.a. Fixed Switches, abbreviated “FS”). The name “RF-read-path array cells” is thus intended herein to denote representative performance capabilities of these array cells 104, as well as structural aspects of their read port circuitry, whether they are memory cells, field programmable superconducting array cells (actually a memory cell itself), or an superconducting cell retaining a fixed state (a.k.a. mask programmed array cell), in terms of their potential bandwidths and latencies (which are abstracted in this detailed description). The term RF-read-path is not construed to be limiting. With respect to RQL-read-path-NDRO array cells 104, RF-read-path array cells 104 can advantageously provide lower latency, but can have lower bandwidth (typically depending on design), principally because multiple flux quanta (signals) are propagated and consumed on microwave lines (“RF” lines). Multi-cycle recovery times are required by flux pumps to restore the multiple flux quanta required for a subsequent operation. Known flux pumps are single flux quantum capable, generating one flux quanta per cycle and storing it in a superconducting loop for future use.

Named herein are two alternative PLAs, Josephson PLA and Josephson magnetic PLA, which will be referred respectively to as “JPLA” and “JMPLA” (following the JMRAM naming convention of Josephson magnetic RAM). A JPLA is formed exclusively with Josephson superconducting array cells 104. Likewise, a JMPLA is formed exclusively with MJJ-based superconducting array cells 104. While the MM 100 populated exclusively with JPLA and/or JMPLA arrays 104 may or may not facilitate a random-access memory function as known in the art, it is still contemplated as a unique embodiment(s) of the invention, as are exclusive memory embodiments and mixed memory and PLA embodiments. Additionally, the mixed memory and PLA embodiments can be further subdivided into (i) those in which the size of the PLAs and memories are fixed and (ii) those in which the size of the PLAs and memories can be programmed. For (ii), programming allots a subset of a fixed number of superconducting array cells 104 to PLAs and the remainder of array cells 104 to memory. It may be best to use the acronym “JPLARAM” to broadly refer to these fungible arrays 102 in which rows can be assigned to memory or logic functions as previously discussed.

The MM 100 can include a plurality of arrays 102 wherein arrays can be of different types. Thus, the MM 100 can have arrays containing at least one of RQL-read-path NDRO array cells (can be memory or logic cells), RF-read-path NDRO array cells (can be memory or logic cells), RF-read-path magnetic array cells (can be memory or logic cells, which form, e.g., JMRAM), RF-read-path magnetic superconducting array cells (which form, e.g., JMPLA), and RF-read-path superconducting array cells (which form, e.g., JPLA). In other words, any known superconducting logic array 104 or memory array can 104 be incorporated into the MM 100, exclusively, or with other types of arrays 104.

Moreover, FPGA gates can be integrated into the MM 100. In particular, they can be incorporated into the decode 114 for a non-trivial decode at the front end of the MM 100, can be included in the array-output circuits 116 for a non-trivial-data-flow modification of the output data of the arrays 104, and can be included in the return bus circuit 108 at the back end of the MM 100 for, for example, (i) routing data to a unique set of entities and/or (ii) recording data bits in a bus.

In another embodiment, an individual array 102 can include different array cells 104 within it so long as these cells conform to the same read path type (e.g., RQL-read-path or RF-read-path). For example, JPLA array cells 104 and JMPLA array cells 104 can be combined within an array in the following fashions: (i) in rows; (ii) in columns; or (iii) intermingled among rows and columns. A potential key for functionality of such a heterogeneous array cell approach can be to ensure substantially similar read-path properties (or elements) in columns and rows. In this embodiment, it should be noted that JLA array cells 104 do not have write ports, while JPLA array cells do. In other words, it should be noted that this embodiment principally concerns the read ports of array cells 104.

Now concerning the JMPLA in particular—while the write time of the array cells 104 of (configured in) the JMPLA, or its write circuits, are long and power hungry and thus may preclude them from forming a high performance “memory” array 102, these array cells 104 can still form an important class of circuits known as “field programmable logic” array 102.

Finally, to prepare for a discussion with respect to FIG. 3B, it is important to mention again that a write operation can be directed by underlying circuits to write a column, rather than a row, of an array while, for the same array, a read operation can be directed to one or more WoDas. This underlying unique read-write orientation forms the basis for the match array in a content addressable memory.

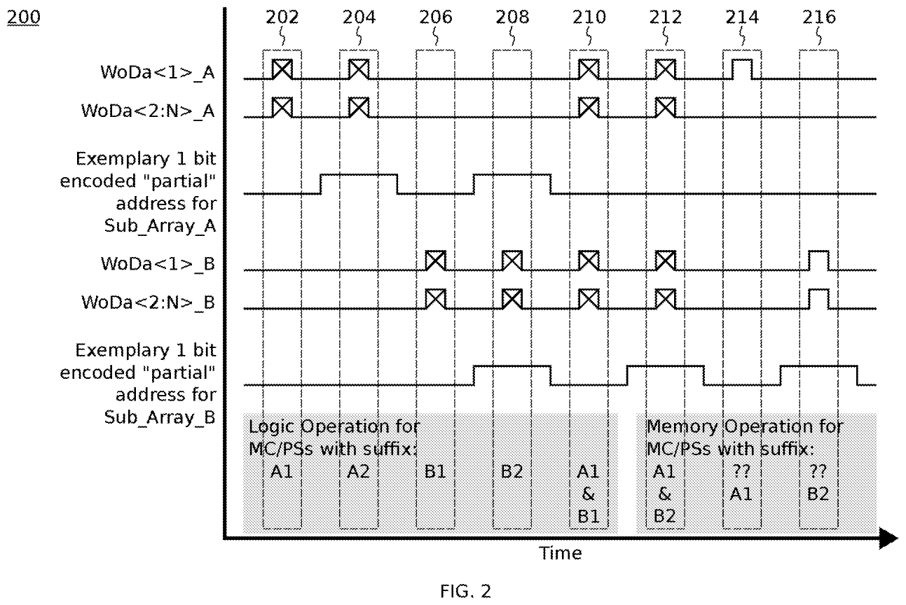

FIG. 2 is a timing diagram 200 depicting at least a subset of word line inputs, data inputs and/or partial address inputs that enable exemplary memory read operations, logic operations, and mixed mode operations associated with the illustrative MM 100 shown in FIG. 1, according to one or more embodiments of the invention. While mixed mode memory and logic operations may not be explicitly shown in the timing diagram 200, they are certainly contemplated, feasible, and useful for increasing per-operation functionality of the MM 100, and are within the scope of embodiments of the invention.

It is important to note that if the decode logic 114 is included in the illustrative MM 100 shown in FIG. 1, logic operations can be directed to an active subset of active superconducting array cells (MC/PS/FS) 104 in at least one array 102. Timing diagram 200 provides illustrative operations to locations of subsets of active superconducting array cells (MC/PS/FS) 104 in the array 102. To illustrate a memory operation, WoDa<1>_A and WoDa<1>_B input signals have been broken out of the set of input WoDa signals to represent a single (lone, one hot) active word line among a set of potentially active word lines (enabled by the partial decode logic 114) required for memory operations directed to Array A 102 and Array B 102, respectively. As such, WoDa<1> in the timing diagram 200 more generally represents WoDa<x> where x is an integer from 1 to N. The timing diagram 200 also includes inputs WoDa<2:N>_A and WoDa<2:N>_B.

The level of each signal in the timing diagram 200 indicates the Boolean value of that signal. An “x” (cross hatch) indicates that the Boolean value of the signal can be either a logic “0” or a logic “1.” Ignoring the presence of the electable inverter (e.g., 112 in FIG. 1) in this explanation of the timing diagram 200 (given that no outputs are shown in the timing diagram 200), the following examples will describe the function invoked; namely, a memory operation or a logic operation (again mixed memory and logic operations are also possible, as will be discussed in further detail herein below).

With continued reference to FIGS. 1 and 2, a first set of input signals 202 configures the MM 100 to perform prescribed logic functions that are designated by the superconducting array cells 104 of array A 102 configured as programmable switches. More specifically, the first set of input signals 202 drives an OR-based logic operation defined by the “programmed” state of a subset of programmable switches (i.e., superconducting array cells (MC/PS/FS) 104) in array A 102, where the active superconducting array cells (MC/PS/FS) 104, which participate in the logic operation, are located in active rows defined by at least one “partial” address input to the decode logic 114. Potentially active programmable switches (i.e., active superconducting array cells (MC/PS/FS) 104) in the logic operation notably have the suffix “A1,” which indicates the particular region. The “A1” set of programmable switches (superconducting array cells (MC/PS/FS) 104) include cells in row 1 being 1_1_A1 through 1_M_A1, cells in in-between rows, and cells in row N being N_1_A1 through N_M_A1.

Out of this subset of programmable switches, active programmable switches (i.e., active superconducting array cells (MC/PS/FS) 104) are preprogrammed (i.e., written) to store “1-states” so that, when activated by a row activation operation (a read operation of the superconducting array cells (MC/PS/FS) 104 in a given row), they couple their logic input/selection signals, WoDa<1:N>_A, to the inputs of corresponding OR gate(s) 106. The logic input signals selected by the active programmable switches can thus be transformed by operation of the OR gate(s) 106 (and representative OR gate(s) 110) and produce the resultant signals Data<1:M>_for_logic_OPS, which notably are generated within array A 102 exclusively. Since all WoDa<1:N>_B are “0s,” the outputs of array B 102 are “0s,” and thus they do not control the output of OR gates 110, as will be understood by those skilled in the art. It should be noted that the broader generalized Boolean capability of the MM 100 (in its capacity to provide a logic operation) will be discussed in greater detail with respect to FIG. 5.

Before describing the set of input signals 204, a simple example is useful in illustrating the programming of a subset of the superconducting array cells 104 functioning as programmable switches (MC/PS/FS) associated with OR gates 106. Input signals 202 define both the data input (WoDa<1:N>_A) and the location/set of the programmable switches (MC/PS 104) used (controlled by a combination of signals WoDa<1:N>_A and “exemplary 1 bit encoded ‘partial’ address for Array A). For example, suppose WoDa<1> is assigned to logic signal E, WoDa<2> is assigned to logic signal E_not/bar, WoDa<3> is assigned to logic signal F, and WoDa<4> is assigned to logic signal F_not/bar. To set Datum<1>_for_logic_OPS equal to the OR of E and F_not/bar, the superconducting array cells (MC/PS/FS) 104 1_1_A1 and 4_1_A1 are programmed to a “1-state.” The superconducting array cells (MC/PS/FS) 104 2_1_A1 and 3_1_A1, associated with the same column in the MM 100, are programmed to “0-state” so that their connections to OR gate 106, corresponding to Datum<1>_for_logic_OPS, are disabled.

With continued reference now to the illustrative timing diagram 200 shown in FIG. 2, a second set of input signals 204 configures the MM 100 to perform logic functions that are designated by at least a subset of the superconducting array cells 104 functioning as programmable switches (MC/PS/FS) of array A 102. More specifically, the second set of input signals 204 drives an OR-based logic operation defined by a “programmed” state of a subset of programmable switches (superconducting array cells (MC/PS/FS) 104) in array A 102, where the active superconducting array cells (MC/PS/FS) 104, which participate in the logic operation, are located in the active rows defined by at least one “partial” address input to the decode logic 114. Potentially active programmable switches in the logic operation notably have the suffix “A2.” The “A2” set of superconducting array cells (MC/PS/FS) 104 configured as programmable switches include cells in row 1, being 1_1_A2 through 1_M_A2, cells in in-between rows, and cells in row N, being N_1_A2 through N_M_A2.

Out of this subset of programmable switches (superconducting array cells 104), active programmable switches (MC/PS 104) have been preprogrammed (i.e., written) to store “1-states” so that, when activated by a row activation operation (a read operation of the MC/PSs 104 in a given row), they couple their logic input/selection signals, WoDa<1:N>_A, to the inputs of OR gate(s) 106. The logic input signals selected by the active programmable switches can thus be transformed by the logical operation of the OR gate(s) 106 and produce the resultant signals Data<1:M>_for_logic_OPS, which notably are generated within array A 102 exclusively.

Since all WoDa<1:N>_B signals are logic “0s,” the outputs of array B 102 are logic “0s,” and thus they do not control the output of OR gates 110, as will be understood by those skilled in the art. As previously stated, the broader generalized Boolean capability of the MM 100 (in its capacity to provide a logic operation) will be discussed in further detail with respect to FIG. 5.

A third set of input signals 206 configures the MM 100 to perform logic functions that are designated by at least a subset of the superconducting array cells (MC/PS/FS) 104 configured as programmable switches of array A 102. More specifically, the third set of input signals 206 drives an OR-based logic operation defined by the “programmed” state of a subset of the programmable switches (superconducting array cells (MC/PS/FS) 104) in array A 102, where the active superconducting array cells (MC/PS/FS) 104, which participate in the logic operation, are located in the active rows defined by at least one “partial” address input to the decode logic 114. Potentially active programmable switches (superconducting array cells (MC/PS/FS) 104) in the logic operation notably have the suffix “B1.” The “B1” set of programmable switches (superconducting array cells (MC/PS/FS) 104) include cells in row 1, labeled 1_1_B1 through 1_M_B1, cells in in-between rows, and cells in row N, labeled as N_1_B1 through N_M_B1.

Out of this set of programmable switches (superconducting array cells (MC/PS/FS) 104), active programmable switches (superconducting array cells (MC/PS/FS) 104) are preprogrammed (i.e., written) to store “1-states” so that, when activated by a row activation operation (a read operation of the MC/PSs 104 in a given row), they couple their logic input/selection signals, WoDa<1:N>_B, to the inputs of corresponding OR gate(s) 106. The logic input signals selected by the active programmable switches (active subset of superconducting array cells (MC/PS/FS) 104) can thus be transformed by the logical operation of the OR gate(s) 106 and produce the resultant signals Data<1:M>_for_logic_OPS, which notably are generated within array B 102 exclusively.

Since all WoDa<1:N>A signals are logic “0s,” the outputs of array A 102 are logic “0s,” and thus they do not control the output of the OR gates 110, as will be understood by those skilled in the art. As previously stated, the broader generalized Boolean capability of the MM 100 (in its capacity to provide a logic operation) will be discussed in further detail in conjunction with FIG. 5.

A fourth set of input signals 208 configures the MM 100 to perform logic functions that are designated by at least a subset of the superconducting array cells (MC/PS/FS) 104 configured as programmable switches of array A 102. More specifically, the fourth set of input signals 208 drives an OR-based logic operation defined by the “programmed” state of a subset of programmable switches (superconducting array cells (MC/PS/FS) 104) in array A 102, where the active MC/PSs 104, which participate in the logic operation, are located in the active rows defined by at least one “partial” address input to the decode logic 114. Potentially active superconducting array cells (MC/PS/FS) 104 configured as programmable switches in the logic operation notably have the suffix “B2.” The “B2” set of programmable switches (superconducting array cells (MC/PS/FS) 104) include cells in row 1 being 1_1_B2 through 1_M_B2, cells in in-between rows, and cells in row N being N_1_B2 through N_M_B2.

Out of this set of programmable switches (superconducting array cells (MC/PS/FS) 104), active programmable switches (MC/PS 104) are preprogrammed (i.e., written) to store “1-states” so that, when activated by a row activation operation (a read operation of the MC/PSs 104 in a given row), they couple their logic input/selection signals, WoDa<1:N>_B, to the inputs of OR gate(s) 106. The logic input signals selected by the active programmable switches (subset of superconducting array cells (MC/PS/FS) 104) can thus be transformed by the logical operation of the OR gate(s) 106 and produce the resultant signals Data<1:M>_for_logic_OPS, which notably are generated within array B 102 exclusively.

Since all WoDa<1:N>A signals are logic “0s,” the outputs of array A 102 are logic “0s,” and thus they do not control the output of the OR gates 110, as will become apparent to those skilled in the art. As previously stated, the broader generalized Boolean capability of the MM 100 (in its capacity to provide a logic operation) will be described in further detail in conjunction with FIG. 5.

With continued reference to FIG. 2, a fifth set of input signals 210 configures the MM 100 to perform logic functions that are designated by at least a subset of the superconducting array cells (MC/PS/FS) 104 configured as programmable switches of arrays A and B 102. More specifically, the fifth set of input signals 210 drives an OR-based logic operation defined by the “programmed” state of subsets of programmable switches (superconducting array cells (MC/PS/FS) 104) in array A 102 and array B 102, where the active superconducting array cells (MC/PS/FS) 104, which participate in the logic operation, are located in the active rows defined by at least two “partial” address inputs to the decode logic elements 114 of each array 102 (array A and array B).

Since this logic operation involves programmable switches (superconducting array cells (MC/PS/FS) 104) from two arrays, potentially active programmable switches in the logic operation notably have the suffices “A1” and “B1.” The “A1” and “B1” set of programmable switches (superconducting array cells (MC/PS/FS) 104) include: (i) for array A 102, cells in row 1 labeled 1_1_A1 through 1_M_A1, cells in in-between rows, and cells in row N being N_1_A1 through N_M_A1; and (ii) for array B 102, cells in row 1 labeled 1_1_B1 through 1_M_B1, cells in in-between rows, and cells in row N labeled N_1_B1 through N_M_B1.

Out of this set of programmable switches (superconducting array cells (MC/PS/FS) 104), active programmable switches (MC/PS 104) are preprogrammed (i.e., written) to store “1-states” so that, when activated by a row activation operation (a read operation of the superconducting array cells (MC/PS/FS) 104 in a given row), they couple their logic input/selection signals, WoDa<1:N>_A and WoDa<1:N>_B, to the inputs of their corresponding OR gates 106. The logic input signals selected by the active programmable switches (subset of superconducting array cells (MC/PS/FS) 104) can thus be transformed by the logical operation of the OR gates 106 and 110, and produce the resultant signals Data<1:M>_for_logic_OPS. The resultant operation notably depends on the respective programmable switches (MC/PSs 104) in arrays A and B 102. The broader generalized Boolean capability of the MM 100 (in its capacity to provide a logic operation) will be described in further detail herein with reference to FIG. 5.

A sixth set of input signals 212 in the illustrative timing diagram 200 configures the MM 100 to perform logic functions that are designated by at least a subset of the superconducting array cells (MC/PS/FS) 104 configured as programmable switches in respective arrays A and B 102. Specifically, the sixth set of input signals 212 drives an OR-based logic operation defined by the “programmed” state of respective subsets of programmable switches (i.e., superconducting array cells (MC/PS/FS) 104 configured as programmable switches) in arrays A and B 102, where the active MC/PSs 104, which participate in the logic operation, are located in the active rows defined by at least two “partial” address inputs to the decode logic elements 114 of each array 102.

Since this logic operation involves programmable switches (subset of superconducting array cells (MC/PS/FS) 104) from two arrays 102, potentially active programmable switches in the logic operation notably have the suffices “A1” and “B2.” The respective “A1” and “B2” subsets of programmable switches (superconducting array cells (MC/PS/FS) 104) include: (i) for array A 102, cells in row 1 labeled 1_1_A1 through 1_M_A1, cells in in-between rows, and cells in row N labeled N_1_A1 through N_M_A1; and (ii) for array B 102, cells in row 1 labeled 1_1_B2 through 1_M_B2, cells in in-between rows, and cells in row N labeled N_1_B2 through N_M_B2.

Out of this set of programmable switches (superconducting array cells (MC/PS/FS) 104), active programmable switches (MC/PS 104) are preprogrammed (i.e., written) to store “1-states” so that, when activated by a row activation operation (a read operation of the MC/PSs 104 in a given row), they couple their respective logic input/selection signals, WoDa<1:N>A and WoDa<1:N>_B, to the inputs of their corresponding OR gates 106. The logic input signals selected by the active programmable switches (subset of superconducting array cells (MC/PS/FS) 104) can thus be transformed by the logical operation of the OR gates 106 and 110, and produce the resultant signals Data<1:M>_for_logic_OPS. The resultant operation notably depends on the programmable switches (superconducting array cells (MC/PS/FS) 104) in arrays A and B 102. The broader generalized Boolean capability of the MM 100 (in its capacity to provide a logic operation) will be described in further detail herein below.

The sets of input signals 202 through 212 in the illustrative timing diagram 200 were used to configure the superconducting array cells (MC/PS/FS) 104 in the MM 100 to perform logic operations. As previously stated, at least a portion of the superconducting array cells (MC/PS/FS) 104 may be configured to perform memory operations. In this regard, a seventh set of input signals 214 configures at least a subset of the superconducting array cells (MC/PS/FS) 104 in the MM 100 to perform memory operations. More particularly, the set of input signals 214 drives a memory operation in array A 102.

Active superconducting array cells (MC/PS/FS) 104 configured as memory cells, which source read data, are located in an active row defined by a combination of signal WoDa<1>_A, being a “1-state,” and the “partial” address input to the decode logic elements 114, being a “0-state.” WoDa<1>_A is intended to be exemplary of one selected row within a subset of rows, WoDa<1:N>_A, wherein all unselected rows WoDa<2:N>A are in a “0-state,” associated with a particular decoded address. In this scenario, active memory cells are 1_1_A1 through 1_M_A1. Given that no other rows are selected, the outputs of the active memory cells (subset of superconducting array cells (MC/PS/FS) 104) pass through OR gates 106 of array A 102 and on through OR gates 110, and produce resultant signals Data<1:M>_for_memory_OPS.

Similarly, an eighth set of input signals 216 in the illustrative timing diagram 200 shown in FIG. 2 are operative to configure at least a subset of the superconducting array cells (MC/PS/FS) 104 in the MM 100 of FIG. 1 to perform memory operations. Specifically, the set of input signals 216 drives a memory operation in array B 102. The active memory cells (selected subset of the superconducting array cells (MC/PS/FS) 104), which source the read data, are located in an active row defined by a combination of signal WoDa<1>_B, being a “1-state,” and the “partial” address input to the decode logic elements 114, being a “1-state.” WoDa<1>B is meant to be exemplary of one selected row within a subset of rows, WoDa<1:N>_B, wherein all unselected rows WoDa<2:N>_B are in a “0-state,” associated with a particular decoded address. In this scenario, active memory cells (104) are 1_1_B2 through 1_M_B2. Given that no other rows are selected, the outputs of the active memory cells (superconducting array cells (MC/PS/FS) 104) pass through OR gates 106 of array A 102 and on through OR gates 110, and produce the resultant signals Data<1:M>_for_memory_OPS.

FIG. 3A is a schematic diagram depicting at least a portion of an exemplary quantum computing system 300 that includes elements adaptable to implement control and data path/plane logic, elements partially enabled by the MM 100 of FIG. 1, that are necessary to process mixed quantum and classical/Boolean algorithms, according to one or more embodiments of the invention. In a quantum computing system, Boolean logic functions are necessary to process mixed quantum and classical/Boolean algorithms, such as quantum error correction codes (QECC). The quantum computing system 300, in one or more embodiments, includes at least one MM 100, “room temperature” processing entities 302, “low temperature” logic entities 304, “low temperature” memory management entities 306, multiplexing entities for word line address and/or input data 308, multiplexing entities for encoded “partial” address 310 (in FIG. 1, notably only 1 bit), memory read and write request buses 312 (wherein a programming of PLA locations is understood to be at least one memory write operation to at least one row or at least one column), “low temperature” logic and memory overlap entities 314, analog/digital generation and communication layer/entity 318, and quantum computation entities (with entangled Qubits) 320. The core entities 304, 306, 308, 310, 312, 314 associated with the illustrative quantum computing system 300 interact directly or operatively with the MM 100 of FIG. 1 when permitted (i.e., cycles with no pipeline collisions). The core entities, which appear in the quantum computing system 300, should not be interpreted as limiting but are rather included to highlight certain aspects and advantages of embodiments of the invention, as will become apparent to those skilled in the art given the teachings herein. As known in the art, the quantum computing system 300 may, for example, further include “near 77 Kelvin” processing entities 303 to reduce the thermal load (heat injection) of the “room temperature” processing entities 302. These “near 77 Kelvin” processing entities 303 may serve as main memory and cache for classical computing resources (e.g. the processing the syndromes of quantum computation entities 320), A quantum computing system 300 would benefit from either a reduced temperature environment or closer electrical proximity to the 4.2 Kelvin processing entities. Such main memory and cache can be formed, in part, for example, using DRAM and SRAM, respectively.

Entities 100, 304, 306, 308, and 310 can all be implemented with reciprocal quantum logic technologies, as known in the art, and associated RAMs (herein referred to as RQL-based RAMs).

### Quantum Computing and Control of Qubits

The MM 100 can assist in (i) the synthesis of qubit control signals (e.g., potentially providing oversight, operators, and/or acquired test data for signal synthesis), in (ii) the generation of digital signals from qubit read out signals, in (iii) the processing of syndromes, and in (iv) the classical computations (classical subroutines) of an algorithm. For the control signal generation (i) in particular, far more energy efficient waveform storage can be realized by superconducting circuits than by semiconductor circuits at the expense of die/chip area with respect to SRAM: The word array tokens X equal 2Y, where Y is the binary integer of an instruction. Each instruction is weighted for a particular set of qubit parameters.

No particular diagram is needed to discuss briefly how the present invention fits into the state of the art of qubits, which can be understood by considering the controls and applications that might be useful on a quantum computer. A brief overview of qubits indicates possible roles for the present invention and, moreover, makes some command execution steps clearer, as known in the art.

In a quantum computer, generally the following two actions are desired: turning on and off coupling between qubits and applying excitations to individual qubits. Applied correctly, these can effect the qubit behavior as a (quantum) logic gate on one, two, or more qubits. These operations/actions can be executed by properly applying a voltage tuned to the qubit(s) in question; exactly what this voltage does isn't too important for this present discussion. Unlike regular logic, this voltage is more akin to an analog signal than the Boolean quasi-DC voltage. The more accurate the voltage value, the less corrections need to be applied. What adds complexity is that every qubit can be fabricated differently, is different, given its unique analog physical characteristics. Fortunately, the target voltage signal waveform for each physical qubit doesn't change within any cool down. There are ways to approximate an optional voltage signal waveform for each physical qubit. Simply put, a system can “guess” in the form of a well-defined signal, and extract the individual device parameters from the measurement, potentially repeating this process as a refinement until the desired level of optimization is reached.

It is evident where a local data cache (or instruction word memory) might be useful. Localized control over voltages is needed to apply a near perfect, uniform voltage, selectively turning it on and off when and where needed for specific qubits. If Boolean data defining the voltage signal waveform would be retrieved from room temp every time, that would at best make the whole process much less energy efficient (causing heat injection into the dilution refrigerator . . . phonon noise). However, if the voltage values for the voltage waveforms are advantageously obtained locally in the “low temperature” area (4.2 Kelvin cold space), the number of data connections and I/O data streams can be significantly decreased, making the system significantly more power efficient.

In different words, if voltage values (e.g., 8-bit digital-to-analog converter (DAC) inputs) can be stored locally, for use at a certain time and place, the values can be pulled from the local storage. This is more like a local data storage than anything else. In this case, one instance of a MM 100 can be used to define signals to control a set of qubits. Any solution for building waveforms and signals, which will be tailored to the system at hand and its underlying architecture, will benefit from in-memory logic operations that can transform a set of values and relationships into more individual and specific inputs to a general waveform generator.

A few common applications of a logic array, suitable to different levels of overall system complexity, include decompression of data, dynamic remote control, and automated system repair. None of the possible uses are exclusive to any size system; instead, these examples highlight the utility of a programmable logic array that can adapt to any size system, capabilities, and constraints.

A particularly simple application of a PLA would be to decompress stored (or incoming) data. A well-design control system will not be expecting a random and unpredictable set of inputs but a an organized one with observable patterns. Any stream with a pattern can exploit the redundancy to reduce superfluous bits and/or replace predictable data with a check bit or check sum to ensure data integrity. For example, an array of logical qubits may all have an average additional offset in a voltage of the same amount. Decomposing the explicit values into an average and an offset from average may require less data store resources. A system that is sufficiently large will see a reduction in resources needed when the PLA that decompresses data is smaller than the memory resources needed to store all values individually and explicitly. This concept can be applied to both locally stored data or data streamed in through a room-temperature connection.

Along the same lines, a PLA may enable dynamic remote control of a system. Frequently used signals can be defined in a library stored at the cold device. Calling the signal from room temperature is then a matter of sending down the appropriate index for lookup in the library instead of a full (lengthy) control signal. The device on the cold side then decodes the index for the desired signal and generates it in situ. Taken to the logical conclusion, this is a way of building up a set of control words for higher level functionality of the system while leaving the details of the electrical signals within the system.

Customization for either the physical device in use or the use case of interest can be done once ahead of operation and then reused until a new use case or device is needed. In a similar application, if a large number of individual processing units all receive the same instructions but operate on different sets of data (a SIMD type of use), a PLA could operate as a control manager for the individual cores.

Finally, a PLA may be part of an internal data feedback loop. Mechanisms within the system to provide measurement data may send a result to the PLA, which could analyze it and take appropriate action. In any array with non-negligible failure rate, if the array units can be interchanged, spare units can be automatically activated to assume the role of the failed unit. This allows a separation of concerns, leaving detailed management of resources to the “hardware” while the overall use case and algorithm are managed externally (e.g., “software” operating at room temperature to control the overall behavior of the system). This is entirely similar to a hard drive controller automatically managing good and bad sectors of a hard drive without the need for the operating system of a computer to take on this task.

Returning to the discussion of quantum computing in general, it is important to understand what kind of operations can be done on qubits. Of particular importance, due to its utility as a known starting state, is creating “Bell” states out of pairs of qubits. This is done by coupling, exciting, and rotating (which for this discussion just means a certain voltage waveform extending for a certain amount of time) the qubits of interest. A generic algorithm may start with all qubits in such a state, or only some, intending to either create Bell states later or allow the yet-unused qubits to serve another purpose. In such an algorithm, every even qubit might be used to create a “Bell” state, while, with no voltage waveform applied, every odd qubit remains in the ground (|0>) state. Or, every qubit could be used to form an array of qubits in the “Bell” state. This kind of common and repeated operation can be a useful command to execute frequently. A PLA could receive a short command to do this, which would then execute other commands local to the array, ultimately sending voltage values to DACs, mixers, or any other electrical devices, each with their own unique values designed to excite each parametrically unique qubit to an identical “Bell” state (the uniqueness being recorded as the “acquired test data” noted earlier).

Another common step may be to measure the qubit state after a specific amount of time. “Measuring” may also involve applying the right voltage signal waveforms to couple qubits to readout devices. Again, the higher-level capability of readout can be defined as a command and the details of applying voltages left to the PLA. With the right voltage waveforms collected for the digital-to-analog and analog-to-digital converters of the qubits, the quantum computation entities 320 can be operated. If used for qubit control, any of the common qubit gates can be defined as a command to the PLA. Each one is ultimately applying voltages, but it is applying the right voltages for the right amount of time on each qubit (or coupler). All in all, with proper values stored as inputs to the control mechanisms and the desired commands stored as indices in a defined library, all gates and readout of interest can be reduced to a set of commands. This is the opposite of generating all signals explicitly at room temperature and sending down analog signals directly to qubits.

In view of the above, it can be seen that an MM 100 (or, in combination, principally with a cache) can be used much closer to the qubits (e.g., for storing up a single DAC value in each line and applying it for one cycle only, then moving on to the next) or much farther away from them (e.g., for higher level commands, like a gate operation). Given that instructions are shared between many qubits, the quantum control architecture (which involves 300 of FIG. 3A) is similar to a single-instruction, multiple data architecture of a CMOS computer.

### Classical Boolean Logic and the Dataflow

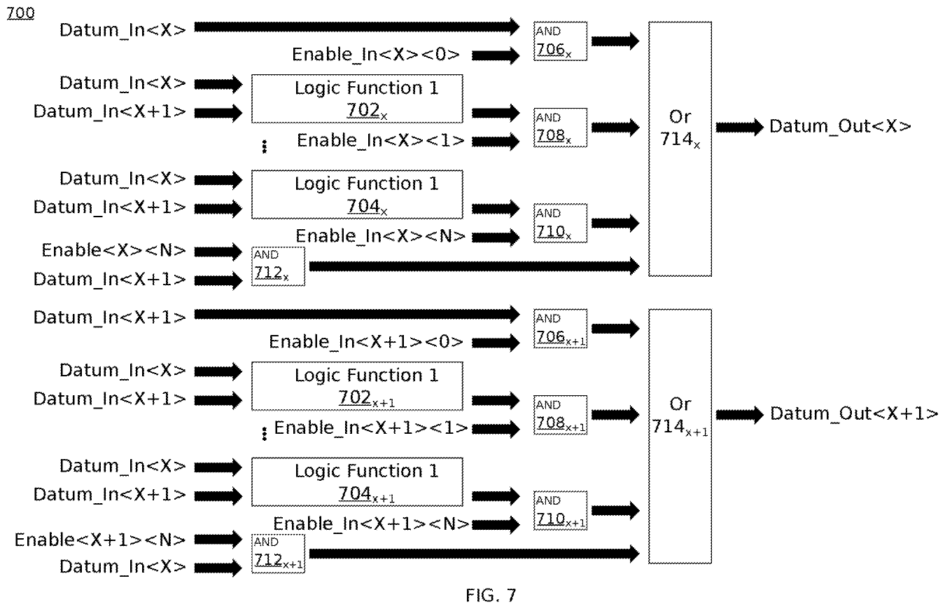

Returning now specifically to the discussion of the quantum computing system 300 of FIG. 3A, it can further include sparse logic 316 for at least one of increasing performance, reducing die area (achieving a higher compute density) and reducing power consumption. Such logic can include a wide OR, or NOR, of results, datum<1:M>_for_logic_OPS and datum<1:M>_for_memory_OPS, returning from the output bus circuit 108 possibly generated by multiple array enablements and modified by, for example the activation of nearest neighbor, or cycle sequenced, logic (to be discussed with respect to FIGS. 7, 9, 10, and 12). It can be fixed/hardwired or FPGA-like, in various embodiments, and can be configured to implement early branch resolution logic, as will be described with reference to FIG. 16.

Functioning as a central entity, the illustrative MM 100 shown in FIG. 1A can perform at any time (i) a memory read operation, (ii) a logic operation, or (iii) mixed memory and logic operations (simultaneously), returning data, Data<1:M> for_logic_OPS and Data<1:M> for_memory_OPS, to the “low temperature” logic entities 304. It should be appreciated that these outputs differ only slightly, primarily differentiated for conceptual purposes. In fact, in one or more embodiments, the control logic which drives the electable inverters 112 can provide control signals which configure the electable inverters 112 to perform only a buffer function. In such a case, outputs Data<1:M> for_logic_OPS and Data<1:M> for_memory_OPS are, functionally speaking, identical.

In general, exemplary logic operations of the quantum computing system 300 include: (i) data path/plane operations performed by quantum computation entities 320; (ii) data path/plane operations performed by the MM 100; (iii) data path/plane operations performed by “low temperature” logic entities 304; (iv) data path/plane operations performed by “room temperature” processing entities 302; (v) control path/plane operations performed by the collective entities 100, 304, 306, 308, 310, 312, 314, 316 in overseeing the data path/plane operations of the quantum computation entities 320; (vi) control operations performed by the collective entities 304, 306, 308, 310, 312, 314, 316 in overseeing the MM 100; (vii) control operations performed by the “room temperature” processing entities 302 in overseeing the collective entities 100, 304, 306, 308, 310, 312, 314, 316, 318, 320; and (viii) a system of feedbacks and acknowledgments among various entities after completing tasks.

The data path/plane operations performed by the illustrative quantum computing system 300 can be, for example, Boolean-based addition, comparisons, or multiplication, or can be Qubit-based wave function operations (parallel via superposition of entangled states) to realize, for example, Shor's algorithm (for factoring), Grover's algorithm (for sorting unstructured lists), and quantum Fourier transforms (QFTs). Considering the rich set of quantum computing technology alternatives (analog and digital/Boolean gate-like), the field of possibilities is numerous and therefore will not be fully described herein.

Attempting to optimize what operations are performed and within what entities (i.e., where) in the quantum computing system 300, for the lowest overall cost or for the greatest performance, involves consideration of intrinsic latencies, bandwidths, power consumptions, circuit yield, functional and environmental factors (e.g., necessary for quantum computation) of the various constituent entities, among other factors. Programmed/set for a window of time during which a particular algorithm is run, functions can be intertwined, the logic, memory, and mixed configurations, can be provided, in part, by the collective superconducting array cells 104, or, more generally speaking, by superconducting array cells 104 and FPGA superconducting elements. In fact, as already stated, a goal of this invention is to have circuits/entities serve roles for logic, memory, and mixed/combined operations. It is to be appreciated that the entities in the illustrative quantum computing system 300 are explicitly organized and generically named to convey the broad capabilities of various embodiments of the present invention.

Embodiments of the invention can be used in conjunction with known superconducting memories, or portions thereof, for beneficially improving the capabilities of such conventional superconducting memories, given their diverse specifications, with specialized entities adapted to address the unique attributes of each memory. An all-RF read path (i.e., radio frequency (RF) transmission line-based read path system) of JMRAM or PRAM advantageously has far lower latencies than an all RQL read path, but unfortunately can lower overall bandwidth (due to multi-flux quanta signaling, which requires flux pumps). These differences will be noted herein are not the subject of the present invention.

Embodiments of the inventive concept further seek to improve performance in light of extremely poor yields associated with conventional superconducting electronics. As opposed to modern CMOS chips, superconducting chips support only at least one hundred times fewer Boolean circuits. Just as in the case of the illustrative MM 100 shown in FIG. 1A, an important objective of embodiments of the invention is to establish multiple roles for the scarce circuitry that can be included on modern superconducting chips, given anticipated yield constraints of superconducting circuits and an inability to sufficiently scale superconducting circuits, due at least in part to London penetration depth requirements of superconductors. The term “sparse” as used in FIG. 3A is therefore intended to convey an objective of the invention to reduce cost and increase performance, all given realistic JJs-per-chip yields, exploiting the unique embodiments of the present invention and thus should not be considered limiting.

Portions of “quantum” algorithms, programs and applications can be processed in all temperature zones using various physical systems available at each temperature: Qubits (at milli-Kelvin), superconducting analog and digital circuits (less than or equal to 4.2 degrees Kelvin; liquid helium), potential intermediate stages CMOS bipolar (liquid nitrogen temperatures at 77 Kelvin), and CMOS and bipolar circuits (at “room temperature,” e.g., a range from about-50 to 100 degrees Celsius). In embodiments of the invention, the specific design of a hardware/application/algorithm across different physical systems, having different logic and memory circuits, is not emphasized. Rather, the entities, their capabilities and their interactions with the MM (e.g., MM 100 depicted in FIG. 1A), and among each other, are emphasized to describe unique embodiments and potential advantages of the invention.

“Low temperature” logic and memory management entities are named as such because they are likely to contain superconducting circuits such as RQL, but there is a reasonable possibly that they may contain CMOS circuits as well (two such example for Josephson magnetic FPGAs and JMPLAs are discussed in Appendix G). Much information regarding exact circuit choices (e.g., CMOS versus RQL) remains only conjecture at the moment, given the immature state of quantum computing. Thus, with respect to quantum computing system 300, the following principal elements according to one or more embodiments of the invention will each be discussed in broad detail (rather than discussing them as a more precise design like other embodiments, e.g. MM 100).

In general, the “low temperature” logic entities 304 can be directed to various purposes, such as, for example: (i) performing control; (ii) managing data pipelines of the MM 100; (iii) preparing data for use in the MM 100 (e.g., true/complement generation for WoDa<1:N> signals, determination of encoded “partial” address<1:?>, and, in concert with multiplexors 308 and 310, aligning signals on appropriate phases and RQL cycles); (iv) improving the compute efficiency of operations associated with the illustrative MM 100 and/or the quantum computation entities 320; and (v) operatively interacting with “room temperature” processing entities 302, quantum computation entities 320 and each other 304, among other functions.

“Low temperature” logic entities 304 include a true complement Boolean data generation logic 305 (i.e., inverters and buffers) that operatively sources the MM 100 with true complement data (WoDa<1:N>) to be processed by the logic enabled within 100. “Low temperature” logic entities 304 can further include sparse logic 316 that can perform logic functions so that a second pass through the MM 100, which is typically required for Boolean logic completeness, can be avoided. Avoiding a second pass can improve performance.

Multiplexor entities for word line address and/or data 308 can be just a simple multiplexor(s) that selects among logic operations, memory read operations, and mixed memory and logic operations for the MM 100. It can also be enhanced to include slightly more complex control signals which set specified bit ranges to logical “0s” (using AND gates, as known by those skilled in the art) to assure only a subset of rows in a location selected by multiplexor entities for encoded “partial” addresses 310 (decoder 114) can be activated/selected; in this row-zeroing-out mode (setting bit fields to logical “0s”), the multiplexor 308 can, for example, provide a secondary decode function to the decoder 114.

Multiplexor entities for encoded “partial” addresses 310 can be a simple multiplexor(s) that chooses array locations (e.g., arrays 102 in FIG. 1) where logic operations, memory read operations, and mixed logic and memory operations occur for the MM 100.

Memory read and write request buses 312 are highlighted as entities in the illustrative quantum computing system 300 depicted in FIG. 3A primarily for the conceptual purpose of indicating that the “low temperature” logic entities, owning instruction decode and execution pipelines are the master(s) of the “low temperature” memory management entities 306, which serve as their slaves (1) to retrieve data for operations, or (2) to store data for subsequent operations of all kinds (e.g., writing memory cells or setting programmable switches).

“Low temperature” logic and memory overlap entities 314 can include reservation tables for all operations occurring within the MM 100, in one or more embodiments. Such operations may involve arrays 102 of different column/output widths over a two-pass logic operation. It is important to note that two passes may be necessary to generate a complete Boolean function, as will be discussed in conjunction FIG. 5. In this scenario, either the first or second (or both) pass logic operations may generate fewer outputs than an array operation would typically generate. An array operation can gang together multiple arrays 102 that have fewer outputs for a logic operation to store and retrieve data from one unified memory location (involving a plurality of memory arrays 102). Moreover, located within 314, array built-in self-test (ABIST) and scan-based ABIST (e.g., scan chain can include elements for applying WoDas) can be used to test individual arrays 102 individually or as pluralities/collections depending on the logic and bus resources (e.g., output bus circuit 108) as known in the art.

In one or more embodiments, the sparse logic 316 can include at least one of the following: (i) Josephson FPGA (field programmable gate array) cells and interconnect for performing more customized bit-by-bit (i.e., bitwise) operations; or (ii) fixed logic functions for implementing frequently used functions. Sparse logic 316, in one or more embodiments, can include instruction-branch-partial-resolution logic, such as performing a comparison of only the high-order bits of two numbers involved in a conditional clause containing less than or greater than statements between two numbers/operands. If a branch cannot be resolved by such logic 318, a second pass can be executed.

Quantum computation entities 320 include a plurality of entangled qubits. Generally, interactions/communications among the quantum computation entities 320 and other entities (note that the interaction with the “low temperature” logic entities 304 is highlighted) involve complex analog electronics, represented here by A_to_D and D_to_A communication entities for Qubits 318. The “low temperature” logic entities can participate in control plane/path (e.g., quantum error correction code (QECC)) and data plane/path (e.g., Shor's algorithm for factoring, Grover's algorithm for searching an unordered list, and quantum Fourier transform (QFT) algorithm).

Logic operations, like OR functions, can be and are preferably performed in the output bus circuit 108 in the illustrative MM 100 shown in FIG. 1, by enabling two separate arrays 102 (Array A and Array B) simultaneously and, in part, by managing ranges of array outputs forwarded to the output bus circuit 108 using array-output circuit(s) 119 to be discussed with respect to FIG. 6 to selectively disable bit ranges.

FIG. 3B is a schematic diagram depicting at least a portion of an exemplary quantum computing system 350 that includes elements adaptable to implement control and data path/plane logic, elements partially enabled by compound MMs 100 of FIG. 1, that are necessary to process mixed quantum and classical/Boolean algorithms, according to one or more embodiments of the invention.

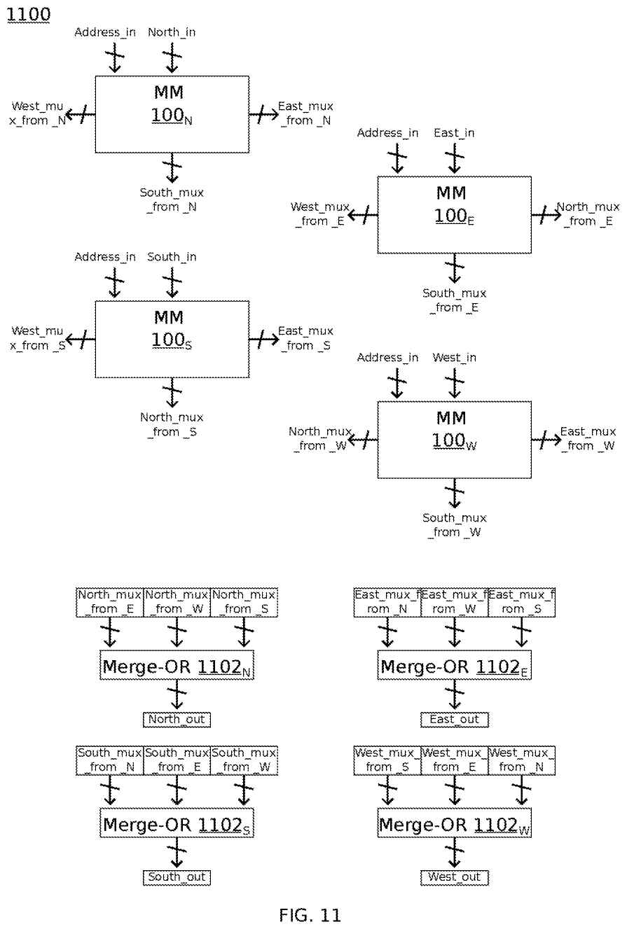

It should be noted that the differences between FIGS. 3A and 3B include (i) only shows superconducting layer (labeled “low temperature”) and (ii) one array 102 of an MM 100 drives another array 102 of an MM (some embodiments through an intervening circuit 330). The latter—one array driving another—is the only important difference with respect to the one or more embodiments of the present invention. Taken further than can be depicted in FIG. 3B, where the MM 100 drives other MMs 100, which drive yet other MMs 100, and so on, a mesh network can be formed, the structure and operation of which will be discussed in further detail with reference to FIG. 11.

As previously discussed, in FIG. 3B, it is important to realize that a write operation can be directed by underlying circuits to write a column, rather than a row, of an array while, for the same array, a read operation can be directed to one or more WoDas (enabling rows). This underlying unique read-write orientation forms the basis for the match array, or first array of a first MM(s)_A 100, in a content addressable memory (CAM). Known as a data array, a second array 102 of a second MM(s)_B 100 can be driven by the match array to form a complete CAM.

FIG. 4 is a block diagram depicting at least a portion of an exemplary logic implementation 400 (e.g., a reciprocal quantum logic (RQL) implementation) of an electable inverter (EI) 112 included in the illustrative MM 100 of FIG. 1, according to one or more embodiments of the invention. With reference to FIG. 4, the exemplary electable inverter logic schematic 400 includes an AnotB (AB) gate 402 (from the RQL family of logic circuits), an AND gate 404, and an OR gate 406. A first input of the AnotB gate 402 is inverted and adapted to receive an input signal, IN, supplied thereto, a second input of the AnotB gate 402, which is non-inverted, is adapted to receive a Pass 1 control signal, and an output of the AnotB gate 402 is connected to a first input of the OR gate 406. A first input of the AND gate 404 is adapted to receive the input signal IN, a second input of the AND gate 404 is adapted to receive a Pass 2 control signal, and an output of the AND gate 404 is connected to a second input of the OR gate 406. OR gate 406 is connected to an output OUT.

The electable inverter 400 can function as a buffer or as an inverter, or can output “0s.” To invoke inversion during an exemplary Pass 1 of the MM 100, the Pass 1 control signal is set to a logic “1” and the Pass 2 control signal is set to a logic “0.” To invoke buffering during an exemplary Pass 2 of the MM 100, the Pass 2 control signal is set to a logic “1” and the Pass 1 control signal is set to a logic “0.” Otherwise, when logic operations are not active, the electable inverter 400 can be beneficial to reduce power consumption by setting both Pass 1 and 2 control signals to “0,” which saves energy in generating and propagating the signals associated with the control inputs (e.g., Pass 1 and Pass 2), in computing the signal driven through the output “Out,” and in propagating any “1s” of “Out” to downstream logic.

FIG. 5 is a first logic block diagram 500 that is used to explain how two passes through the illustrative MM 100 of FIG. 1 (as overseen by the exemplary quantum computing system 300 of FIG. 3) enables the generation of a universal Boolean expression, according to one or more embodiments of the invention. Although there is no theoretical limit to the size of the Boolean expression that can be handled by embodiments of the invention, the actual size of the Boolean expression will be bounded by the size of the arrays 102 in the MM 100 of FIG. 1. The logic flow diagram 500 for generating a universal Boolean expression includes true/complement (T/C) generation for Boolean terms 305, pass 1 logic representation 502 (of the MM 100, wherein data inversion is enabled), pass 2 logic representation 504 (of the MM 100, wherein data buffering is enabled).

Represented as glue logic circuits 506, the exemplary logic flow diagram 500 to generate a universal Boolean expression further includes “low temperature” logic entities 304, multiplexor entities for word line address and/or data 308, multiplexor entities for encoded “partial” addresses 310 (all entities 304, 308, 310 can be represented as glue logic circuits 506 in FIG. 5) disposed between pass 1 logic representation 502 and pass 2 logic representation 504 for the purpose of routing/returning signals (on appropriate RQL cycles) to the MM 100.

It is important to recognize that, as the “key” in FIG. 5 indicates, the box labelled “PS” for programmable switch 508 represents the superconducting cell 104 (MC/PS/FS) of FIG. 1. These programmable switches (PS) 508 are responsible for assembling a desired logic circuit from a programmable Boolean logic circuit, as will be understood by those skilled in the art.

When De Morgan's Law 510 (for an OR_not transform) is applied, it can be seen that pass 1 and pass 2 logic representations 502 and 504, respectively, can be represented with AND gates 512, OR gate 514, and inversion bubbles 516. In combination with T/C generation for Boolean “data” terms 305, the aforementioned resulting logic forms a universal Boolean expression. It should be noted that the labeling of logic gates 106, 110, 112 from FIG. 1 has been provided, for those skilled in the art, to aid in understanding the actual logic of the MM logic 100, traversed in each pass (phase) 502, 504.

Addressing the inverter bubbles 516, positioned just before the AND gates 512, it should be noted that inversions actually result from the transform 510 applied to combinations of OR gates 106 and 110, in one or more embodiments. Moreover, it should be noted that the programmable switches (PS) 508, situated in front of AND gates 512 and OR gate 514, provide the programmability of the logic.

The embodiment of the logic flow diagram 500 to generate a universal Boolean function should be considered illustrative rather than limiting. Other significant, but intermediate, manipulations of data at the output of multiplexors 308 and arrays 102, for example, can be beneficial as has been discussed already in connection with some embodiments of the invention. Moreover, pass1 ORing and pass 2 ANDing can be enabled by configuring the electable inverters 112 as buffers in pass1 and then as inverters in pass 2, respectively. In general, N pass traversals can occur (where Nis an integer ranging from 1 to an extremely large number/infinity) to form a prescribed logic expression or, perhaps, co-mingling logic operations with memory operations, to implement a prescribed algorithm.

It should be further understood that the exemplary block diagram 500 depicted in FIG. 5 only pertains to one logic function located (addressed) in the illustrative MM 100 of FIG. 1. As will be discussed further herein below, different addressing schemes (such as, for example, link-based schemes) can assemble (i.e., stitch together) various memory and/or logic operations into a cohesive algorithm.

FIG. 6 is a schematic diagram depicting at least a portion of an exemplary array output circuit 600, known in the art. Broadly stated, an array output circuit 600 can receive outputs of an array (e.g., array 102 shown in FIG. 1) from column lines (i.e., bit lines or data lines) that are represented by OR gates within it (e.g., OR gate 106 of FIG. 1) into its data inputs, such as, for example, a pair of data inputs represented by “Datum_In<1>” and “Datum_In<2>” of each array output circuit 600. In general, each array output circuit 600 includes at least one of (i) a multiplexing circuit, (ii) a time-division multiplexing (TDM) circuit, and (iii) a non-controlling output generation circuit (non-controlling for subsequent (downstream) logic gates).

Assuming the Datum_Out<1> signal from an upstream array(s) is a logic “0” (given that the upstream arrays are disabled from generating data in the pipeline for the cycle(s) under consideration), specified control signal settings will trigger the following exemplary behavior(s) of the array-output circuit 600 noted in the MM 100 as 119:
[1] For the cycle(s) of interest, setting Enable<1>, Enable_TDM<2>, and Enable<2> control signals all equal to logic “0” drives Datum_Out<1> to logic “0,” which is a non-controlling state for downstream logic (e.g., OR gate 110 within the output bus circuit 108 shown in FIG. 1);
[2] For the cycle(s) of interest, setting Enable<1> and Enable_TDM<2> control signals both equal to logic “1,” and Enable<2> control signal to logic “0,” serves (i) to feed the datum (from the output of array 102 of FIG. 1) provided to input Datum_In<1> on cycle N to output Datum_Out<1> on cycle N, where N represents an arbitrary input data cycle, and (ii) to feed the datum (from the output of array 102 of FIG. 1) provided to input Datum_In<2> on cycle N to output Datum_Out<1> on cycle N+1;
[3] For the cycle(s) of interest, setting Enable<1> signal equal to logic “1,” and both Enable<2> and Enable_TDM<2> signals equal to logic “0,” serves to feed the datum (from the output of array 102 of FIG. 1) provided to input Datum_In<1> on cycle N to output Datum_Out<1> on cycle N, where N represents an arbitrary cycle;
[4] For the cycle(s) of interest, setting Enable<1> and Enable_TDM<2> signals both equal to logic “0,” and Enable<2> signal equal to logic “1,” serves to feed the datum (from the output of array 102 of FIG. 1) provided to input Datum_In<2> on cycle N to output Datum_Out<1> on cycle N, where N represents an arbitrary cycle;
[5] For the cycle(s) of interest, setting Enable_TDM<2> signal equal to logic “1,” and both Enable<1> and Enable<2> signals equal to logic “0,” serves to feed the datum (from the output of array 102 of FIG. 1) provided to input Datum_In<2> on cycle N to output Datum_Out<1> on cycle N+1. This one-cycle delay function of only “Datum_In<2>” (and not “Datum_In<1>,” which would require additional gates) may not appear to be advantageous at first glance, but when data alignment in cycles (e.g., for data field bit concatenation among and within arrays 102 and/or for specific pipeline latencies of circuitry/logic resident in “low temperature” logic entities 304 of FIG. 3) is considered, such unique control scenarios may be desired for actual chip designs).

Collectively, exemplary behaviors [3] and [4] of the array-output circuit 600 embody multiplexing. As opposed to time division multiplexing (TDM), which preserves data in data beats across cycles (for this example, two cycles), traditional multiplexing, such as described by the combination of behaviors [3] and [4], discards a subset of the data. In this exemplary array-output circuit 600, half the data is lost if multiplexor requests are enabled.

It is also important to recognize that column-oriented address logic (multiplexors) serves to enable a second form of address decoding for arrays. As implemented by the array output circuit(s) 600 (119), these circuits can select various sets of columns of data, being sourced form one or more arrays 102 in a MM 100, for output as will be discussed with respect to bit slice output dataflows of FIGS. 10 and 12.

Under the oversight of instructions, which implement a certain computer architecture corresponding to a particular program, control logic (which drives, for example, signals Enable<1>, Enable<2>, Enable_TDM<2> in the illustrative array-output circuit 600 shown in FIG. 6) preferably coordinates appropriate time-based actions in buses and arrays to support, in general, read requests and logic processing requests that support computation according to the prescribed computer architecture. Such instruction oversight, often referred to as “computer microarchitecture,” prevents, for example, collisions among separate requests from colliding in time on a bus where, if such collisions were to occur, would undesirably destroy the data of the separate requests (e.g., ORed together in output bus circuit 108 of FIG. 1).

Neighbor-to-neighbor two-input even-odd data flow operations include, for example, those associated with RQL. Two-input logic includes, for example, AND, OR, XOR (a composite function of RQL AndOr and RQL AnotB), RQL AndOr, RQL AnotB gates.

FIG. 7 is a schematic diagram depicting at least a portion of a programmable-neighbor-to-neighbor-data-flow circuit, according to one or more embodiments of the invention. Broadly stated, a nearest neighbor logic circuit 700, in one or more embodiments, receives two data flow inputs and either transforms them with two-input logic functions (driving them to either odd or even datum bit path), swaps them (between odd and even data bit paths), or forwards them unchanged reincorporating them (even and odd bits) back into the same physical data-flow pipeline. In the cases where functional transformations occur, the at least one output can be routed to either of the two downs stream outputs corresponding to the two inputs.

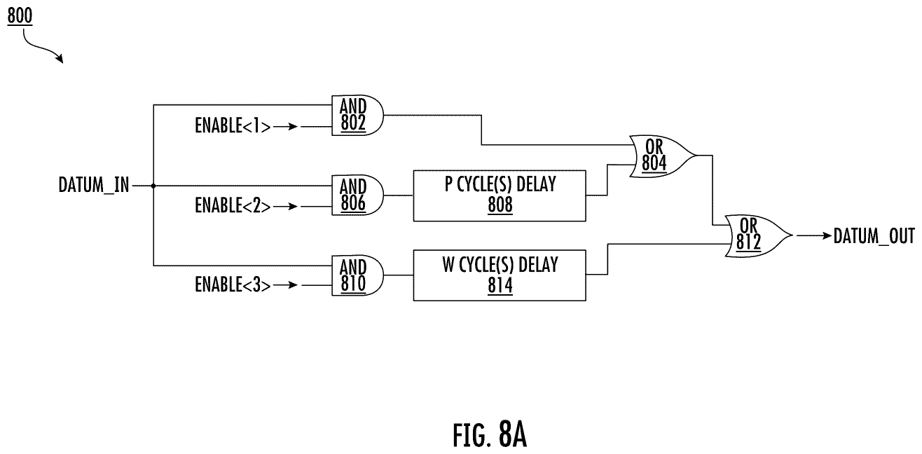

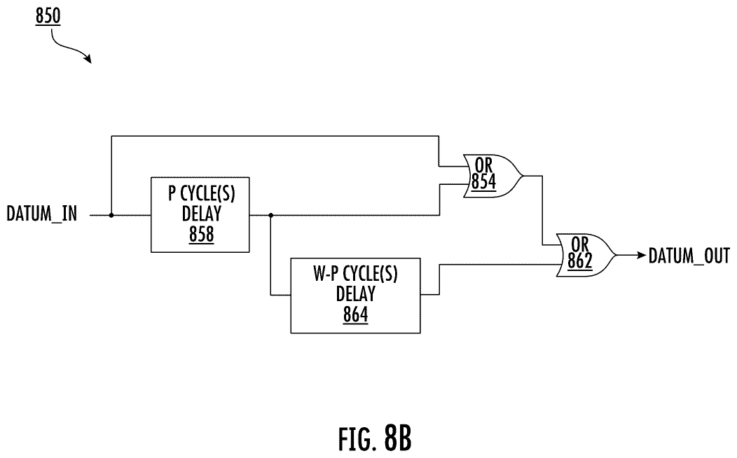

FIG. 8A is a schematic diagram depicting at least a portion of an exemplary programmable copy delay circuit 800, according to one or more embodiments of the invention. Broadly stated, the programmable copy delay circuit 800, in one or more embodiments, receives a signal at its input Datum_In, delays the signal for a control-signal-designated-number of cycles (e.g., RQL cycles), which can range from none to a large number depending on the circuit topology of 800, and, after the cycles have elapsed, outputs the signal at its output Datum_Out. The control signals are shown as Enable<1:3>. While typical scenarios would have one such control signal asserted high (“1”) at a time, it should also be understood that multiple control signals can be high at a time creating more than one delayed version of the signal in a pipeline flow, useful to feed downstream pipelines having different relative latency requirements for their incoming data as will be discussed with respect to FIG. 10.

Referring to FIG. 8A, a minimum RQL logic representation of the exemplary programmable copy delay circuit 800 includes a first AND gate 802, a first OR gate 804, a second AND gate 806, a P cycle delay module 808, where P is an integer, a third AND gate 810, a second OR gate 812, and a W cycle delay module 814, where W is an integer. Specifically, AND gate 802 includes a first input adapted to receive the Datum_In input signal and a second input adapted to receive a first enable signal, Enable<1>. AND gate 806 includes a first input adapted to receive the Datum_In input signal and a second input adapted to receive a second enable signal, Enable<2>. AND gate 810 includes a first input adapted to receive the Datum_In input signal and a second input adapted to receive a third enable signal, Enable<3>.

An output of the AND gate 802 is supplied to a first input of OR gate 804, and an output of AND gate 806 is delayed by the P cycle delay module 808 before being supplied to a second input of the OR gate 804. An output of OR gate 804 is supplied to a first input of OR gate 812. An output of the AND gate 810 is supplied to an input of the W cycle delay module 814 before being supplied to a second input of the OR gate 812. An output of the OR gate 812 generates the Datum_Out signal.

The following exemplary application of control signals is illustrative, but not limiting, of an exemplary behavior of the programmable copy delay circuit 800:
[1] For the cycle(s) of interest, setting Enable<1>, Enable<2>, and Enable<3> control signals all equal to logic “0” drives Datum_Out to logic “0,” which is a non-controlling state for downstream logic;
[2] For the cycle(s) of interest, setting Enable<1> signal equal to logic “1,” and both Enable<2> and Enable<3> signals equal to logic “0,” serves to feed the datum provided to input Datum_In on cycle N to output Datum_Out also on cycle N, where N represents an arbitrary cycle;
[3] For the cycle(s) of interest, setting Enable<2> signal equal to logic “1,” and both Enable<1> and Enable<3> signals equal to logic “0,” serves to feed the datum provided to input Datum_In on cycle N to output Datum_Out on cycle N+P, where N represents an arbitrary cycle and P is an integer associated with the P cycle delay module 808;
[4] For the cycle(s) of interest, setting Enable<1> and Enable<2> control signals both equal to logic “1,” and Enable<3> control signal to logic “0,” serves (i) to feed the datum provided to input Datum_In on cycle N to output Datum_Out on cycle N, where N represents an arbitrary input data cycle, and (ii) to feed the datum provided to input Datum_In on cycle N to output Datum_Out on cycle N+P, where N represents an arbitrary cycle and P is an integer associated with the P cycle delay module 808; and
[5] For the cycle(s) of interest, setting Enable<1>, Enable<2>, Enable<3> control signals all equal to logic “1,” serves (i) to feed the datum provided to input Datum_In on cycle N to output Datum_Out on cycle N, where N represents an arbitrary input data cycle, and (ii) to feed the datum provided to input Datum_In on cycle N to output Datum_Out on cycle N+P, where N represents an arbitrary cycle and P is an integer associated with the P cycle delay module 808, and (iii) to feed the datum provided to input Datum_In on cycle N to output Datum_Out on cycle N+W, where W represents an arbitrary cycle and P is an integer associated with the P cycle delay module 808.

FIG. 8B is a schematic diagram depicting at least a portion of an exemplary copy delay circuit 850, according to one or more embodiments of the invention. Broadly stated, the copy delay circuit 850, in one or more embodiments, receives a signal at its input Datum_In, delays the signal for a control-signal-designated-number of cycles (e.g. RQL cycles), which can range from none to a large number depending on the circuit topology of 850, and, after the cycles have elapsed, outputs the signal at its output Datum_Out.

For the cycle(s) of interest, fixed copy delay circuit 850 serves (i) to feed the datum provided to input Datum_In on cycle N to output Datum_Out on cycle N, where N represents an arbitrary input data cycle, and (ii) to feed the datum provided to input Datum_In on cycle N to output Datum_Out on cycle N+P, where N represents an arbitrary cycle and P is an integer associated with the P cycle delay module 808, and (iii) to feed the datum provided to input Datum_In on cycle N to output Datum_Out on cycle N+W, where W represents an arbitrary cycle and P is an integer associated with the P cycle delay module 808.

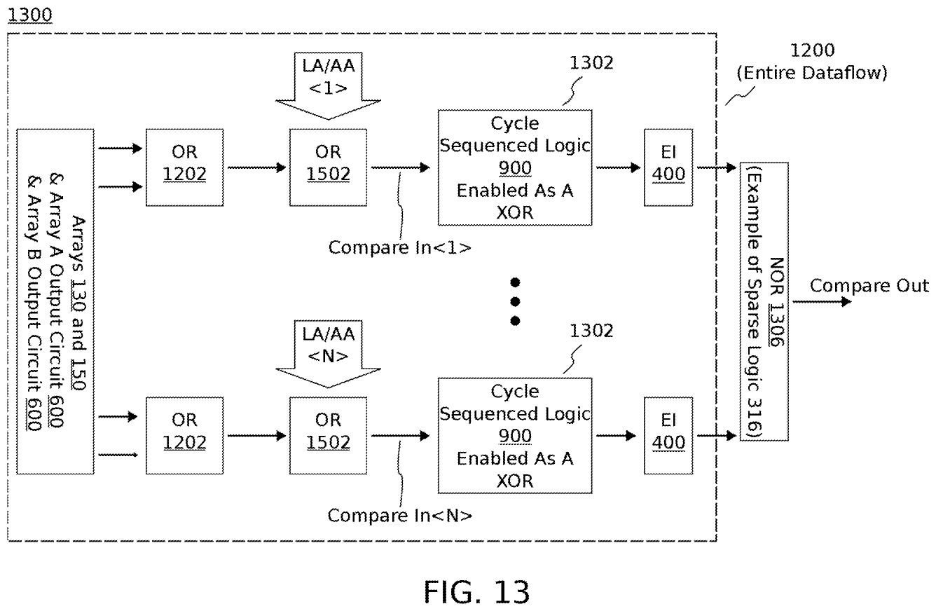

FIG. 9 is a schematic diagram depicting at least a portion of an exemplary cycle sequenced logic circuit 900, according to one or more embodiments of the invention. Each exemplary 2-input gate included in the cycle sequenced logic circuit 900 may have an N-cycle(s) delay element 902 disposed between its two terminals. Similar to the nearest neighbor logic, it can support many two-input functions, including XORs, ANDs, etc. Two-input even-odd data flow operations include, for example, those associated with RQL. Two-input logic includes, for example, AND, OR, XOR (a composite function of RQL AndOr and RQL AnotB), RQL AndOr, RQL AnotB gates. As will be discussed with respect to FIGS. 12 and 13 (wide NOR), data produced by a first read of an array can be compared with data produced by a second read by electing a 2-input XOR function.

FIG. 10 is a diagram conceptually depicting at least a portion, which may be referred to herein as a bit slice, of an exemplary array output data flow 1000, according to one or more embodiments of the invention. The array output data flow 1000 may include, for example, array output circuits 600, OR gates 1002, programmable copy delay circuits 800, nearest neighbor logic 700, and elective inverters 400, among other circuit or dataflow elements. It is important to understand that one or more dataflow elements in the bit slice of the exemplary array output data flow 1000, which is meant to be illustrative only, can be reordered in terms of their flow to achieve desired logic requirements of a system implementation, in accordance with embodiments of the present disclosure.

It is also important to recognize that column-oriented address logic (e.g., multiplexors) serves to enable a second form of address decoding for arrays. The array output data flow 1000 of FIG. 10 may include a plurality of array output circuits 600; specifically, a first plurality of array output circuits 600, array_A output circuits, connected to corresponding column lines in array_A 102A, and a second plurality of output array circuits 600, array_B output circuits, connected to corresponding column lines in array_B 102B. Each of the array output circuits 600 may comprise a time-division multiplexing (TDM) circuit, in one or more embodiments.

In one or more embodiments, a first one of the first plurality of array output circuits 600 may be connected to a first pair of adjacent column lines, <x> and <x+1> (where x is an integer), in array_A 102A, and a second one of the first plurality of array output circuits 600 may be connected to a second pair of adjacent column lines, <x+2> and <x+3>, in array_A. Likewise, a first one of the second plurality of array output circuits 600 may be connected to a first pair of adjacent column lines, <x> and <x+1>, in array_B 102B, and a second one of the second plurality of array output circuits 600 may be connected to a second pair of adjacent column lines, <x+2> and <x+3>, in array_B. The first pair of adjacent column lines in each array 102A, 102B may be considered to be associated with an “even” bit slice, and the second pair of adjacent column lines in each array 102A, 102B may be considered to be associated with an “odd” bit slice.

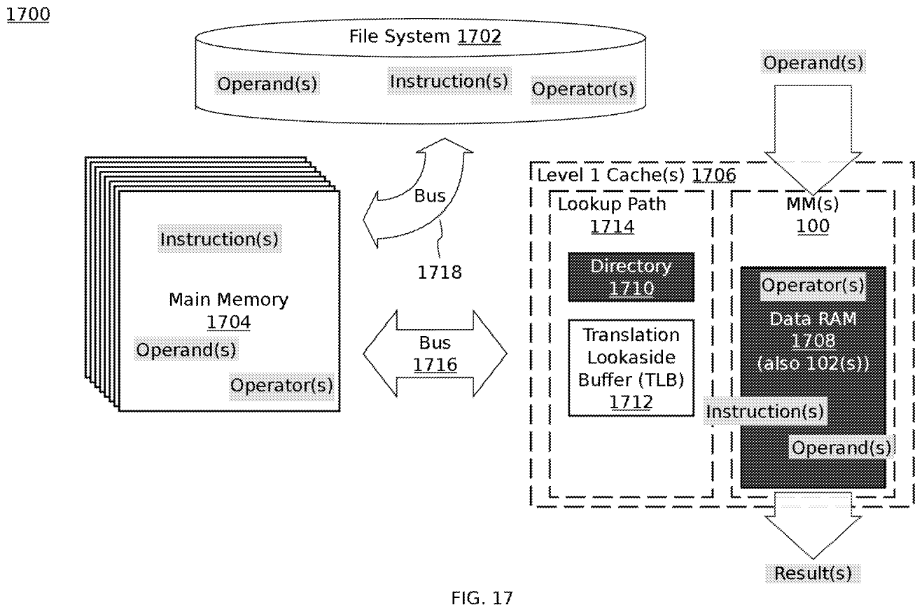

Each of the array output circuits may be configured to select at least a given one of the corresponding column lines to which it is connected as a function of one or more enable signals supplied thereto. For example, the first one of the first plurality of array output circuits 600 may be configured to receive a first set of one or more enable signals, ens_A<0,1>, the second one of the first plurality of array output circuits 600 may be configured to receive a second set of one or more enable signals, ens_A<2,3>, the first one of the second plurality of array output circuits 600 may be configured to receive a third set of one or more enable signals, ens_B<0,1>, and the second one of the second plurality of array output circuits 600 may be configured to receive a fourth set of one or more enable signals, ens_B<2,3>. In one or more embodiments, the enable signals ens_A<0,1>, ens_A<2,3>, ens_B<0,1>, ens_B<2,3> may comprise “control bits” in a corresponding dataflow outside the array 102. Exemplary control bits will be discussed in the cache section with reference to FIGS. 17 through 21. In this manner, the first and third sets of control signals may be used to select the first pair of adjacent column lines <x>, <x+1> in the even bit slice of array_A and array_B, respectively, and the second and fourth sets of control signals may be used the second pair of adjacent column lines <x+2>, <x+3> in the odd bit slice of array_A and array_B, respectively.

Outputs of each of the array output circuits 600 configured to select the first pairs of adjacent column lines <x>, <x+1> in array_A 102A and array_B 102B may be supplied to corresponding inputs of a first one of the OR gates 1002, which may correspond to the even bit slice. Similarly, outputs of each of the array output circuits 600 configured to select the second pair of adjacent column lines <x+2>, <x+3> in array_A 102A and array_B 102B may be supplied to corresponding inputs of a second one of the OR gates 1002, which may correspond to the odd bit slice.

Outputs of the OR gates 1002 may be supplied to corresponding programmable copy delay (PCD) circuits 800. More particularly, an input of a first PCD circuit 800, which may be associated with the even bit slice, is preferably configured to receive an output of the first (even) OR gate 1002, and a second PCD circuit 800, which may be associated with the odd bit slice, is preferably configured to receive an output of the second (odd) OR gate 1002. Each of the PCD circuits 800 is preferably configured to generate an output signal that is a delayed copy of the input signal supplied thereto, as a function of one or more corresponding enable signals supplied thereto. The first PCD circuit 800 may be configured to receive a first set of one or more PCD enable signals, ens_even PCD, and the second PCD circuit 800 may be configured to receive a second set of one or more PCD enable signals, ens_odd PCD. In one or more embodiments, an amount of delay generated by the PCD circuits 800 may be controllable based on the PCD enable signals.

Respective outputs generated by the PCD circuits 800 may be supplied to corresponding inputs of the nearest neighbor logic (NNL) 700. The nearest neighbor logic 700, in one or more embodiments, is preferably configured for implemented 2-inupt logic operations (such as a XOR) as a function of one or more enable signals supplied thereto. Specifically, the nearest neighbor logic 700 may be configured to receive a first set of one or more enable signals, ens_even NNL, and a second set of one or more enable signals, ens_odd NNL, for selecting, as an output of the nearest neighbor logic 700, a nearest neighbor in the even bit slice or a nearest neighbor in the odd bit slice, respectively; the nearest neighbor output for the even bit slice is selected by setting the ens_even NNL enable signal(s) to an appropriate level or data pattern, and likewise the nearest neighbor output for the odd bit slice is selected by setting the ens_odd NLL enable signals(s) to an appropriate level or data pattern.

The outputs of the nearest neighbor logic 700 may be supplied to corresponding inputs of the elective inverters (EI) 400. Each of the elective inverters 400 may be configured to generate a corresponding datum output as a function of an enable signal(s) supplied thereto. Specifically, the elective inverter 400 associated with the even bit slice is preferably configured to generate an output datum, Datum<Z>_for_logic_OPS, as a function of a corresponding enable signal, ens_even EI, supplied thereto, and the elective inverter 400 associated with the odd bit slice is preferably configured to generate an output datum, Datum<Z+1>_for_logic_OPS, as a function of a corresponding enable signal, ens_odd EI, supplied thereto.

FIG. 11 is a block diagram depicting at least a portion of an exemplary north-south-east-west network element 1100, which may be utilized in a superconducting system for performing logic, memory, and/or mixed logic and memory operations according to one or more embodiments of the invention. With reference to FIG. 11, the network element 1100 comprises a plurality of superconducting array circuits, namely, a “north” superconducting array circuit 100_{N}, a “south” superconducting array circuit 100_{N}, an “east” superconducting array circuit 100_{E}, and a “west” superconducting array circuit 100_{W}. Each of the superconducting array circuits 100_{N}, 100_{S}, 100_{E}, 100_{W}, which may be implemented in a manner consistent with the illustrative superconducting array circuit 100 shown in FIGS. 1A-1C, preferably includes an address input port adapted to receive an address input signal, Address_In, and a data input port, adapted to receive data from a respective one of the north, south east or west superconducting arrays circuits 100_{N}, 100_{S}, 100_{E}, 100_{W}, depending on where the particular superconducting array circuit is located in the network.

Each of the superconducting array circuit further includes a plurality of output ports connected to corresponding multiplexers in the network. More particularly, the north superconducting array circuit 100_{N} includes a first output port, West_mux_from_N, a second output port, South_mux_from_N, and a third output port, East_mux_from_N. The north superconducting array circuit 100_{N} is configured to pass received data from its input data port, North_in, to a given one of its output ports as a function of the Address_in signal supplied to its address input port. The south superconducting array circuit 100_{S} includes a first output port, West_mux_from_S, a second output port, North_mux_from_S, and a third output port, East_mux_from_S. The south superconducting array circuit 100_{S} is configured to pass received data from its input data port, South_in, to a given one of its output ports as a function of the Address_in signal supplied to its address input port. The east superconducting array circuit 100_{E} includes a first output port, West_mux_from_E, a second output port, South_mux_from_E, and a third output port, North_mux_from_E. The east superconducting array circuit 100_{E} is configured to pass received data from its input data port, East_in, to a given one of its output ports as a function of the Address_in signal supplied to its address input port. Likewise, the west superconducting array circuit 100_{W} includes a first output port, North_mux_from_W, a second output port, South_mux_from_W, and a third output port, East_mux_from_W. The west superconducting array circuit 100_{W} is configured to pass received data from its input data port, West_in, to a given one of its output ports as a function of the Address_in signal supplied to its address input port. The north-south-east-west-network element 1100 can preferably support more than one non-conflicting_transaction concurrently (e.g., north to south, south to north, east to west, and west to east).

The network element 1100 further includes a plurality of merge OR circuits 1102. Each of the merge OR circuits is configured to generate an output as a function of logical sum of the signals applied to its inputs. Specifically, a first merge OR circuit, which may be a “north” merge OR circuit 1102N, is configured to receive, as inputs, output signals generated by the superconducting array circuits 100_{S}, 100_{E}, 100_{W}, for a “north” multiplexer, North_mux_from_E, North_mux_from_W and North_mux_from_S, and to generate, as an output, a North_out signal. A second merge OR circuit, which may be a “south” merge OR circuit 1102s, is configured to receive, as inputs, output signals generated by the superconducting array circuits 100_{N}, 100_{E}, 100_{W}, for a “south” multiplexer, South_mux_from_N, South_mux_from_E and South_mux_from_W, and to generate, as an output, a South_out signal. A third merge OR circuit, which may be a “east” merge OR circuit 1102E, is preferably configured to receive, as inputs, output signals generated by the superconducting array circuits 100_{N}, 100_{S}, 100_{W}, for an “east” multiplexer, East_mux_from_N, East_mux_from_W and East_mux_from_S, and to generate, as an output, an East_out signal. Likewise, a fourth merge OR circuit, which may be a “west” merge OR circuit 1102w, is preferably configured to receive, as inputs, output signals generated by the superconducting array circuits 100_{N}, 100_{S}, 100_{E}, for a “west” multiplexer, West_mux_from_S, West_mux_from_E and West_mux_from_N, and to generate, as an output, a West_out signal. As shown in FIG. 11, a programmable switch setting (one per column set to “1”) in each of the memory cells (104 in FIGS. 1B-1C) in the superconducting arrays (102A, 102B in FIGS. 1B-1C) may be configured to route WoDa signals to corresponding Data Out lines according to the region selected by the partial address. Data Out lines may be divided into three sets, each associated with an egress direction.

The MM 100 can, for example, be used as a mesh network routing element 1100 in a networking system receiving data from any first direction, either North, South, East, or West, and sending the data along at least one of a set of second directions, North, South, East, and West, the at least one second direction being notably not the first. The data from the first direction is applied to the WoDa inputs, the Data_for_logic_OPS is divided into three outputs corresponding to the set of possible second directions (in this exemplary planar network). Each address selects a region (which in this instance includes a partial encoded address, an array 102 enable address, and possibly a column address).

FIG. 12 is a schematic depicting a portion (bit slice) of an exemplary array output data flow, which can include array output circuits 600, OR gates 1052, cycle sequenced logic 900, and elective inverters 400, according to one or more embodiments of the invention. It is important to understand that the dataflow elements in the exemplary bit slice, which is meant to be illustrative only, can be reordered in terms of their flow to achieve desired logic requirements of a system implementation.

The term sparse logic (e.g., sparse logic 316 in FIGS. 3A-3B) connotes the use of little logic. Sparse logic 316 has to be very useful logic, particularly for superconducting circuits, which are orders of magnitude larger than CMOS circuits.

FIG. 13 is a schematic featuring an embedded comparator that includes XOR 1302 and NOR 1306 for function, other logic principally buffers.

While the logic for bit field comparisons is known in the art, bit field comparisons (by comparators), useful for the lookup path which will be discussed with reference to FIG. 17, are enabled by 2-input XORs of cycle sequenced logic 900.

High-bandwidth passive transmission line (PTL) circuits are particularly well-suited for the low latency distribution of control signals (described as enables), which typically have wide fan-outs that steer many bits of data flow logic.

A common limitation in current superconducting logic technologies is the distance SFQ pulses can travel before being captured and retransmitted. This limitation arises in different contexts and for different reasons. A common solution would be to transmit the signal along a PTL, rather than an active JTL; this makes sense when the resources for changing from JTL to PTL, and back again, are less than the resources required to actively transmit the same signal. However, this adds a new limitation, in that there is a limited bandwidth of the PTLs, often associated with the “charge time” for building up a signal for a PTL (actually what is storing flux quanta; in practice this is the time required to build up a multi-SFQ signal). Generally, PTLs can only take one flux quantum at a time, and therefore PTLs take time to recover. Embodiments of the invention beneficially provide a solution to this PTL “recovery” issue, and therefore are able to achieve increased bandwidth while minimizing resource usage.

In an extreme solution, a single signal could be split to N different PTL drivers, where N is the number of clock cycles required to ready a PTL driver. In this way, the bandwidth of the PTLs collectively would match that of the incoming line, at the cost of a large amount of PTLs and corresponding PTL drivers. In more practical terms, such long-distance signals are more likely to be less frequent, for example a single synchronization bit every 64 cycles. In such cases, a similar round-robin approach can be used with far fewer resources. Of course, ultimately the amount of resources needed will generally be dictated by the requirements of the rest of the system.

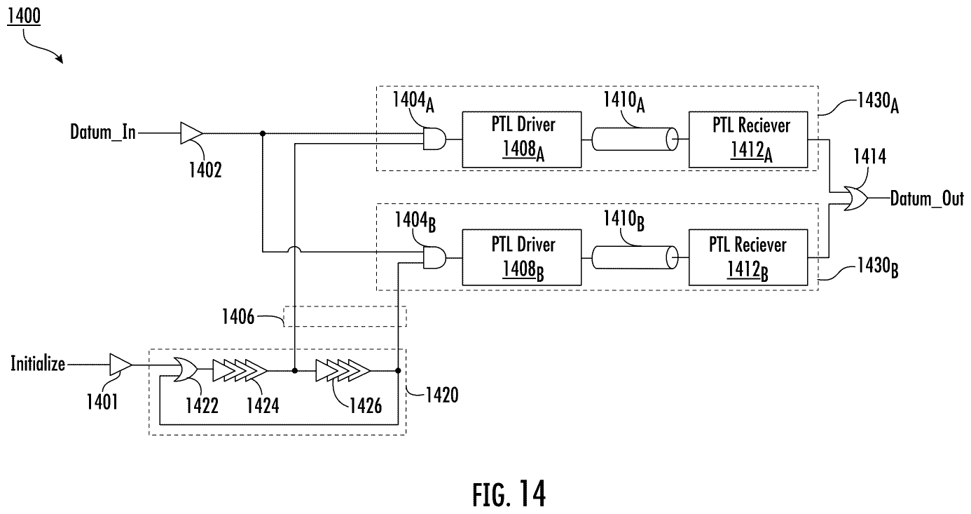

FIG. 14 is a schematic diagram depicting at least a portion of an exemplary PTL distribution circuit 1400, according to one or more embodiments of the invention. The PTL distribution circuit 1400 may include a plurality of PTL circuits, 1430_{A} and 1430_{B}, a delay circuit 1420, and some logic circuitry. Although only two PTL circuits 1430_{A}, 1430_{B} are shown, it is to be appreciated that embodiments of the invention are not limited to any specific number of PTL circuits.

With continued reference to FIG. 14, a first one of the PTL circuits, 1430_{A}, may include an AND gate 1404 having a first input adapted to receive a data input signal, Datum_In, and a second input adapted to receive a first enable signal. The input data signal Datum_In supplied to the AND gate 1404_{A}, in some embodiments, may be buffered first. In one or more embodiments, a non-inverting buffer 1402 may be employed to generate a buffered version of the input data signal Datum_In which is supplied to the AND gate 1404_{A}, although use of an inverting buffer is similarly contemplated. An output of the AND gate 1404_{A} is preferably supplied to an input of a PTL driver (i.e., transmitter) 1408_{A}, and an output of the PTL driver 1408_{A} may be fed to a corresponding passive transmission line 1410_{A}. The signal conveyed by the passive transmission line 1410_{A} is supplied to an input of a PTL receiver 1412_{A}, and an output of the PTL receiver 1412_{A} may be combined with outputs of one or more other PTL circuits (e.g., PTL circuit 1430_{B}) to form a data output signal, Datum_Out, of the PTL distribution circuit 1400.

Similarly, a second one of the PTL circuits, 1430_{B}, may include an AND gate 1404_{B} having a first input adapted to receive the data input signal Datum_In, and a second input adapted to receive a second enable signal. The input data signal Datum_In supplied to the AND gate 1404_{B}, in some embodiments, may be buffered first, such as by the non-inverting buffer 1402. An output of the AND gate 1404_{B} is preferably supplied to an input of a PTL driver (i.e., transmitter) 1408_{B}, and an output of the PTL driver 1408_{B} may be fed to a corresponding passive transmission line 1410_{B}. The signal conveyed by the passive transmission line 1410_{B} may be supplied to an input of a PTL receiver 1412_{B}, and an output of the PTL receiver 1412_{B} may be combined with outputs of one or more other PTL circuits (e.g., PTL circuit 1430_{A}) to form the data output signal, Datum_Out, of the PTL distribution circuit 1400.

The first and second enable signals, collectively the one-hot bus 1406, supplied to the second input of the AND gates 1404A and 1404B in the first and second PTL circuits 1430A and 1430B, respectively, may be generated by the delay circuit 1420. In one or more embodiments, the delay circuit 1420 includes an OR gate 1422 having a first input adapted to receive a buffered version of an initialize signal, Initialize, supplied to the delay circuit. In the illustrative PTL distribution circuit 1400, a non-inverting buffer 1408 may be used to generate the buffered version of the initialize signal supplied to the OR gate 1422, although use of an inverting buffer is similarly contemplated. An output of the OR gate 1422 may be supplied to a first delay line 1424, and an output of the first delay line may be supplied to an input of a second delay line 1426. An output of the second delay line 1426 is preferably fed back to a second input of the OR gate 1422. The outputs of the respective delay lines 1424, 1426 are preferably used to generate the first and second enable signals supplied to the PTL circuits 1430A, 1473B.

In one or more embodiments, each of the first and second delay lines 1424, 1426 may include a plurality of series-connected non-inverting or inverting buffers having a prescribed delay value associated therewith. The delay values corresponding to the first and second delay lines 1424, 1426 are preferably the same, although it is similarly contemplated that, in some embodiments, the first and second delay lines 1424, 1426 may have different delay values. In the delay circuit 1420, the second enable signal will have a longer delay value compared to the first enable signal, since the initialize signal is passed through at least one additional delay line to generate the second enable signal. In one or more embodiments, the delay value corresponding to each of the delay lines 1424, 1426 may be equal to the fractional PTL driver recovery period of the whole circuit.

As previously stated, the outputs of the respective PTL circuits 1430_{A}, 1430_{B} are preferably combined to form the output data signal Datum_Out. To accomplish this, the respective outputs of the PTL receivers 1412_{A}, 1412_{B} in the PTL circuits 1430_{A}, 1430_{B}, can be supplied to corresponding inputs of an OR gate 1414; an output of the OR gate 1414 preferably forms the Datum_Out signal as a logical summation of the output signals from the PTL circuits 1430_{A}, 1430_{B}. Thus, whenever any one of the outputs of the PTL circuits 1430_{A}, 1430_{B} is a logic high, the Datum_Out signal will be a logic high (i.e., logic “1”), and the Datum_Out signal will only be a logic low (i.e., logic “0”) when all of the respective outputs of the PTL circuits 1430_{A}, 1430_{B} are a logic low. Although shown as an OR gate 1414, it is to be understood that similar summation functionality may be achieved using other logic gates, such as inverters, AND gates, NOR gates and/or NAND gates (e.g., using De Morgan's theorem), as will become apparent to those skilled in the art.

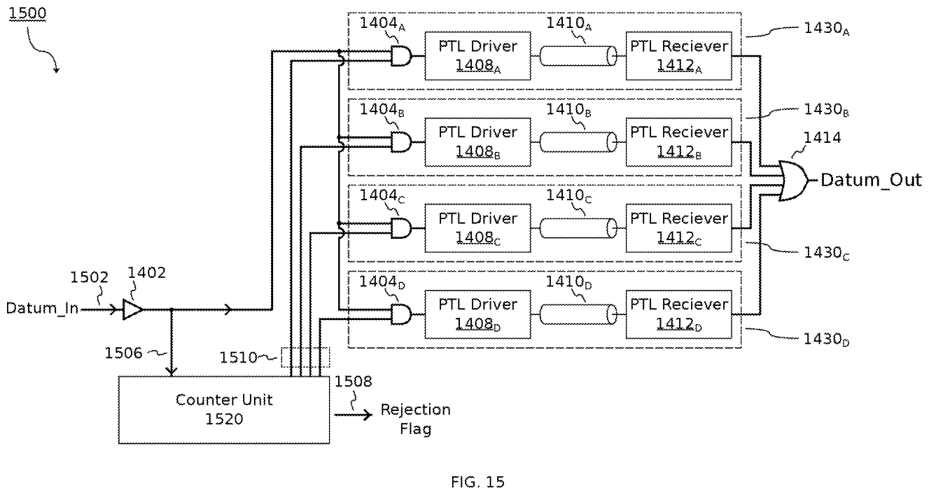

The exemplary techniques for distributing a datum signal(s) using PTLs as described in conjunction with FIG. 14 can be extended, as shown in FIG. 15. FIG. 15 is a schematic diagram depicting at least a portion of an exemplary PTL distribution circuit 1500, according to one or more embodiments of the invention. The PTL distribution circuit 1500, like the illustrative PTL distribution circuit 1400 of FIG. 14, includes a plurality of PTL circuits 1430_{A}, 1430_{B}, 1430_{C} and 1430_{D}. Each of the PTL circuits 1430_{A}, 1430_{B}, 1430_{C}, 1430_{D} may be implemented in a manner consistent with the PTL circuits shown in FIG. 14. Specifically, each of the PTL circuits 1430_{A}, 1430_{B}, 1430_{C}, 1430_{D} in the PTL distribution circuit 1500 may comprise an AND gate 1404_{A}, 1404_{B}, 1404_{C}, 1404_{D} configured to supply a received datum signal to a corresponding PTL driver 1408_{A}, 1408_{B}, 1408_{C}, 1408_{D}. An output of the PTL driver 1408_{A}, 1408_{B}, 1408_{C}, 1408_{D} in each of the PTL circuits 1430_{A}, 1430_{B}, 1430_{C}, 1430_{D} may be supplied to a corresponding passive transmission line 1410_{A}, 1410_{B}, 1410_{C}, 1410_{D}, which is, in turn, supplied to a corresponding PTL receiver 1412_{A}, 1412_{B}, 1412_{C}, 1412_{D}. Outputs generated by the PTL receivers 1412_{A}, 1412_{B}, 1412_{C}, 1412_{D} form outputs of the respective PTL circuits 1430_{A}, 1430_{B}, 1430_{C}, 1430_{D}. Each of the outputs from the respective PTL circuits may be combined using an OR gate 1414 (or similar OR functionality) to generate a data output, Datum_Out, of the PTL distribution circuit 1500.

As in the illustrative PTL distribution circuit 1400 shown in FIG. 14, a first input of each of the AND gates 1404_{A}, 1404_{B}, 1404_{C}, 1404_{D} in the respective PTL circuits 1430_{A}, 1430_{B}, 1430_{C}, 1430_{D} may be configured to receive a buffered version 1506 of a data input signal, Datum_In, supplied to a data input port 1502 of the PTL distribution circuit 1500. In one or more embodiments, a non-inverting buffer 1402 may be employed to generate the buffered version 1506 of the input data signal Datum_In supplied to the respective AND gates 1404_{A}, 1404_{B}, 1404_{C}, 1404_{D}, although use of an inverting buffer is similarly contemplated.

As previously stated in conjunction with the PTL distribution circuit 1400 shown in FIG. 14, activation of the PTL circuits 1430_{A}, 1430_{B}, 1430_{C}, 1430_{D}, such as by supplying corresponding enable signals to a second input of the AND gates 1404_{A}, 1404_{B}, 1404_{C}, 1404_{D} in each of the respective PTL circuits 1430_{A}, 1430_{B}, 1430_{C}, 1430_{D}, is preferably delayed by a prescribed amount configured to allow the PTL circuits time to recover storing their flux quanta. In the PTL distribution circuit 1400 of FIG. 14, the delay circuit 1420 was configured to perform this function. In the exemplary PTL distribution circuit 1500, this function may be performed using a counter unit 1520. In one or more embodiments, the counter unit 1520 is preferably configured to receive the buffered Datum_In signal 1506, which may function as a clock signal for incrementing (or decrementing) the counter unit.

An output count value generated on one or more outputs, collectively 1510, may be indicative of a delay amount. These outputs 1510, and the count value associated therewith, are preferably supplied to the second input of the corresponding AND gates 1404_{A}, 1404_{B}, 1404_{C}, 1404_{D} in each of the respective PTL circuits 1430_{A}, 1430_{B}, 1430_{C}, 1430_{D}. If the count value generated by the counter unit 1520 exceeds a prescribed threshold value, the counter unit may generate a rejection flag 1508 to indicate that an overflow condition has occurred, or may generate a rejection flag 1508 if the counter unit 1520 exceeds a prescribed threshold value and receives an input Datum_In signal 1506.

With reference now to FIG. 16, a block diagram is provided that conceptually illustrates at least a portion of an exemplary branch resolution system 1600 configured to perform early and late branch resolutions, according to one or more embodiments of the invention. The branch resolution system 1600 may be representative, for example, of any system comprising multiple pipelines which have different required arrival times for identical data portions (e.g., Data<1:16>_for_memory_OPS) of a larger data field (e.g., Data<1:64>_for_memory_OPS). The branch resolution system 1600 may include a plurality of programmable copy delay circuits 800, early branch resolution logic 1602, and late branch resolution logic 1604. In particular, skewed data, Datum<1:16>_for_logic_OPS, may return from a MM (e.g., 100 shown in FIG. 1A) and pass through one or more programmable copy delay circuits 800. As previously described with respect to FIGS. 8A-8B, an input signal on an arbitrary cycle N that is supplied to the branch resolution system 1600 can be copied by the programmable copy delay circuit 800 and delivered on the same cycle and/or on one or more different cycles, for example, N, N+P, N+W, etc., where P refers to an arbitrary P cycle and W refers to an arbitrary W cycle.

In one or more embodiments, the skewed data Datum<1:16>_for_logic_OPS: (i) can undergo no delay to feed the early branch resolution logic 1602 (which may process the most significant bits in a comparison); and/or (ii) can be delayed by P cycles to feed the late branch resolution logic 1004, which can process a combination of skewed early and late data of Datum<1:M> (for at least portions of the skewed data). The MM may have rapid single flux quantum (RSFQ) or RQL-based-read-path NDRO arrays. It is important to recognize that, with additional enables (not explicitly shown, but contemplated), the programmable copy delay circuits 800 may be configured to align various bit fields in the late branch resolution logic 1604 to overlay or correct functional operations in pipelined logic.

In a practical application of a processing system, to improve performance, serial instructions are often fetched and decoded before branches are resolved, thereby tying up many resources including caches. Therefore, when a branch will be taken in an instruction stream (as detected by the early branch resolution logic 1602), even though the branch address may be unknown at the time, it is important to stop serial fetches and decodes occurring in sequence after the branch instruction (wrongly processed) in an operation. As is known in the art, a pipeline flush (also known as a pipeline break or pipeline stall) is a procedure enacted by a processor when it cannot ensure that it its instruction pipeline will be correctly processed in the next clock cycle. The pipeline flush essentially frees all pipelines occupied by the serial processing of instructions (wrongly processed) for use by other new processes contending for resources. Such pipeline control actions improve performance and save power, and might involve, for example, the stoppage (i.e., disablement of propagation) of wrongly fetched data in the MM 100 (FIG. 1A) pipeline by setting the enable signals associated with array output circuits (e.g., array output circuits 600 in FIG. 10 or 12, or the array output circuit 119 in FIG. 1A) all to a “0-state.”

The early branch resolution logic 1602 shown in FIG. 16 represents one particular exemplary form of sparse logic 316 (see FIGS. 3A-3B), which can provide both performance improvements and power reduction in a MM. In more general terms, multiple inputs ranging from early to late can be fed to a plurality of logic pipelines (e.g., early branch resolution logic 1602 and/or late branch resolution logic 1604 shown in FIG. 16).

FIG. 14 shows a simple implementation of the circuit 1400 which is an embodiment of the invention for a pair of PTL drivers (N=2), with a cycle time of two clock cycles. The input Datum_In comes in via JTL 1402 and is split to feed one of the inputs of AND gates 1404_{A}, 1404_{B} each. (Note, in FIGS. 14 and 15, JTL are explicitly shown. In all other schematics, those skilled in the art understand where to include them.)

A second input signal, an “initialize” input initializes an enablement/trigger/launch loop circuit 1420, which itself is responsible for activating one of the PTL drivers 1408_{A}, 1408_{B}, readied with sufficient flux, to drive a signal applied to the input Datum_In across one of the PTLs 1410_{A}, 1410_{B}.

The initialization procedure of the enablement/trigger/launch loop circuit 1420 follows: At some point before operation of the circuit, a one-time logical “1” is applied to the initialize input of JTL 1408, which drives the signal through OR gate 1422. The signal then passes through the one-bit shift register 1424 in one clock cycle and splits, going to both an input of AND gate 1404 and the other one-bit shift register 1426. Shift register 1426 retains the in-flight signal for one clock cycle before feeding it back to OR gate 1422 and the other AND gate 1406. In this way, on alternating clock cycles, either AND gate 1404 or AND gate 1406 (but not both) will see a logical 1. In this sense, enablement/trigger/launch loop circuit 1420 functions as a “round robin” trigger generator, with a two-bit, one-hot output. A continuous stream of data at Datum_In will now alternatingly hit PTL Driver 1408_{A} and 1408_{B} on alternating clock cycles. Assuming substantially similar delays through passive transmission lines 1410_{A}, 1410_{B} and passive transmission line receivers 1412_{A}, 1412_{B}, OR gate 1414 will merge the transmissions back into a single output, Datum_Out.

If the duty cycle of the circuit is less than 100% of the available bandwidth of the underlying SFQ technology, such as RQL, (for example 25%), alternative embodiments can be implemented with more sophisticated versions of an input and round robin N-bit, one-hot circuits. It is contemplated that, in other embodiments of the invention, data unable to be driven through the PTLs, being that not one of the PTLs is charged with flux quanta, can be redirected. That is, data arriving before a PTL driver is available will not be transmitted via PTL; this feature may not be used or necessary for a properly restrained input data sequence.

The invention contains at least two gated transmission channels 1430 (a set of at least one AND gate 1404, at least one PTL driver 1408, at least one PTL transmission line 1410, and at least one PTL receiver 1412), at least one N-way OR gate 1414, at least one input JTL 1402 (which in general may be split into any number of JTLs necessary to achieve sufficient fan-out), at least one counter unit 1420 (which itself has at least one data input 1408, can have a rejection flag output 1508, and N outputs 1406 for the “one-hot” bus 1406), and at least one “one-hot, N-channel” output bus 1406.

FIG. 15 shows circuit 1500, a generalized version of circuit 1400, including a rejection flag output 1508, just discussed, perhaps used for initial system debug. In this illustrative embodiment of the invention, data is split between four PTLs, though the solution is scalable to any number of lines. Each of four passive transmission lines 1410_{A}, 1410_{B}, 1410_{C}, 1410_{D} has a driver 1408 and receiver 1412 on each of their ends, each group of which together with the AND gate 1404 is a separate channel 1430. On the receive side, all outputs go into the four-way OR gate 1414 and produce Datum_Out. Given that the OR gate would only receives one input at a time, a simpler and smaller merge gate can always be used in its place as known in the art.

The input signal 1502 is split by JTL 1402 (or an appropriate splitter tree) to go to each of the four AND gates 1404_{A}, 1404_{B}, 1404_{C}, 1404_{D} as well as to the counter unit 1520. Upon receiving an input bit, the counter unit can send the bit to the “rejection flag” output 1508 if no PTL driver is ready. It is contemplated that the circuit providing input to 1500 is designed such that input only arrives when sufficient PTL drivers are ready, and as such the description of this implementation will assume no early data arrives.

The counter unit 1520 has a data input 1506 from the split, and outputs four (or more generally, N) one-hot outputs for each of the PTLs, collectively indicated as the data bus 1406. The one-hot outputs may also overall have a “no-hot” state (logical zero on all outputs) if no PTLs are ready to receive data. The counter unit first has an internal timer counting up to one-fourth of the recharge time of the PTL drivers. (In general, the counter increases to a value such that the next PTL will be ready for the next incoming logical 1 bit; this value is highly dependent on the frequency of incoming data, the size of the incoming data, the number of PTL drivers available, and the recharge time of the PTL drivers.) The counter unit waits until this counter has reached the appropriate value and then cycles through the four one-hot outputs upon arrival of the data-present signal. Each of the one-hot outputs goes to a separate AND gate. The one-hot outputs will maintain a single logical 1 output until a data input is received, after which it will have a “no-hot” output until the counter once again reaches its maximum value, after which the next line in the one-hot output switches to a logical 1. In this way, incoming data arriving early to the AND gates 1404 will not proceed to the PTL driver 1408 until the appropriate PTL driver is ready.

The remainder of circuit 1500 functions similarly to circuit 1400, with only one of the AND gates primed to pass through data at a time. (Note, that by design the circuit 1400 has as many channels as it takes cycles to recharge the PTL driver, and as such never needs a “no-hot” output state of the bus. Otherwise, the counter unit 1520 provides the same functionality as enablement/trigger/launch loop circuit 1420 of circuit 1400.) The input data is split and each goes to one each of the AND-gates that the one-hot counter unit signals go to. In this way, only one of the AND gates 1404_{A}, 1404_{B}, 1404_{C}, and 1404_{D} is ever active, and sends the signal through from the output of the AND gates to one of the PTL drivers 1410_{A}, 1410_{B}, 1410_{C}, and 1410_{D}. By design, the next PTL, either PTL 1412_{A}, 1412_{B}, 1412_{C}, and 1412_{D}, used will be the next one in sequence.

In summary, the counter unit will direct data input to a failure flag output unless the one of the one-hot outputs is active. Otherwise, one and only one of the “one-hot” outputs is active and will allow the split input data to pass through that and only that AND gate to the appropriate PTL driver. The counter unit outputs are “no-hot” when the counter is running up to the maximum value to prevent access to the PTL drivers if they are still charging up.

In a more sophisticated design, the counter could count up to the total time needed for a PTL driver to recharge, starting at the fourth (or in general, N^{th}) input bit, and independently going through the one-hot outputs. In this way, four consecutive bits can be sent, but at a cost of a longer overall recharge time before any other bit can be sent. This is useful for a “burst mode” transmission where (in this example) four consecutive bits need to be sent in quick succession but the overall frequency of such transmissions is the same as the full recharge time of the PTL drivers. This is not particularly different from the implementation described above, except that the one-hot outputs cycle through the first to the last bit before reaching a “no-hot” output state. In different words, the PTL triggering times do not need to be periodic. Instead, they can occur one cycle after the next sort of collectively in bursts, should there be a need for a burst signal.

FIG. 16 illustrates an exemplary schematic of a branch resolution system 1600 that performs early and late branch resolutions. The branch resolution system 1600 is intended to be representative of any systems having pipelines, which have different required arrival times for identical data portions (i.e. Data<1:16>_for_memory_OPS) of a larger data field (Data<1:64>_for_memory_OPS). The branch resolution system 1600 includes a plurality of programmable copy delay circuits 800, early branch resolution logic 1602, and late branch resolution logic 1604. In particular, skewed data (i.e. Data<1:16>_for_memory_OPS) returning from a MM 100, which has a rapid single flux quantum (RSFQ) or RQL-based-read-path NDRO arrays, and passing through programmable copy delay circuits 800 can [i] undergo no delay to feed the early branch resolution logic 1602, which processes the most significant bits in a comparison, and, portions of which, can [ii] be delayed by P cycles to feed the late branch resolution logic 1004, which can process a combination of skewed early and late data of Datum<1:M>. It is important to recognize that, with additional enables (not shown but contemplated), the programmable copy delay circuits 800 can align various bit fields in the late branch resolution circuit 1604 to overlay of for correct functional operations in pipelined logic.

In a real processing circuit/system, to improve performance, serial instructions are fetched and decoded before branches are resolved, tying up many resources including a cache. Therefore, if a branch will be taken in an instruction stream (as detected by the early branch resolution circuit 1602), even though it is not known to which address, it is important, not only to stop serial fetches and decodes occurring in sequence after the branch instruction (wrongly processed) in an operation. As known in the art, a pipeline flush frees all pipelines occupied by the serial processing of instructions (wrongly processed) for use by other new processes contending for resources. Such pipeline control actions improve performance and save power and might involve, for example, the stoppage (disablement of propagation) of wrongly fetched data in the MM 100 pipeline by setting the enables of 600 (also known as the array output circuit 119) all to a “0-state.”

The early branch resolution logic represents one particular form of sparse logic 316 (see FIGS. 3A-3B), which provides both performance improvements and power reduction.

In more general terms, multiple inputs ranging from early to late can be fed to a plurality of logic pipelines (e.g., 1602, 1604). The multi pipeline system with embedded variable delay elements 1600 includes a plurality of programmable copy delay circuits 800, a first early processing pipeline 1602 and a second late processing pipeline 1604. As discussed with respect to FIG. 8, one input can be copied in a programmable copy delay circuit 800 from an input signal on arbitrary cycle N and delivered on different cycles, for example, N, N+P, and N+W.

### Cache and Nomenclature

With regard to caches, there are various known cache architectures, including set-associate caches. Note, that a 4-way (and 3-way) set-associative cache is exemplary for the present disclosure, but embodiments of the invention may not be limited to such cache architectures.

FIG. 17 is a block diagram depicting at least a portion of an exemplary file and memory system 1700, according to one or more embodiments of the invention. The file and memory system 1700 may include at least one file system 1702, shown as a database or the like, at least one main memory 1704, and at least one cache 1706, which is depicted as a level 1 cache (which will later be shown to be configured as a “compute cache”). The level 1 cache 1706 is exhibited primarily for the purpose of establishing consistent terminology within the present disclosure and for defining certain features of the overarching invention as being configured for performing “compute cache” functionality.

The exemplary level 1 cache 1706 may include a data RAM 1708, or other addressable storage element, a directory 1710, and a translation lookaside buffer (TLB) 1712, which is often defined as a memory cache that stores recent translations of logical/virtual memory to absolute/physical memory. In one or more embodiments, the data RAM 1708 may be fungible—configured to perform logic, memory, and mixed memory and logic operations. The data RAM 1708 is preferably configured to store lines of data, each line of data comprising, for example, contiguous data, independently addressable, and/or contiguous instructions, also independently addressable. Furthermore, the data RAM 1708 may comprise one or more operands, one or more instructions, and/or one or more operators stored in at least a portion of the data RAM. In one or more embodiments, the data RAM 1708 may be implemented as at least a portion of the MM 100 (see FIGS. 1A-1C), integrated in the level 1 cache 1706. In general, a cache can be an instruction cache (i.e., I-cache), a data cache (i.e., D-cache), a combined instruction and data cache (i.e., a unified cache), and a TLB.

The file system 1702, like the data RAM 1708, may comprise one or more operands, one or more instructions, and/or one or more operators stored in at least a portion of the file system. Similarly, the main memory 1704 may comprise one or more operands, one or more instructions, and/or one or more operators stored in at least a portion of the main memory. The main memory 1704 is preferably operatively coupled to the cache 1706, such as via a bus 1716 or other connection arrangement. Although only one bus 1716 is shown in FIG. 17 for illustrative purposes, it is to be understood that a plurality of buses 1716 may be included in the file and memory system 1700, between the level 1 cache 1706 and the main memory 1704, particularly when a plurality of level 1 caches 1706 are employed in the system.

### A Compute Cache Configurable for (i) Instruction, Operand, and Operator Storage, and (ii) Operator Processing

In accordance with one or more embodiments of the invention, the level 1 cache 1706 may be advantageously configured as a “compute cache.” To begin a discussion regarding aspects of the present inventive concept associated with the level 1 cache 1706 configured as a “compute cache,” it is important to recall the inclusion of operand(s), instruction(s), and operator(s) in all regions of the file and memory system 1700, including the file system 1702, the main memory 1704 and the data RAM 1708 in the cache 1706. An important benefit that is unique to the level 1 cache 1706 according to aspects of the present disclosure is it may be configured: (i) to enable fetching of one or more operators from the main memory 1704 (or the file system 1702, or other levels of the cache 1706 (not explicitly shown for simplicity)); (ii) to enable a lookup of one or more operators (and, of course, operands and instructions) by the directory 1710 and the TLB 1712, for example via a lookup path 1714 in the cache 1706; (iii) to enable processing of one or more operators (also one or more operations) by the data RAM 1708; and (iv) to enable storage of operators in the data RAM 1708 alongside instructions and operands. Additional functionality resident in the MM 100 within the level 1 cache 1706—for example, the output data flows depicted as a bit slice 1000 (including its driving arrays 102A, 102B) in FIG. 10 and as a bit slice 1200 (including its driving arrays 102A, 102B) in FIG. 12—may enable a significantly broader processing capability than the data RAM 1708 (i.e., array(s) 102A, 102B) alone, while reducing power consumption without requiring significant additional chip real-estate.

After describing several elements in the exemplary file and memory system 1700 and defining their respective functions, a top-down description will now be provided. First, in accordance with one or more embodiments of the invention, known computer architectures may be enhanced with new instructions for exploiting capabilities of the underlying attributes of the MM 100 and its external support logic. By way of example only and without limitation or loss of generality, one (partial) format of an illustrative instruction which may be suitable for use with embodiments of the invention is as follows:
instruction address name <operator address >: <control address or_reg_defined or instruction_defined>; <operand_1 address or reg> <operand_2 address or reg>.

For the exemplary instruction format shown above, “address” may refer to a logical/effective/virtual storage address of an instruction, operand or operation, and “reg” may refer to the register in which an operand is stored (e.g., general purpose register (GPR) or register holding results from an earlier pass). Moreover, in the exemplary instruction format shown above, “control” may define one or more logic actions of primarily the dataflow outside the superconducting array(s) 102A, 102B of the MM 100 (FIGS. 1A-1C). By “instruction_defined,” it is meant that the control signals, which manage the dataflow (i.e., enables), are defined exactly by the named instruction and thus “control” does not actually appear in the instruction format.

In decoding an instruction, the controls/enables may be defined by the instruction name itself. In contrast, “address_or_register_defined controls” can be enables of at least one of data flow and address flow entities, defined, at least in part, by a particular logical address or defined by a particular register. Address or register defined controls, as opposed to “instruction defined controls,” may make it easier for diagnostic purposes (e.g., to fix bugs) involving the control bit values, because only a software change would be needed as opposed to a hardware change. In the particular example that follows, it will be assumed that the control bits are not defined by a logical address, and thus the control bits are sent to the level 1 cache 1706.

Whether the source of the controls are instruction, address, or register, they can drive data flow entities, driving for example, (i) ens_A<0:3>, ens_B<0:3>, ens_even PCD, ens_odd PCD, ens_even NNL, ens_odd NNL, ens_even EI, and ens_odd EI, all signals being associated with the illustrative bit slice 1000 in FIG. 10; or (ii) ens_A<0:3>, ens_B<0:3>, ens_even CSL, ens_odd CSL, ens_even EI, and ens_odd EI, all signals being associated with the illustrative bit slice 1200 in FIG. 12.

In an alternative instruction set architecture (ISA) according to one or more embodiments of the inventive concept, as part of the operator fields, the specific values and bit positions of these control bits would be specifically listed. Instruction decode would send these values and bit positions to the instruction unit, which would send them to the level 1 cache 1706.

An operation can be a collection of instructions, each of which can have an operator(s) and operand(s) associated therewith. Thus, in the context of a cache, an “operation” may invoke dataflow circuitry outside the array 102A, 102B of the MM 100 (FIGS. 1A through 1C, 10, and 12), in addition to at least one “operator” contained within it. An operation thus combines an operator(s), whose content and function may be made available by a reference to storage (fetch), and an instruction. The instruction references the location of the operator(s) and manages the dataflow logic outside the array 102A, 102B of the MM 100 (FIGS. 1A-1C) through the use of control signals previously mentioned. It is contemplated that the operator location can be modified, enabling, for example, a self-modifying code capability.

To set up an operator, the contents of the operator's storage location can be used in an MM (see, e.g., block 100 in FIG. 1A) as programmable switch 104 (FIGS. 1B-1C) values to prepare for performing a Boolean logic operation of some sort. These values can be referred to as internal (or memory) switch values.

For performing an operation, controls will preferably be used to invoke external (i.e., outside the array 102A, 102B in FIGS. 1A-1C) programmable logic values to perform a Boolean logic operation of some sort in the dataflow and address flow surrounding the array(s) 102A, 102B (FIGS. 1A-1C).

Some non-limiting examples of control bits for use in conjunction with embodiments of the invention can be as follows:
(i) true/complement control: see T/C Boolean data generation block 305 of FIGS. 3A and 3B. This newly defined control, in an exemplary implementation to be discussed, can invert the bus feeding the true-complement Boolean data generation block 305;
(ii) elective inverter control: see the elective inverter block 112 located in FIG. 1A (and described by the exemplary logic shown in FIG. 4) and note pass 1 and pass 2 (enable signals of FIG. 4) invert or buffer an input signal “In,” respectively, as it is being driven to an output “Out;”
(iii) enable nearest neighbor logic: see enable signals ens_even NNL and ens_odd NNL of FIG. 10 (bit slice (including arrays) 1000);
(iv) multiplexing and time division multiplexing enables associated with the array output circuit 119: see FIG. 600; and
(v) the enables for pipeline timing alignment, for elective logic processing (e.g., by a 2-input gate), and for producing one or more cycle-specific copies across pipelines: see FIGS. 7 and 8, with applications in FIGS. 10 and 12, respectively.

Traditionally, the term “split” cache refers to separate instruction and operand (data) caches, and the term “unified” cache refers to one cache that contains both instructions and operands. The term “fully split,” as used herein, is intended to broadly refer to separate instruction, operand, and operator caches, and the term “fully unified” (a compute cache), as used herein, is intended to broadly refer to one cache that contains instructions, operands and operators (and performs operations). While embodiments of the invention may be configured as a “split” operator-only cache, this cache example describes a fully unified cache as the MM (100 in FIG. 1A), at least in part because this is perhaps the most flexible (and powerful) application and the broadest embodiment.

Depending on programming use cases, traditional caches can fill differently, determining the residency of instructions and data during the execution of processes. This new fully unified cache memory according to one or more embodiments of the invention (e.g., level 1 cache(s) 1706 of FIG. 17) has beneficially extended the actions that can be performed, with its inherent storage, inclusion of an operator fetch and operation processing. The cache architecture according to one or more embodiments of the invention can now perform in-array computations (e.g., within the data RAM 1708 of FIG. 17) on externally applied operand(s) and produce result(s). The term “unified cache,” as used herein, is intended to broadly refer to this new fully unified cache (a compute cache) which is configured to store instructions operands, and operators. As previously noted, the unified cache has a data RAM 1708 (e.g., MM(s) 100 of FIGS. 1A and 17). For this exemplary unified cache, it is assumed (i) that instructions, operands and operators all use the same line size, and (ii) that unified cache accesses all take one machine cycle to complete.

The “low temperature” memory management entities 306 within FIGS. 3A and 3B may be used, in one or more embodiments, to implement at least a portion of the TLB 1712 and directory 1710 functionalities in the level 1 cache 1706 example, which may be used to describe one or more embodiments of the inventive concept. As previously discussed, FIG. 17 shows the lookup path 1714 (including the TLB 1712 and directory 1710) within the level 1 cache 1706 (which has the data RAM 1708/MM 100), which can communicate with at least one file system 1702, at least one higher-level cache (not explicitly shown), and main memory 1704, to process fetches required after directory misses (perhaps from the near 77K processing entities 303 of FIG. 3A).

Discussed subsequently is an exemplary setup process to enable (i) retrieval of an instruction, (ii) retrieval of an operand, and (iii) a pass of an instruction/operation for logic (operator). In one or more embodiments, all setup processes will initially involve a fetch.

If the instruction(s), operator(s), and operand(s) were all identified by their addresses, and their lookups all had directory misses, the fetches to the next level of storage hierarchy and corresponding unified cache installs would be similar. If they later had all directory hits, the operand(s) data returns would be saved in registers. During the execution of an instruction, the operator's control (derived from the instruction name or pointed to by the instruction with a reference to address_control) would be saved in a register in the cache control area.

The instruction and operand fetches would be normal memory requests/accesses to the cache. In mapping cache function into the superconducting entities (i.e., entities 304, 306, 308, 310, 312, and 314) of FIG. 3A and the MM 100 of FIGS. 1B and 1C, part of the array address can be encoded 328 and another part can be decoded 326. For the decoded portion, preferably one bit in a field of bits is activated for a memory access. For these requests/accesses, the corresponding read data<1:M> for memory ops 110 is returned from data RAM 1708 (located with the MM 100). Examples of normal memory accesses are shown in timing diagram examples 214 and 216 of FIG. 2, corresponding to array regions A1 and B2 in arrays A and B 102, respectively. In the very simple decoder example offered, the state of the one encoded partial address bit per subarray determines “1” vs “2” for the labels A1 and B2. To be specific, if the encoded bit is zero, it selects “1” (see blocks 118, 214), and if the encoded bit is one, it selects “2” (see blocks 116, 216). Note, that in timings 214 and 216, only one decoded WoDa bit is on: bit 1. Bits 2 through N are shown as being off, where N is an integer representing the largest WoDa bit. Arrays A and B 102 in FIG. 1 can represent embedded arrays within MM(s) 100, which are depicted in FIG. 3A and FIG. 3B.

Unlike an instruction or operand lookup, the operator's lookup would not enable or access the unified cache. Instead, a subset of the operator's logical/effective address and directory hit setid (or way or sid) would be saved to prepare for the execution of a portion of an instruction, where the portion of the instruction execution occurs in an address-defined-PLA portion of a MM(s) 100 (where the one or more operands get processed). In a more complex architected interaction(s), a combined memory and address-defined-PLA interaction(s) can be performed concurrently within a MM(s) 100. While the MM(s) can support such interaction(s), the interaction(s) is made complex because of the practical control requirements necessitated to assure consistency in system state over the interaction and thereafter (e.g., write interactions must be managed and barred from interfering), this saved information is the cache index and setid which will be referenced later to perform at least part of an operation.

This and subsequent paragraphs describe one pass through the MM 100, and supporting/surrounding logic (e.g., entities 304), which, in different words, can be referred to as the execution of an instruction. It is important to understand that control bits can modify dataflow function outside array(s) 102 of FIG. 1.

It was discussed earlier that there are several possible sources of the control bits, and that the option of sourcing them from a logical address was not chosen for this example. It was also mentioned that the setup process saved the control bits in a register in the cache control area. These control bits within the cache control area are referenced during a pass through the MM.

The operand(s) register values are used to set multiple WoDa bits (See 322, 308, 100, 114). In the case of an operator, if the number of WoDa bits being used is less than the number of WoDa bits available, then the MM(s) 100 can be made immune to the interference that the unused true-complement WoDa signals (bits) would cause on a result by setting the state of the programmable switches 104 in the unused rows (associated with the unused true-complement WoDa signals) in MM(s) 100 to zero.

The operator's saved cache array index and setid are used to set the encoded partial address, associated with rows, as well as the column address made possible by the array output circuit 600 (acting as a column multiplexor). (Also see controls ens A/B<0:3>600 of FIGS. 10 and 12).

A PLA access of the data RAM 1708 (MM 100) is needed to now perform the desired Boolean operation (as depicted in FIG. 12—operand(s) in and result(s) out), exploiting the stored operator. The result(s) (e.g., Datum<1:M>_for_logic_OPS) from the MM is/are saved.

For the PLA access (computation), part of the array address is encoded 328. The input data lines 322 (later WoDas), which are fed by bitwise true and complement versions of the operand(s) generated by the T/C Boolean data generation entity 305, set multiple bits of a bus that, for operand(s) and instruction(s) fetches, contains a decoded portion of the array address, known as the WoDa bits (which pass through multiplexor 308). Upon processing within the MM 102, the corresponding result(s) (data<1:M> for logic OPS) 112 of FIG. 1A are returned from the MM 100, also of FIG. 1A.

Examples of PLA accesses are shown in timing diagram examples 202 through 212 of FIG. 2, corresponding to array regions A1 through B2 in blocks 102. The state of one encoded partial address bit per subarray determines “1” versus “2” for the labels A1 through B2. To be specific, if the encoded bit is zero, it selects “1” (see blocks 118, 202, 206, 210), and if the encoded bit is one, it selects “2” (see blocks 116, 204, 208). Note, that in timings 202 through 212 that multiple WoDa bits are on: bit 1 and at least one of bits 2 through N, where Nis an integer representing the largest WoDa bit. Note, that timing diagram examples 210 and 212 involve regions in both arrays (A and B).

This completes the description of one pass through the MM 100. The desired operation, however, may require more than one pass through the MM (which can be enabled by executing multiple instructions). See pass 2 in FIG. 5 and EI 112 of FIG. 1A (schematic in FIG. 4).

One example of a 2-pass operation is an and-or, where the “and” is done on the first pass and the “or” is done on the second pass (see FIG. 5).

For the first pass instruction, some dataflow control bits are set as follows:
true/complement control=complement (i.e. Invert the bus feeding the true-complement Boolean data generation block 305)
elective inverter control=invert (i.e., Pass 1 set equal to a logic 1, and Pass 2 set equal to a logic 0)

The inverted bus feeds the true complement Boolean data generation block 305, within low temperature logic entities 304. The outputs from block 305 feed input data lines for PLA requests 322, which propagate through the WoDa mux 308, which feed the WoDa bits into the MM 100. Through this propagation, the inverted bus that fed block 305 negates the inversion bubbles 516. This source of bitwise complement operand(s) connects into the column 106, via enabled programmable switches 104. The output of the column OR(s) 106 propagate to the “ORs 110,” which propagate to EI 112, which behaves as an invert due to the EI control (See upper half of pass 1 logic representation 502). Because the source data is inverted, the or-invert propagation behaves as an “and” 512 (See lower half of pass 1 logic representation 502). This “and” feeds MM 100 output data<1:M> for_logic_ops which feeds back into a holding register within low temperature logic entities 304.

Only the simplest dataflow, that of FIGS. 1A, 1B, and 1C, has been discussed in this example. As described already, the other following alternatives exist: (i) the input data flow can support the simultaneous selection of more than one region; and (ii) the output data flow, for example highlighted as 1000 of FIGS. 10 and 1200 of FIG. 12 integrates significantly more function at the expense of area. Moreover, the input data flow can be pre-processed as noted.

For a multipass operation, a separate instruction can be used for each pass. The first pass may dump its results in a register. The second pass may then pick up an operand from that register. This is one way that passes of a multipass operation can link to each other.

For the second pass instruction, some dataflow control bits are set as follows:
true/complement control=true (i.e. Do not invert the bus feeding the true-complement Boolean data generation block 305.)
elective inverter control=buffer or no-invert (i.e., Pass 1 set equal to a logic 1, and Pass 2 set equal to a logic 0)

The operand for a second pass instruction can be retrieved from the holding register holding the first pass result. The holding register can be located in entity 304. This time a bitwise “true” holding register result, within low temperature logic entities 304, feeds the true complement Boolean data generation block 305. The outputs from block 305 feed input data lines for PLA requests 322 (via an internal multiplexor, which selects between the outputs of T/C Boolean data generation entity 305 and Data<1:M>_for_logic_OPS), which propagate through the WoDa mux 308, which feed the WoDa bits into the MM 100. Through the array cells 104, this source then feeds the column ORs 106, the output of which propagate to the ORs 110, which propagate to EI 112, which behaves as a non-inverting buffer due to the EI control (see upper half of pass 2 logic representation 504). The or-buffer propagation behaves as an “or” 514 (see lower half of pass 2 logic representation 504). This “OR” feeds MM 100 output data<1:M> for_logic_OPS.

### New Directory Entry Bits Defined for Operators

Perhaps the directory array contains a bit that specifies whether the entry is for an operation. This bit protects the line from being LRU′ed out (by a “least recently used management” known in the art), unless all available setids for a given directory index are operations. If a special flush request comes in for that address, this protection bit is cleared. Further details regarding a use of this function are provided herein below.

When a fetch request comes to the L1 cache for an operator, it will come along with two control bits that will be installed in the directory entry:
(i) line protect bit; and
(ii) line read-only bit

There will also be a control bit put in the directory indicating operator. The “operator bit” will be used for debug and for various other uses that are TBD. One use of the read-only bit is, if the operator fetch misses in the L1 cache, to fetch the line from the cache hierarchy with read-only status (as opposed to fetching it conditional-exclusive). Another use of the read-only bit is, if a store to the line is attempted, then detect an exception or an error. The two purposes of the read-only bit then can be to improve performance in a multiprocessor system and detect when operators are being improperly modified.

The “line protect” bit is used to override the directory least recently used management (LRU), so that the line does not get LRU′ed out of the cache, except for unusual cases. One unusual case would be another CPU in a multiprocessing system storing to that line. The reason for the “line protect” bit is to preserve the operator for an extended period of time, until usage of it is complete, even if usage is infrequent enough such that the operator would normally LRU-out.

There would be a corresponding new “flush operator(s)” (one or more operators) request to the level 1 cache. It would either come with a corresponding line address, or increment through all directory indexes. It would turn off the directory's line protect bit(s).

In an alternative embodiment of the invention, it is contemplated that the operator line itself can be modified while the system is running, to modify the operation based on results from earlier computations (a self-modifying code). There would need to be logic in place to prevent the operation from being stored-to while it is being used.

### Directories, TLBs, and Data RAMs of a Cache Collectively Held in a Metamorphosing Memory

### Moving the TLB Outside of the Level 1 Cache Unit

Referring again to FIG. 17, in accordance with one or more embodiments, for the lookup mechanism of the level 1 cache 1706, the TLB 1712 and absolute directory 1710 may be replaced with symmetric logical/absolute (LA) directories. The logical/absolute directories may be split or merged; the directory(s) preferably share one set of valid bits. The TLB 1712 and its associated address translator can be moved to a next level (e.g., level 2) of storage/memory hierarchy.

As part of how the term “symmetric” is being defined in accordance with embodiments of the present disclosure, the LA directory and corresponding level 1 cache 1706 must be indexed only by address bits that are not subject to translation. This restriction limits the maximum size of the cache. Furthermore, if the directories are separate, they must still be addressed with the same array index bits.

The term “synonyms,” as may be used herein, is intended to refer broadly to two (or more) logical addresses that map to the same absolute address. This design point beneficially removes the possibility of two synonyms being in different cache index addresses, since the cache is not indexed by address bits that are subject to translation.

The LA directory according to aspects of the present inventive concept preferably integrates the functions of the TLB 1712 and directory 1710. Therefore, any requests that normally invalidate only directory entries (e.g., such as cross interrogates XIs), and any requests that normally invalidate only TLB entries (such as ipte=invalidate page table entry), will invalidate LA directory entries.

The main fields in the logical directory portion of an LA directory are the full logical (or effective) page address and, if it exists, the full logical address extension (e.g., alet, asce, etc); those fields may be abbreviated as “log address” and “ext.” The main field in the absolute directory portion of an LA directory is the full absolute (or physical) page address; that field may be abbreviated as “absolute address.”

The LA directory arrays may be sliced like a TLB, in terms of the three fields: log address, ext and absolute address. However, the LA directory's array indexing and set associativity are like a directory. For example, assume an LA directory and cache that is four-way set associative (i.e., four setids).

For a fetch request, the requestor's log address and ext are preferably compared against the corresponding values in the LA directory's four setids. If there is a hit, the corresponding data is selected from the cache to return to the requestor. The absolute address is not used at all for a fetch hit or a fetch miss.

For an XI (cross-interrogate or invalidate), the XI's absolute address may be compared against corresponding values in the LA directory's four setids. If there is a hit, the corresponding LA directory valid bit is turned off. If the LA directory implementation is split, the XI searches may run in parallel with fetches.

In one or more embodiments of the invention, the interface between the level 1 cache 1706 and a next level of storage hierarchy preferably receives two related changes as follows:
(i) The fetch address bus from the L1 cache changes from an absolute line address to a logical line address and extension, where the logical line address is sent on one cycle and the extension is sent on another cycle;
(ii) The translated absolute line address is sent on the existing XI absolute address bus to the level 1 cache, shortly before the start of the data return to the level 1 cache.

In one or more embodiments of the invention, changes to the system architecture may be performed for implementing certain other features or performance enhancements, including changes within a next level (e.g., level 2) storage hierarchy to support the new design, and changes for TLB spop (special op) handling (ipte, etc.), which may affect how virtual addressing, page swapping, etc., function, among other possible modifications.

As previously stated, with regarding to synonyms, this design point removes the possibility of two synonyms being in different cache index addresses, since the cache is not indexed by address bits that are subject to translation. However, the new design, according to some embodiments, can have synonyms within the same cache/LA directory index address, in different setids, where different log address/ext values have the same corresponding absolute page address; one or more embodiments of the invention may provide multiple ways to handle this case.

In terms of array layout comparisons for a traditional design versus the new design according to aspects of the inventive concept, as a rough approximation, using a reasonable set of assumptions, the new design may use about five percent more array area for the level 1 cache unit compared to a traditional base design. However, this slight increase in array area may results in increased data RAM 1708 bandwidth. See pros/cons list.

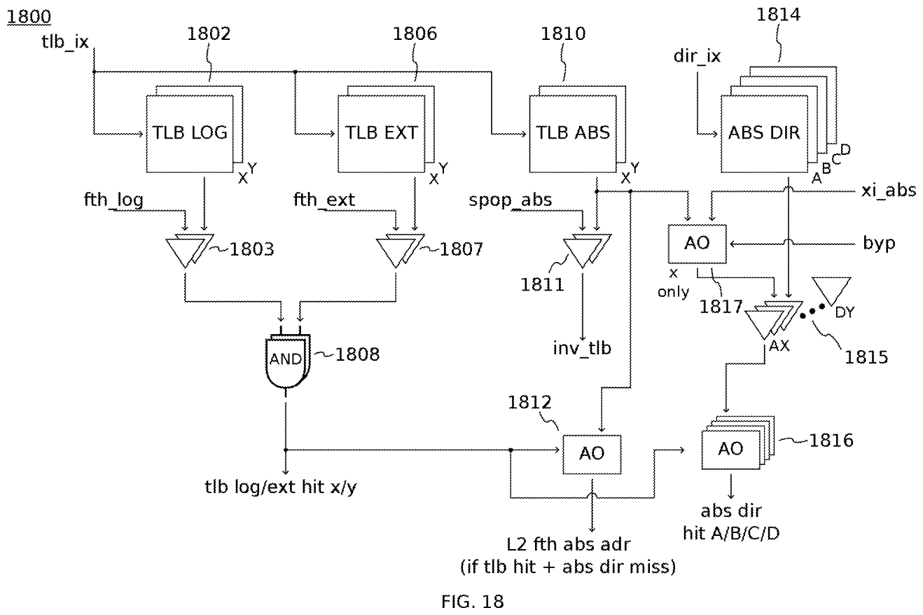

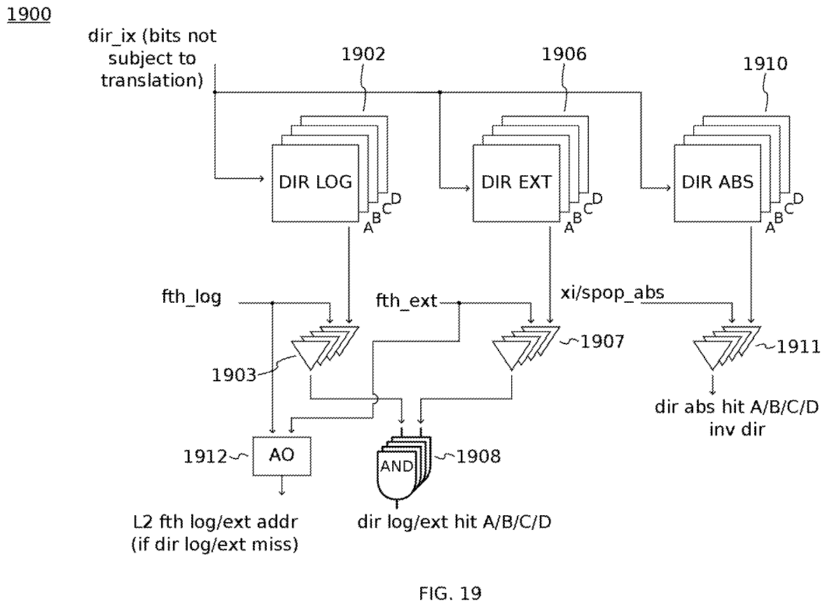

FIGS. 18 and 19 are schematic diagrams depicting at least a portion of traditional request lookup circuitry and exemplary enhanced request lookup circuitry, respectively, for comparison purposes; that is, FIG. 18 illustrates conventional request lookup circuitry 1800, and FIG. 19 illustrates exemplary enhanced request lookup circuitry 1900 according to one or more embodiments of the invention. For these examples, it is assumed that the dimensions of each of the array rectangles, and the width of each of the compare triangles, are roughly equivalent. By way of example only and without limitation, assume each array rectangle is 128 bits deep by roughly 36 bits wide, and call each rectangle an “sid array” (setId array).

With reference to FIG. 18, the traditional lookup circuitry 1800, which assumes a two-way set-associative TLB, includes TLB log arrays 1802, TLB ext arrays 1806, and TLB abs arrays 1810 (corresponding to setids X and Y) accessed in parallel with a four-way absolute directory (abs dir) 1814 (corresponding to setids A through D). Each of the TLB arrays 1802, 1806, 1810 is adapted to receive a TLB index address bus, tlb_ix, supplied thereto. Likewise, each of the arrays in the four-way absolute directory (abs dir) 1814 is preferably configured to receive a directory index address, dir_ix, supplied thereto.

The traditional lookup circuitry 1800 further comprises a plurality of sets of comparison blocks 1803, 1807 and 1811, each set of comparison blocks including multiple comparators (e.g., two in this example, one for each setid X, Y). Each comparator in the first set of comparison blocks 1803 is configured to compare an output of a corresponding one of the TLB log arrays 1802 (setid X, Y) with an fth_log address supplied to the comparator. Each comparator in the second set of comparison blocks 1807 is configured to compare an output of a corresponding one of the TLB ext arrays 1806 (setid X, Y) with an fth_ext address supplied to the comparator. Likewise, each comparator in a third set of comparison blocks 1811 is configured to compare an output of a corresponding one of the TLB abs arrays 1810 (setid X, Y) with an spop_abs address supplied to the comparator. “fth_log” Is the logical address of a fetch lookup request. “fth_ext” is the logical address extension of a fetch lookup request. “spop_abs” is the absolute address of a TLb special op, such as ipte (invalidate page table entry’).

An output of each comparator in the first and second sets of comparison blocks 1803 and 1807, respectively, is supplied as inputs to corresponding AND gates 1808 (one AND gate for each setid X, Y). Respective outputs of the AND gates 1808 forms an output signal, tlb log/ext hit x/y, of the traditional lookup circuitry 1800. The tlb log/ext hit x/y output signal is a source of the control AO 1812, which selects the TLB absolute address, sent to the next level of cache hierarchy for directory misses. An output of each comparator in the third set of comparison blocks 1811 forms a corresponding output signal inv_tlb. At least a portion of the outputs of the TLB abs arrays 1810 may form a TLB absolute address which is supplied to an AND-OR (AO) gate 1812. The AO gate 1812 is configured to select the TLB absolute address from the TLB abs arrays 1810 with the tlb log/ext hit x/y output signal from the AND gates 1808 to form an address signal, L2 fth abs adr, which may be sent to a next level of cache hierarchy (e.g., “L2,” standing for level 2 cache) when a TLB hit and an absolute directory miss occurs.

A portion of the outputs of the TLB abs arrays 1810 (corresponding to setid X) may be supplied as an input to a second AO gate 1817. The second AO gate 1817 may also be configured to receive a cross-interrogate absolute signal, xi_abs, and a bypass control signal, byp. An output generated by the second AO gate 1817 may be supplied as an input to a fourth set of comparison blocks 1815. The fourth set of comparison blocks 1815 preferably includes multiple comparators (14 in this example—a pair (setids X, Y) for each setid A through D in the absolute directory 1814; that is, setids AX, AY, BX, BY, . . . , DX, DY). Outputs from the set of comparison blocks 1815 may be supplied as an input to a set of AO gates 1816 (four in this example; one for each setid A through D in the absolute directory 1814). The tlb log/ext hit x/y signal generated by the AND gates 1808 may be supplied as an input to the set of AO gates 1816, which is configured to generate corresponding absolute directory hit signals, abs dir hit A/B/C/D, corresponding to each of the setids in the absolute directory 1814.

Referring now to FIG. 19, the enhanced operator lookup circuitry 1900 preferably comprises a plurality of arrays, namely, directory log (dir log) arrays 1902, directory extension (dir ext) arrays 1906, and absolute directory (dir abs) arrays, each of the arrays 1902, 1906, 1910 (corresponding to setids A through D). Each of the directory arrays 1902, 1906, 1910 may be indexed only by address bits, dir_ix, that are not subject to translation. As previously stated, this restriction limits the maximum size of the cache.

The enhanced operator lookup circuitry 1900 further includes a plurality of sets of comparison blocks 1903, 1907 and 1911, each set of comparison blocks including multiple comparators (e.g., four in this example, one for each setid A through D of the arrays 1902, 1906, 1910). Each comparator in the first set of comparison blocks 1903 is configured to compare an output of a corresponding one of the directory log arrays 1902 (setid A, B, C, D) with an fth_log signal supplied to the comparator. Each comparator in the second set of comparison blocks 1907 is configured to compare an output of a corresponding one of the directory extension arrays 1906 (setid A, B, C, D) with an fth_ext signal supplied to the comparator. Likewise, each comparator in a third set of comparison blocks 1911 is configured to compare an output of a corresponding one of the directory absolute arrays 1910 (setid A, B, C, D) with an xi/spop_abs signal supplied to the comparator.

Outputs from the first and second sets of comparison blocks 1903, 1907 may be supplied as inputs to AND gates 1908, configured to generate respective directory log/extension output signals indicative of a hit occurring between the directory log and extension arrays associated with setids A through D. The fth_log and fth_ext control signals may also be supplied to an AO gate 1912 for forming a log/ext address which may be sent to a next level of cache hierarchy (e.g., “L2,” standing for level 2 cache) when an fth log/extension miss occurs. Outputs generated by the third set of comparison blocks 1911 may form control signals indicative of a directory absolute hit occurring in the directory absolute arrays 1910 associated with setids A through D.

Comparing the illustrative traditional lookup circuitry 1800 shown in FIG. 18 with the illustrative enhanced lookup circuitry 1900 shown in FIG. 19, the traditional lookup circuitry 1800 uses ten sid arrays 1802, 1806, 1810 and the enhanced lookup circuitry 1900 uses twelve sid arrays 1902, 1906, 1910. The traditional lookup circuitry 1800 uses fourteen sid comparators 1803, 1807, 1811, 1815 and the enhanced lookup circuitry 1900 uses twelve sid comparators 1903, 1907, 1911. Note, how the directory arrays 1902, 1906 and 1910 in the enhanced lookup circuitry 1900 are consistent with the TLB arrays 1802, 1806 and 1810 in the traditional lookup circuitry 1800.

The traditional lookup circuitry 1800 includes eight absolute directory comparators 1815 (setids AX, AY, BX, BY, CX, CY, DX, DY) rather than four as used in the enhanced lookup circuitry 1900. This is because both TLB setids in the traditional lookup circuitry 1800 are compared against the directory in parallel, to reduce latency. The tlb log/ext X/Y hit result of the AND gates 1808 is then used to select four of the eight absolute directory compare results via the AO gate 1816 (labelled “abs dir hit A/B/C/D”). The enhanced lookup circuitry 1900 does not have this parallel-compare-neckdown scheme.

The absolute directory hit setid (labelled “abs dir hit A/B/C/D”) signal generated by the AO gates 1816 in the traditional lookup circuitry 1800 is used for the late select to data RAM 1708 (FIG. 17). In the enhanced lookup circuitry 1900, the ANDing (by AND gates 1908) of the log address hit setid signals generated by the respective comparators in the first set of comparison blocks 1903 and the ext hit setid signals generated by the respective comparators in the second set of comparison blocks 1907 may be used for the late select the data RAM 1708 (FIG. 17). For a fetch request to the cache unit, the traditional lookup circuitry 1800 accesses all of its sid arrays, but the enhanced lookup circuitry 1900 does not need to access its directory absolute address arrays 1910.

In the traditional lookup circuitry 1800, the TLB absolute address generated by the AO gate 1812 is the source of the address sent to the next level of cache hierarchy (e.g., L2 cache) for directory misses. The enhanced lookup circuitry 1900 instead sends the requestor's log address and ext, generated as an output of the AO gate 1912, to the next level of cache hierarchy (e.g., L2 cache) for directory misses.

The traditional lookup circuitry 1800 detects a TLB hit (labelled “tlb log/ext hit x/y”) through AND gates 1808 if it has both a TLB log address hit resulting from comparators 1803 and a TLB ext hit resulting from comparators 1807. If the traditional lookup circuitry 1800 detects a TLB miss, it sends an address translation request to a larger TLB or address translation unit that is likely located nearby. By contrast, the enhanced lookup circuitry 1900 does not differentiate between a TLB hit and a TLB miss. Rather, the next level of storage hierarchy (here described previously as L2 cache) checks its TLB to determine TLB hit/miss status.

As previously described, the traditional lookup circuitry 1800 includes a bypass (“byp”) path associated with AO gate 1817 on one of the TLB setids (e.g., setid X) feeding the directory absolute address comparators 1815, which is used for XI searches. The TLB absolute address comparators 1811 are only used for TLB special ops. In the enhanced lookup circuitry 1900, directory absolute address comparators 1911 are used for XI searches and TLB special ops. The enhanced lookup circuitry 1900 may also use the directory absolute address comparators 1911 for synonym detection for directory misses, depending on how synonyms are handled. FIGS. 18 and 19 are also helpful when looking at a “merged directories/cache” embodiment.

Aspects according to the present disclosure presented herein are well-suited for use in conjunction with superconducting logic. For example, if a superconducting system includes a cache hierarchy, level 1 cache (e.g., level 1 cache 1706 in FIG. 17) would likely be located in a “low temperature” area, while level 2 cache would be located in “near 77 Kelvin” processing entities (e.g., 303 in FIG. 3A). The TLB(s) and address translator(s) may also be moved from the level 1 cache area into the 77 Kelvin area, where they would be easier to implement.

A superconducting system does not require, and moreover cannot support, a large level 1 cache array size. Embodiments of the present disclosure can beneficially exploit this practical design restriction, where the cache is not indexed by any address bits that require translation, since this restriction limits cache size.

It was previously mentioned that there may be TLB spop handling performance concerns. Ironically, a smaller cache size may help alleviate such concerns. That is because lines that may otherwise be a performance concern, for example due to being re-referenced with an old translation that is not in the directory, may be overwritten or removed in a smaller cache anyway, for instance as a result of a least recently used (LRU) caching scheme or the like, thereby requiring a refetch to level 2 cache regardless of whether the translation was available.

The idea presented here is well-suited to fungible arrays for memory, logic, and mixed memory/logic operations (see diagrams 300 and 950).

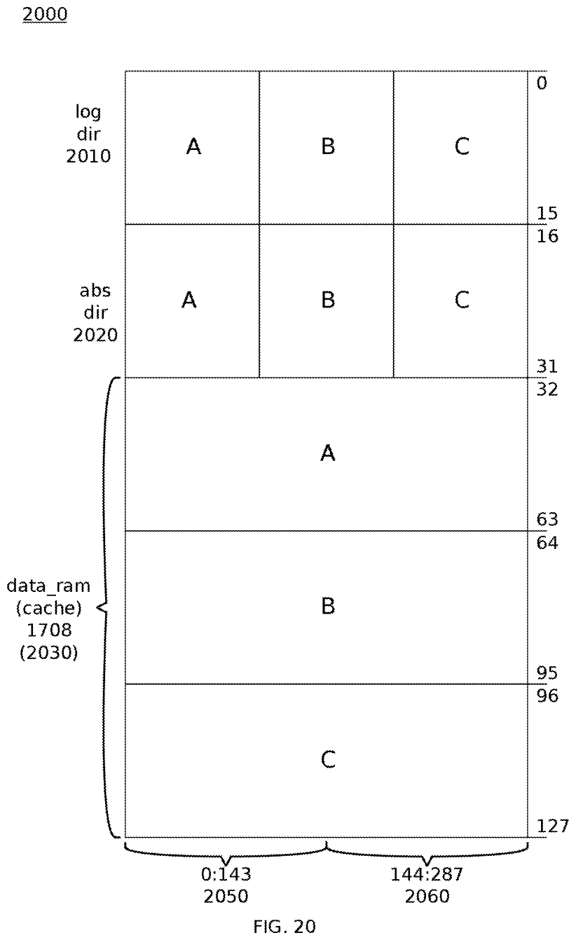

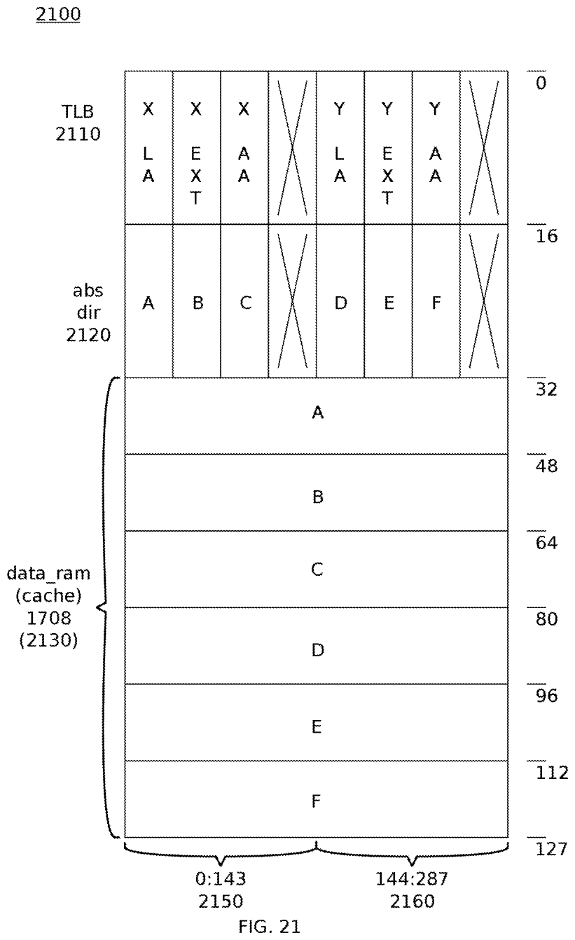

This can be seen when comparing the old versus new lookup schemes, in terms of the ‘merged directories/cache,’ described with reference to FIGS. 20 and 21. The merged approach involves serializing the lookup array accesses into separate steps and potentially splitting array accesses and compares/logic into separate steps.

For the traditional lookup circuitry 1800, the following seven steps would be needed:
(i) access TLB log/ext 1802 and 1806;
(ii) compare TLB log/ext 1803, 1807, and 1808;
(iii) access TLB absolute 1810;
(iv) AND-OR (ao) TLB absolute 1812;
(v) access absolute directory 1814;
(vi) ao for bybass 1817; and
(vii) compare TLB absolute 1815.

For the enhanced lookup circuitry 1900, only two steps are needed, as follows:
(i) access directory log/ext 1902 and 1906; and
(ii) compare directory log/ext 1903, 1907, and 1908, for a total of 2 steps.

However, it should be noted that the traditional lookup scheme can result in a more symmetric lookup array layout for the merged idea, in terms of array row bits lining up with each other, for traditional lookup (TLB vs. absolute directory) compared to enhance lookup (directory log/ext vs directory absolute). This can be seen when comparing the two examples in FIGS. 20 and 21 for the “merged directories/cache” embodiment.

In summary, there are various advantages provided by embodiments of the enhanced lookup scheme, including, but not limited to, the following:
(i) removes need for lookup path tdm (?) to allow full bandwidth;
(ii) perhaps allows XIs to run in parallel with fetches/stests;
(iii) perhaps allows removal of much of storeq absolute address field; and
(iv) moves TLB to higher-temperature region.

Some cons of the enhanced lookup scheme, as a trade-off for the benefits, may include:
(i) performance concerns involving TLB special ops
(ii) creates a type of synonym whose handling would need to be carefully thought through
(iii) adds 5% more array area to cache unit
(iv) Adds array instances and more logic to L2
(v) If logical address extension exists, then it would be sent to L2, using the fetch address bus to L2 a 2^{nd} cycle

### Merged Lookup and Data RAMs

An L1 cache 1706 has a corresponding lookup path 1714 that consists of arrays such as a TLB 1712, a logical directory 1710, and an absolute directory also 1710. Typically, these arrays are separate from each other, and accessed mostly or fully in parallel, to minimize data return speed to optimize performance.

Consider an alternative array layout where the lookup path arrays and the L1 cache array are mostly or fully accessed in series. Furthermore, consider array layouts where these serially accessed arrays, instead of being vertically sliced into separate arrays, are horizontally sliced into different groups of addresses/rows, within one or more arrays, as shown in FIGS. 20 and 21. This layout degrades performance, but optimizes one or more of the following:
1) reduced number of unique array designs
2) reduced array area
3) reduced array power
4) easier implementation of higher set-associativities

The term “array” will continue to be used when referring to the cache or lookup arrays, even though they are now only subsets of physical arrays.

When balancing real estate between TLB/directory(s)/cache, assume the best tradeoff is for the cache to use the majority of real estate. Assume the most efficient array depth is a power of two. To achieve both of these goals, the desired cache array depth is not a power of two. Typical array addressing does not achieve this.

One key solution is to:
1) include encoded setid/way bits as part of the cache array address; and
2) use a cache set associativity that is not a power of two.

This means the setids of the cache are horizontally sliced. For the 2 examples in FIGS. 20 and 21 (for data RAM 2030 and 2130, respectively), note the cache setid slicing direction, the number of lettered setids, and the cache depth. This also means that the encoded setid portion of the cache address has one or more unused code points.

It is preferred that the lookup path arrays have their setids sliced vertically, so that their setids can be compared against in parallel. See (i) log/absolute directory setids A through C/F 2010 and 2020 in FIG. 20 and (ii) TLB setids X and Y 2110 in FIG. 21. The unused cache setid encode(s) are used as part of the lookup path array address. Other address bit(s) may be used to select one of two or more lookup path arrays.

It is mentioned above that this idea allows for easier implementation of higher set associativities. Accessing the arrays in series removes the need for parallel compares that had existed only for the purpose of further latency reduction, such as parallel absolute directory compares against multiple TLB setids 1815. Using the directory hit setids as encodes of cache address bits, instead of late selects, is more area-efficient. Although the examples below vertically slice all setids for a given lookup array, an alternative for handling high set-associativity is to do a combination of vertical and horizontal slicing. For example, grouping half the setids in one horizontal slice, and the other half in another horizontal slice, where each group of 3 setids is vertically sliced, like this:
A B C
D E F

This would increase latency further, but would allow for reducing the number of setids read in parallel, along with reducing the number of comparators needed.

For FIGS. 20 and 21, assumptions for both illustrative embodiments of a lookup path 1714 (structure) and data RAM (cache) stored in a common array building block follow:
1) Assume an array building block that is 128 deep×144 wide
2) Assume 2 building blocks are used (2050 and 2060 for FIGS. 20; 2150 and 2160 for FIG. 21)
3) The cache size is 96 deep×32 bytes=3 kbytes
4) bb address=building block address 0:6

What follows is a description of the example in FIG. 20: Except for the amount of directory set associativity, this example corresponds to earlier FIG. 19. The cache has a lookup structure consisting of 3-way set associative log/absolute directory's 2010 and 2020, each of which are 16 deep. A log directory entry consists of an LA (logical address) and an EXT (logical address extension). An absolute directory entry consists of an absolute address (AA). “For simplicity, assume the width is 36 bits for each of LA, EXT, AA.” This means that there is leftover space in each of the log/absolute directory setids in the example in FIG. 20, especially for the absolute directory. The cache is addressed with 54:58. The directories are addressed with 54:57, for a line size of 64 bytes. If the desired cache read data widthis 8 bytes, then address bits 58:59 mux 288 read data bits down to 72.

The sequence for an exemplary XI is the following:
1) access absolute directory with
   bb address (0:1)=‘00’=lookup path
   bb address (2)=‘1’=absolute directory
   bb address (3:6)=54:57
2) compare XIs AA against each of absolute directory setids:
   1 36-bit compare×3 setids
3) turn off corresponding directory valid bit if hit

The sequence for an exemplary fetch is the following:
1) access log directory with
   bb address (0:1)=‘00’=lookup path
   bb address (2)=‘0’=log directory
   bb address (3:6)=54:57
2) compare fetches LA and EXT against each of the log directory setids:
   2 36-bit compares×3 setids
3) access cache with
   bb address (0:1)=encoded log directory hit setid A:C=‘01’, ‘10’ or ‘11’
   bb address (2)=58
   bb address (3:6)=54:57
4) use address 59:60 to mux down cache array output data from 288 bits to 72 bits

The comparator efficiency follows: the row position of the absolute directory AA fields could be lined up with the position of the log directory LA or EXT field. Then the absolute directory AA comparators could be shared with the log directory LA or EXT compares.

What follows is a description of the example in FIG. 21: Except for the amount of directory set associativity, this example corresponds to earlier FIG. 18. The cache has a lookup structure consisting of a 2-way set associative TLB 2110 (setids X and Y) and a 6-way set associative absolute directory 2210 (setids A through F), each of which are 16 deep. A TLB entry consists of an LA (logical address), an EXT (logical address extension) and an AA (absolute address). An absolute directory entry consists of an AA (absolute address). “For simplicity, assume the width is 36 bits for each of LA, EXT, AA.” This means the only leftover space in the TLB and absolute directory for the example in FIG. 21 is in the 4 crossed-out areas. The TLB is addressed with 48:51, the absolute directory is addressed with 55:58 and the cache is addressed with 55:58. The line size of 32 bytes. If the desired cache read data width is 8 bytes, then address bits 58:59 mux 288 read data bits down to 72.

The sequence for XI is the following:
1) access absolute directory with
   bb address (0:1)=‘00’=lookup path
   bb address (2)=‘1’=absolute directory
   bb address (3:6)=55:58
2) compare XIs AA against each of absolute directory setids:
   1 36-bit compare×6 setids
3) turn off corresponding directory valid bit if hit

The sequence for TLB AA spop (special op) is the following:
1) access TLB AA with
   bb address (0:1)=‘00’=lookup path
   bb address (2)=‘0’=TLB
   bb address (3:6)=48:51
2) compare spops AA against each of TLB setids:
   1 36-bit compare×2 setids
3) turn off corresponding TLB valid bit(s) if hit

The sequence for a fetch is the following:
1) access TLB LA and EXT with
   bb address (0:1)=‘00’=lookup path
   bb address (2)=‘0’=TLB
   bb address (3:6)=48:51
2) compare fetchess LA and EXT against each of the TLB setids:
   2 36-bit compares×2 setids
3) access TLB AA with
   bb address (0:1)=‘00’=lookup path
   bb address (2)=‘0’=TLB
   bb address (3:6)=48:51
4) use earlier TLB hit setid X/Y to mux down
   TLB AA output data
5) access absolute directory with
   bb address (0:1)=‘00’=lookup path
   bb address (2)=‘1’=absolute directory
   bb address (3:6)=55:58
6) compare earlier TLB hit AA against each of absolute directory setids:
   1 36-bit compare×6 setids
7) access cache with
   bb address (0:2)=encoded absolute directory hit setid A:F=‘010’ through ‘111’
   bb address (3:6)=55:58
8) use address 59:60 to mux down cache array output data
   from 288 bits to 72 bits

Concerning comparator efficiency, the row position of the 6 absolute directory AA fields could be lined up with the position of the 6 TLB LA/EXT/AA fields as seen in 2120 and 2120. Then the 6 absolute directory AA comparators could be shared with the TLB LA/EXT/AA fields.

Fungible arrays for memory, logic, and mixed memory/logic operations are well-suited for use with merged arrays.

The intrinsic flexibility of the hardware, covering logic, memory, and both, permits a variety of hardware organizations suited to achieve far higher performance per die area than a general purpose processor. Moreover, the underlying circuit structure is regular, which lends itself to simpler implementations in the highly constrained design execution process of a microwave design in superconducting technology. Again, looking at the fetch for the example in FIG. 21:
1) access TLB LA and EXT
   and
2) compare fetchess LA and EXT against each of the TLB setids
   using fungible arrays in mixed memory/logic mode
   or split into more steps
   2 36-bit compares×2 setids
3) access TLB AA
   and
4) use earlier TLB hit setid X/Y to mux down TLB AA output data
   using fungible arrays in mixed memory/logic mode
   or split into more steps
5) access absolute directory
   and
6) compare earlier TLB hit AA against each of absolute directory setids
   using fungible arrays in mixed memory/logic mode
   or split into more steps
   1 36-bit compare×6 setids
7) access cache
   and
8) use address 59:60 to mux down cache array output data
   from 288 bits to 72 bits
   using fungible arrays in mixed memory/logic mode
   or split into more steps

There are many alternative embodiments of merged arrays that use different addressing combinations, different set associativities, larger cache sizes, more array instances, different building block dimensions, different lookup approaches, etc. An alternative concept would be to structure the fungible arrays and surrounding logic such that various lookup/cache structures could be added and removed during machine operation.

It is to be understood that the methods, circuits, systems and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), Complex Programmable Logic Devices (CPLDs), etc. In an abstract but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

The functionality associated with the examples described in this disclosure can also include instructions stored in a non-transitory media. The term “non-transitory media” as used herein refers to any media storing data and/or instructions that cause a machine, such as a processor, to operate in a specific manner. Exemplary non-transitory media include non-volatile media and/or volatile media. Non-volatile media include, for example, a hard disk, a solid-state drive, a magnetic disk or tape, an optical disk or tape, a flash memory, an EPROM, NVRAM, MRAM, or other such media, or networked versions of such media.

Volatile media include, for example, dynamic memory, such as, DRAM, SRAM, a cache, or other such media. Non-transitory media is distinct from, but can be used in conjunction with transmission media. Transmission media is used for transferring data and/or instruction to or from a machine. Exemplary transmission media, include coaxial cables, fiber-optic cables, copper wires, and wireless media, such as radio waves.

Furthermore, those skilled in the art will recognize that boundaries between the functionality of the above-described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate spatial, temporal, or other prioritization of such elements.

1.-5. (canceled)

6. A multi-channel passive transmission line distribution circuit, comprising:
a plurality of superconducting passive transmission line circuits;
a superconducting timing circuit; and
superconducting logic circuitry operatively coupled to the plurality of superconducting passive transmission line circuits and configured to combine respective outputs of the plurality of superconducting passive transmission line circuits to generate a data output signal of the multi-channel superconducting passive transmission line distribution circuit,
wherein each of the plurality of superconducting passive transmission line circuits is configured to receive a data input signal, and wherein the superconducting timing circuit is configured to generate respective enable signals supplied to each of the plurality of superconducting passive transmission line circuits.

7. The multi-channel passive transmission line distribution circuit according to claim 6, wherein the superconducting timing circuit is configured such that a delay value between activation of respective ones of the plurality of superconducting passive transmission line circuits is at least equal to a flux quanta recovery time of a given one of the plurality of superconducting passive transmission line circuits.

8. The multi-channel passive transmission line distribution circuit according to claim 6, wherein each of the plurality of superconducting passive transmission line circuits comprises:
a superconducting passive transmission line driver;
a superconducting passive transmission line receiver;
a superconducting passive transmission line connected between an output of the superconducting passive transmission line driver and an input of the superconducting passive transmission line receiver; and
a superconducting logic gate configured to provide the data input signal to an input of the superconducting passive transmission line driver as a function of a corresponding one of the enable signals.

9. The multi-channel passive transmission line distribution circuit according to claim 6, wherein the superconducting timing circuit comprises a plurality of superconducting delay lines connected in series, each of the plurality of superconducting delay lines having a prescribed delay value associated therewith, an output of each of the plurality of superconducting delay lines generating a corresponding one of the enable signals provided to the plurality of superconducting passive transmission line circuits.

10. The multi-channel passive transmission line distribution circuit according to claim 9, wherein the prescribed delay values associated with the respective plurality of superconducting delay lines are equal to one another.

11. The multi-channel passive transmission line distribution circuit according to claim 9, wherein the prescribed delay values associated with at least two of the respective plurality of superconducting delay lines are different.

12. The multi-channel passive transmission line distribution circuit according to claim 6, wherein the superconducting timing circuit comprises a counter configured to receive a clock signal based on the data input signal and to generate a count value indicative of a delay amount provided to the plurality of superconducting passive transmission line circuits.

13. The multi-channel passive transmission line distribution circuit according to claim 6, wherein the superconducting logic circuitry is configured to generate the respective enable signals supplied to each of the plurality of superconducting passive transmission line circuits as a function of a trigger signal provided to the superconducting timing circuit, the respective enable signals being configured such that a single one of the plurality of superconducting passive transmission line circuits is active during a prescribed period of time.

14. A single flux quantum copy delay circuit, comprising:
a first single flux quantum delay module having a first delay value associated therewith;
a second single flux quantum delay module having a second delay value associated therewith; and
single flux quantum logic circuitry operably coupled to respective outputs of the first and second single flux quantum delay modules, the single flux quantum logic circuitry being configured to receive an input data signal provided to the single flux quantum copy delay circuit and to generate at least one output data signal, per input data signal received, that is a version of the input data signal delayed as a function of the first and/or second delay values.

15. The single flux quantum copy delay circuit according to claim 14, further comprising a single flux quantum control circuit configured to receive the input data signal and at least first and second control signals, wherein the first delay value is programmable as a function of the first control signal and the second delay value is programmable as a function of the second control signal.

16. The single flux quantum copy delay circuit according to claim 15, wherein the single flux quantum control circuit comprises:
a first logic gate having a first input for receiving the input data signal, a second input for receiving the first control signal, and an output coupled to an input of the first single flux quantum delay module; and
a second logic gate having a first input for receiving the input data signal, a second input for receiving the second control signal, and an output coupled to an input of the second single flux quantum delay module.

17. The single flux quantum copy delay circuit according to claim 16, wherein the single flux quantum control circuit further comprises a third logic gate having a first input for receiving the input data signal, a second input for receiving a third control signal, and an output coupled to an input of the single flux quantum logic circuitry.

18. The single flux quantum copy delay circuit according to claim 14, wherein the first and second delay values are fixed, and wherein the second single flux quantum delay module is configured having an input coupled to an output of the first single flux quantum delay module and configured to generate an output that is equivalent to the input data signal delayed by a combination of the first and second delay values.

19. The single flux quantum copy delay circuit according to claim 14, wherein the first single flux quantum delay module is configured having an input for receiving the input data signal and an output coupled to a first input of the single flux quantum logic circuitry, and wherein the second single flux quantum delay module is configured having an input coupled to the output of the first single flux quantum delay module and an output coupled to a second input of the single flux quantum logic circuitry, and wherein the input data signal is provided to a third input of the single flux quantum logic circuitry without intrinsic delay.

20. The single flux quantum copy delay circuit according to claim 14, wherein the single flux quantum logic circuitry comprises:
a first logic gate having a first input for receiving the input data signal and a second input coupled to an output of the first single flux quantum delay module; and
a second logic gate having a first input coupled to an output of the first logic gate, a second input coupled to an output of the second single flux quantum delay module, and an output for generating the output data signal.

21. A metamorphosing memory circuit, comprising:
a superconducting memory array including a plurality of superconducting memory cells, at least a subset of the plurality of superconducting memory cells arranged into rows and columns in the superconducting memory array, the plurality of superconducting memory cells arranged into a plurality of regions, each of the plurality of regions of superconducting memory cells being an independently accessible subset of the rows in the superconducting memory array;
a superconducting input logic circuit coupled to the superconducting memory array, the superconducting input logic circuit being configured for independent selection of each of the rows of superconducting memory cells during a read cycle for performing a logic operation and/or a memory operation, the superconducting input logic circuit being configured to receive at least one read address signal for providing read address data to the superconducting input logic circuit for selecting at least one region from the plurality of regions of superconducting memory cells for a logic operation and/or a memory operation, the superconducting input logic circuit being configured to receive at least one word-line data address signal for providing word-line address data to the superconducting input logic circuit for selection or non-selection of each row in the subset of rows comprising at least one selected region from the plurality of regions for a logic operation and/or a memory operation; and
a superconducting output logic circuit coupled to the superconducting memory array and configured to receive a plurality of column outputs from the superconducting memory array and to buffer and/or perform logic functions on the plurality of column outputs,
wherein selection of at least one of the plurality of regions of superconducting memory cells is enabled through the superconducting input logic circuit,
wherein each of the plurality of superconducting memory cells is configured to perform at least one of memory operations in a first mode, logic operations in a second mode, or mixed memory and logic operations in a third mode, and
wherein the plurality of column outputs is configured to provide memory state and/or logic operation information to a plurality of corresponding inputs of the superconducting output logic circuit.

22. The metamorphosing memory circuit according to claim 21, wherein the superconducting input logic circuit is configured to access one or concurrently access at least two of the plurality of regions of superconducting memory cells during each read cycle.

23. The metamorphosing memory circuit according to claim 21, wherein each of the plurality of superconducting memory cells comprises at least one of a memory cell, a programmable switch, or a fixed switch, wherein a logic state of the fixed switch is set during fabrication of the metamorphosing memory circuit.

24. The metamorphosing memory circuit according to claim 21, wherein the superconducting output logic circuit comprises logic circuitry configured to combine output data from two or more of the plurality of column outputs.

25. The metamorphosing memory circuit according to claim 21, wherein the superconducting output logic circuit comprises an electable inverter circuit, the electable inverter circuit being configured to provide, at an output thereof, a non-inverted or an inverted version of a signal provided to an input of the electable inverter circuit as a function of at least one control signal.

26. A superconducting cache circuit, comprising:
at least one metamorphosing memory circuit configured to implement a memory system, a programmable logic system, or both a memory system and a programmable logic system, the at least one metamorphosing memory circuit comprising one or more superconducting arrays, each of the superconducting arrays including a plurality of superconducting cells, each of the superconducting cells being configured as a memory cell for performing memory operations in a first mode, or as a programmable switch for performing logic operations in a second mode, or as both a memory cell and a programmable switch for performing mixed-mode operations in a third mode, each of the plurality of superconducting cells being configured to store data comprising at least one of operands, operators or instructions; and
at least one directory operatively coupled to the at least one metamorphosing memory circuit, the directory being configured to index locations of at least one of operands, operators or instructions stored in the at least one metamorphosing memory circuit,
wherein an operator stored in the at least one metamorphosing memory circuit is configured to perform one or more computations based at least in part on operands retrieved from the at least one metamorphosing memory circuit, and to compute results as a function of the retrieved operands and programmable switch states of the plurality of superconducting cells in the at least one metamorphosing memory circuit, and
wherein the directory is configured to confirm that at least one of a requested operand, operator and instruction is stored in the at least one metamorphosing memory circuit.
